(19) United States
(12) Patent Application Publication
(10) Pub. No.: US 2010/0301310 A1
(43) Pub. Date: Dec. 2, 2010

(54) POLYMER AND POLYMERIC LUMINESCENT ELEMENT EMPLOYING THE SAME

(75) Inventors: Takanobu Noguchi, Ibaraki (JP); Tomoyuki Suzuki, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Chuo-ku, Tokyo (JP)

(21) Appl. No.: 12/067,856

(22) PCT Filed: Oct. 5, 2006
(86) PCT No.: PCT/JP06/19979

§ 371 Date: Mar. 24, 2008

(30) Foreign Application Priority Data
Oct. 7, 2005 (JP) 2005-294747
Oct. 7, 2005 (JP) 2005-294748
Oct. 7, 2005 (JP) 2005-294749

(51) Int. Cl. H01L 51/54; C08G 65/38; C08G 73/06

(52) U.S. Cl. 257/40; 528/210; 528/219; 528/405; 257/E51.027

(57) ABSTRACT

A conjugated polymer having a phenoxazine structure and a phenothiazine structure as subsituents.

### TECHNICAL FIELD

The present invention relates to a polymer compound and a polymer luminescent device (sometimes referred to as a “polymer LED”) using the same.

### BACKGROUND ART

A luminescent material of a high molecular weight, unlike that of a low molecular weight, is soluble to a solvent. Since it can form a luminescent layer of a luminescent device by a coating method, various types of luminescent materials of a high molecular weight have been studied. As an example thereof, a polymer compound having two types of repeat units containing an aromatic ring in the main chain and an aryl group, more specifically, a phenyl group (formula weight: 77) as a terminal group is known (see Patent Documents 1, 2 and 3).

Another polymer compound containing a phenoxazine-diyl group and a phenothiazine-diyl group as the repeat unit of the main chain is also known (see Patent Documents 4 and 5).

However, the polymer compounds mentioned above are not sufficient as a luminescent material for a polymer LED luminescent layer for use in practice in the respect of properties such as fluorescent intensity and durability. In the circumstances, it has been desired to develop a polymer compound exhibiting more excellent properties as a luminescent material for a polymer-LED luminescent layer.

Patent Document 1: WO99/54385

Patent Document 2: WO01/49769

Patent Document 3: U.S. Pat. No. 5,777,070

Patent Document 4: U.S. Patent No. 2004-72989

Patent Document 5: JP-A-2004-137456

### DISCLOSURE OF THE INVENTION

### Problem to be Solved by the Invention

The object of the invention is to provide a polymer compound having excellent properties as a luminescent material of a polymer-LED luminescent layer.

### Means for Solving the Problem

The present inventors have conducted intensive studies with a view to attaining the aforementioned object. As a result, they found that a polymer compound, which has at least one type of repeat unit selected from the group consisting of the repeat units represented by the following formula (1) and which has a substituent selected from the group consisting of the monovalent groups represented by the following formula (2) or (3), exhibits strong fluorescent intensity and has excellent properties as a polymer-LED luminescent layer. Based on the finding, they arrived at the present invention.

A polymer compound according to the present invention has excellent properties as a luminescent material. A polymer luminescent device using the polymer compound has high performance and used as a planar light source serving as backlight and a device such as a flat panel display. A polymer compound according to the present invention can be also used as a laser dye, a material for an organic solar battery, an organic semiconductor for use in an organic transistor and a conductive thin-film material.

### BEST MODE FOR CARRYING OUT THE INVENTION

A polymer compound according to the present invention contains at least one type of repeat unit represented by the following formula (1).

More specifically, the present invention is concerned with a polymer compound having at least one type of repeat unit selected from the group consisting of the repeat units represented by the following formula (1), characterized by having a substituent selected from the group consisting of the monovalent groups represented by the following formula (2) or (3),

—Ar₁—(Z′)p— (1)

where Ar₁ represents an arylene group, a divalent heterocyclic group or a divalent aromatic amine group; Z′ represents —CR₄═CR₅— or —C≡C—; R₄ and R₅ each independently represent a hydrogen atom, an alkyl group, an aryl group, a monovalent heterocyclic group or a cyano group; and p represents 0 or 1,

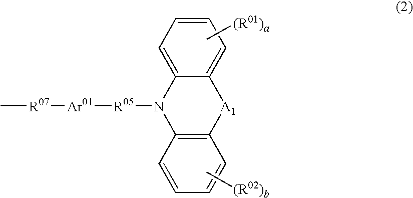

where A₁ represents —O—, —S— or —C(O)—; Ar⁰¹ represents a direct bond, an arylene group, a divalent heterocyclic group or a divalent aromatic amine group; R⁰⁵ and R⁰⁷ each independently represent a direct bond, —R₁—, —O—R₁—, —R₁—O—, —R₁—C(O)O—, —R₁—OC(O)—, —R₁—N(R₂₀)—, —O—, —S—, —C(O)O— or —C(O)—; R₁ represents an alkylene group or an alkenylene group; R₂₀ represents a hydrogen atom, an alkyl group, an aryl group, a monovalent heterocyclic group or a cyano group, with the proviso that when Ar⁰¹ is a direct bond, R⁰⁷ is also a direct bond; R⁰¹ and R⁰² each independently represent a substituent; a and b are each independently an integer from 0 to 4; and a plurality of substituents represented by R⁰¹ and R⁰² may be the same or different,

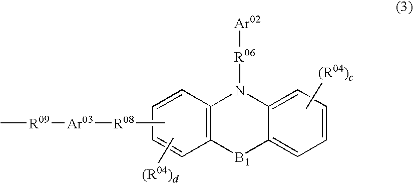

where B₁ represents —O—, —S— or —C(O)—; Ar⁰² represents a hydrogen atom, an aryl group, a monovalent heterocyclic group or a monovalent aromatic amine group; Ar⁰¹ represents a direct bond, an arylene group, a divalent heterocyclic group or a divalent aromatic amine group; R⁰⁶, R⁰⁸ and R⁰⁹ each independently represent a direct bond, —R₁—, —O—R₁—, —R₁—O—, —R₁—C(O)O—, —R₁—OC(O)—, —R₁—N(R₂₀)—, —O—, —S—, —C(O)O— or —C(O)—; R₁ represents an alkylene group or an alkenylene group, R₂₀ represents a hydrogen atom, an alkyl group, an aryl group, a monovalent heterocyclic group or a cyano group, with the proviso that when Ar⁰³ is a direct bond, R⁰⁹ is also a direct bond; R⁰³ and R⁰⁴ each independently represent a substituent; c is an integer from 0 to 4; d is an integer from 0 to 3; and a plurality of substituents represented by R⁰³ and R⁰⁴ may be the same or different.

A polymer compound of the present invention contains one or more types of repeat units represented by the aforementioned formula (1).

In the aforementioned formula (1), Ar₁ represents an arylene group, divalent heterocyclic group or divalent aromatic amine group. Ar₁ herein may have, other than a substituent represented by the aforementioned formula (2) or (3), a substituent such as alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group. When Ar₁ has a plurality of substituents, the substituents may be the same or different.

In the aforementioned formula (1), the arylene group is the remaining atomic group when two hydrogen atoms are removed from an aromatic hydrocarbon. The number of the carbon atoms thereof is generally about 6 to 60, in which the number of carbon atoms of a substituent is not included. The aromatic hydrocarbon herein may have a condensed ring, independent benzene ring or two or more condensed rings joined directly or via a group such as a vinylene group.

Examples of the arylene group include a phenylene group (for example, the following formulas 1 to 3), a naphthalene-diyl group (the following formulas 4 to 13), an anthracenylene group (the following formulas 14 to 19), a biphenylene group (the following formulas 20 to 25), a triphenylene group (the following formulas 26 to 28), a condensed ring compound group (the following formulas 29 to 38), a stilbene-diyl (the following formulas A to D), a distilbene-diyl (the following formulas E and F) and a benzofluorene-diyl (the following formulas G, H, I and K).

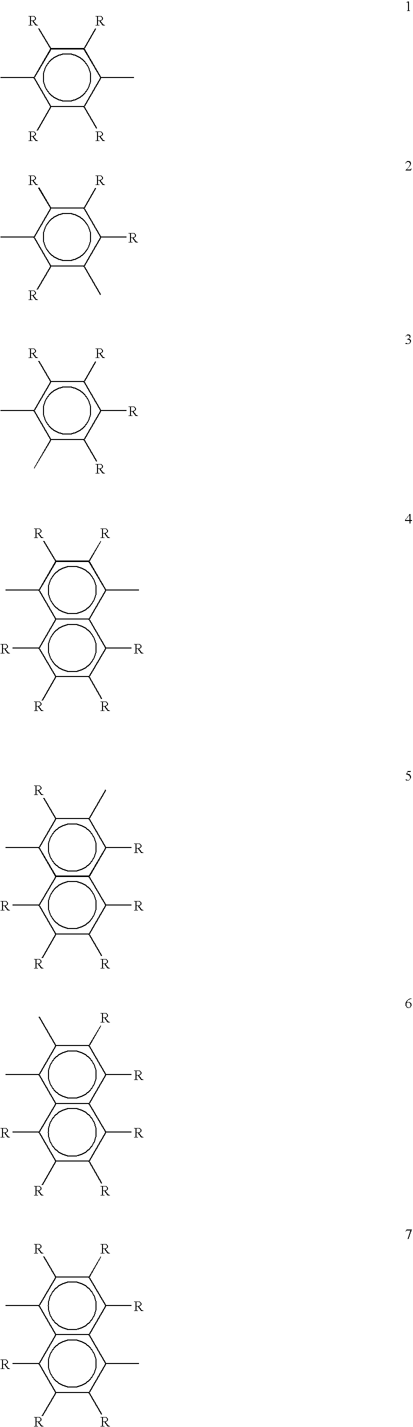

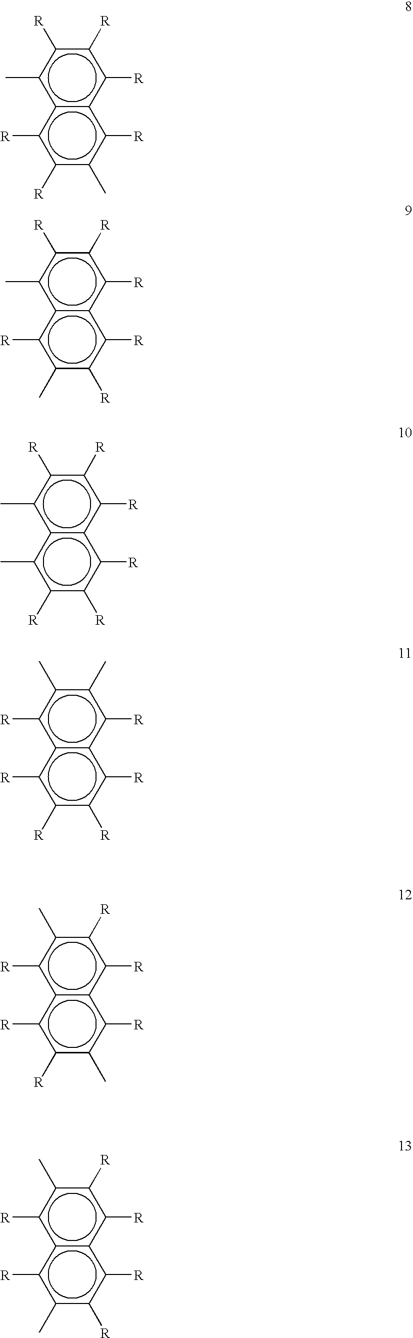

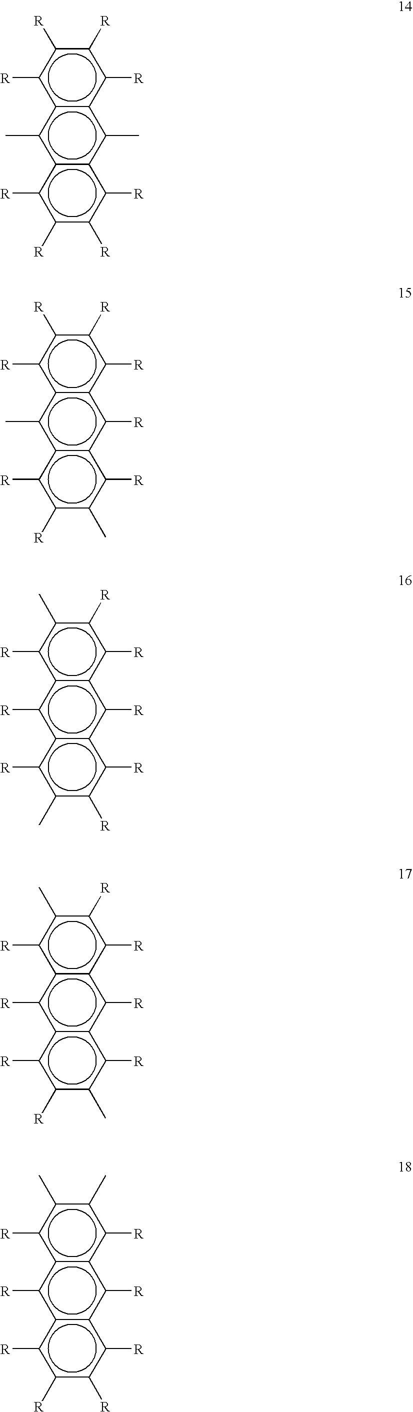

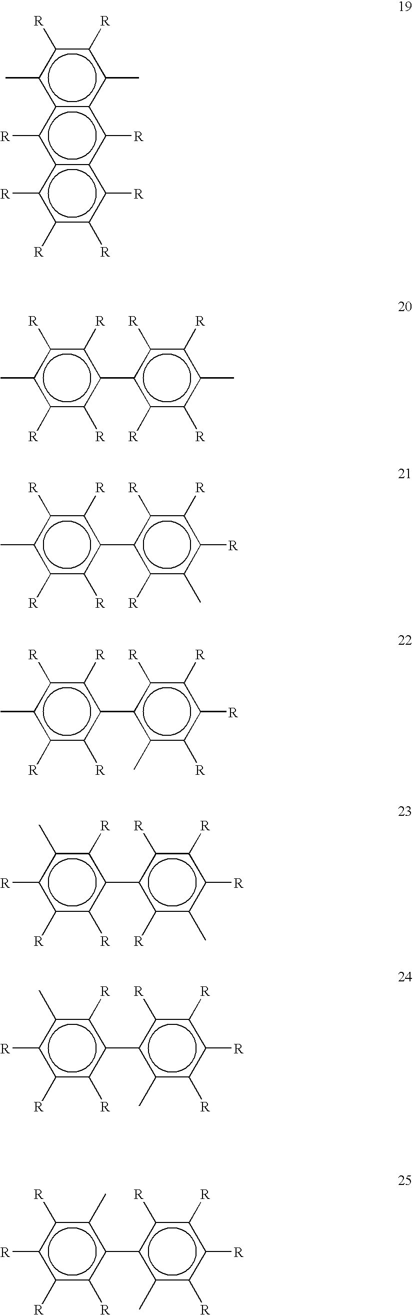

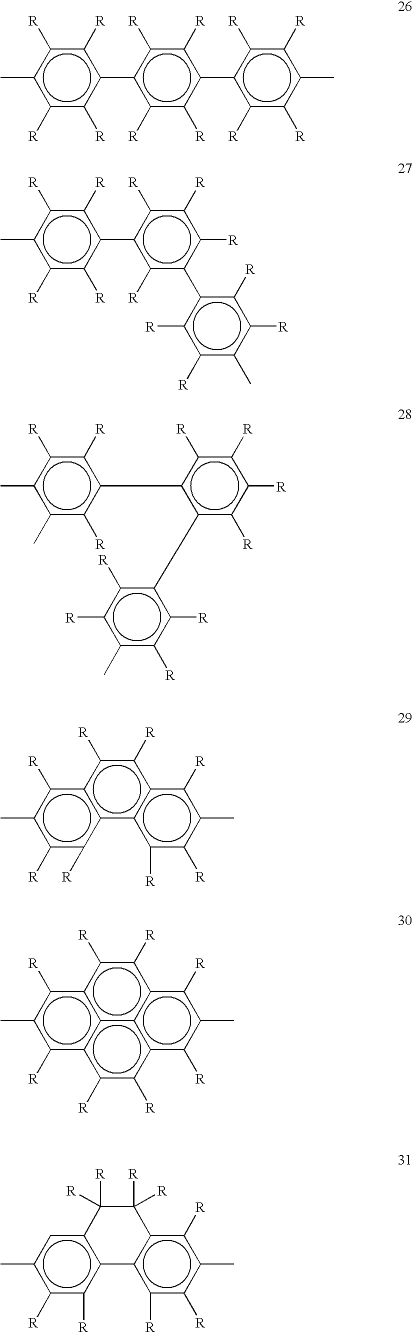

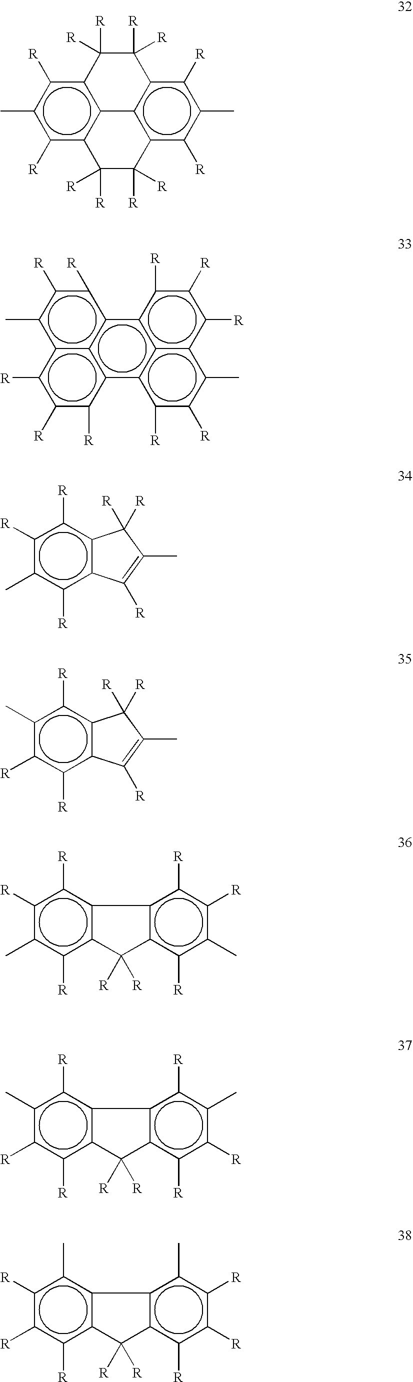

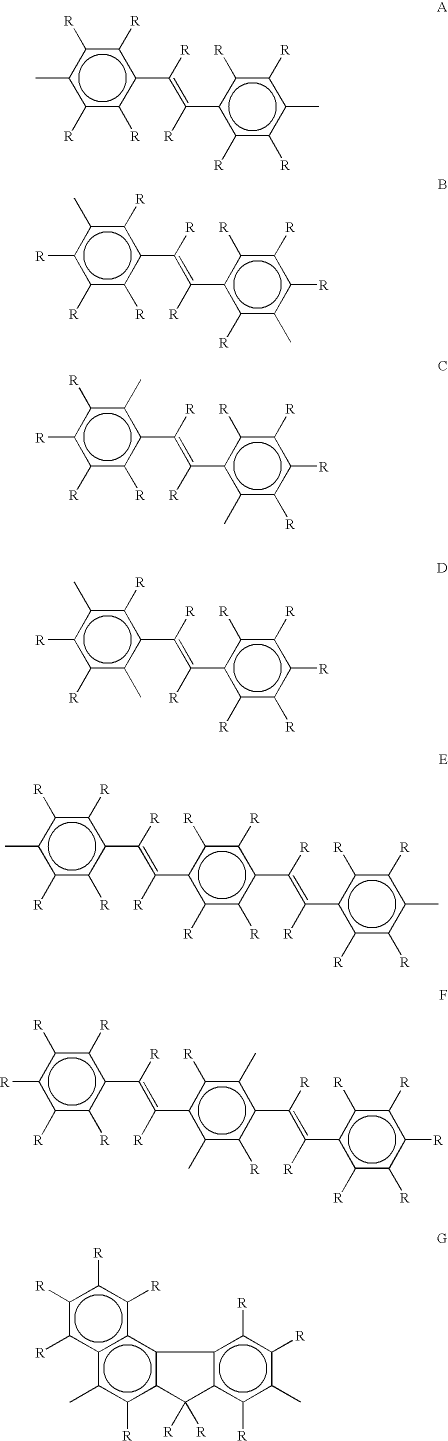

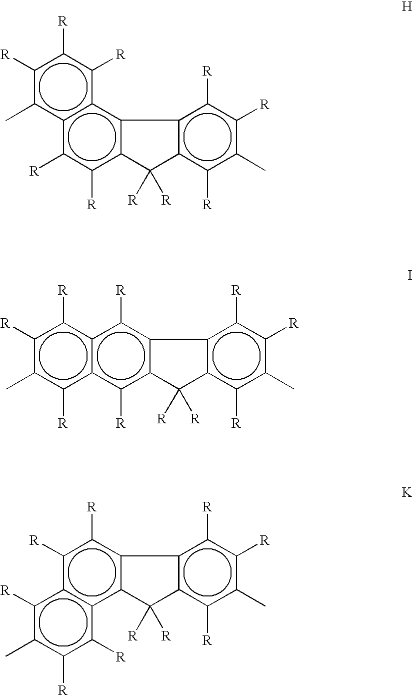

Of them, preferably examples include a phenylene group (for example, the aforementioned formulas 1 to 3), a naphthalene-diyl group (the aforementioned formulas 4 to 13), an anthracenylene group (the aforementioned formulas 14 to 19), a biphenylene group (the aforementioned formulas 20 to 25), a triphenylene group (the aforementioned formulas 26 to 28), a condensed ring compound group (the aforementioned formulas 29 to 38), a stilbene-diyl group (the aforementioned formulas A to D), a distilbene-diyl group (the aforementioned formulas E and F) and a benzofluorene-diyl group (the aforementioned formulas G, H, I and K).

In the aforementioned formulas 1 to 38, A to I and K, R represents a group represented by the aforementioned formula (2) and a group represented by the aforementioned formula (3), a hydrogen atom and an alkyl group, an alkoxy group, an alkylthio group, an alkylsilyl group, an alkylamino group, an aryl group, an aryloxy group, an arylalkyl group, an arylalkoxy group, an arylalkenyl group, an arylalkynyl group, an arylamino group, a monovalent heterocyclic group or a cyano group. The examples mentioned above have a plurality of Rs, which may be the same or different. At least one of the Rs is a group represented by the aforementioned formula (2) or (3) excluding the case where a polymer has a group represented by the formulas (2) or (3) at a molecular chain end of the main chain thereof.

The alkyl group herein may be straight, branched or cyclic and having carbon atoms of generally about 1 to 20. Specific examples thereof include a methyl group, ethyl group, propyl group, isopropyl group, butyl group, isobutyl group, t-butyl group, pentyl group, hexyl group, cyclohexyl group, heptyl group, octyl group, 2-ethylhexyl group, nonyl group, decyl group, 3,7-dimethyloctyl group and lauryl group. Preferable examples thereof include a pentyl group, hexyl group, octyl group, 2-ethylhexyl group, decyl group and 3,7-dimethyloctyl group.

The alkoxy group herein may be straight, branched or cyclic and having carbon atoms of generally about 1 to 20. Specific examples thereof include a methoxy group, ethoxy group, propyloxy group, isopropyloxy group, butoxy group, isobutoxy group, t-butoxy group, pentyloxy group, hexyloxy group, cyclohexyloxy group, heptyloxy group, octyloxy group, 2-ethylhexyloxy group, nonyloxy group, decyloxy group, 3,7-dimethyloctyloxy group and lauryloxy group. Preferable examples thereof include a pentyloxy group, hexyloxy group, octyloxy group, 2-ethylhexyloxy group, decyloxy group and 3,7-dimethyloctyloxy group.

The alkylthio group herein may be straight, branched or cyclic and having carbon atoms of generally about 1 to 20. Specific examples thereof include a methylthio group, ethylthio group, propylthio group, isopropylthio group, butylthio group, isobutylthio group, t-butylthio group, pentylthio group, hexylthio group, cyclohexylthio group, heptylthio group, octylthio group, 2-ethylhexylthio groups, nonylthio group, decylthio group, 3,7-dimethyloctylthio group and laurylthio group. Preferable examples thereof include a pentylthio group, hexylthio group, octylthio group, 2-ethylhexylthio groups, decylthio group and 3,7-dimethyloctylthio group.

The alkylsilyl group herein may be straight, branched or cyclic and having carbon atoms of generally about 1 to 60. Specific examples thereof include a methylsilyl group, ethylsilyl group, propylsilyl group, isopropylsilyl group, butylsilyl group, isobutylsilyl group, t-butylsilyl group, pentylsilyl group, hexylsilyl group, cyclohexylsilyl group, heptylsilyl group, octylsilyl group, 2-ethylhexylsilyl group, nonylsilyl group, decylsilyl group, 3,7-dimethyloctylsilyl group, laurylsilyl group, trimethylsilyl group, ethyldimethylsilyl group, propyldimethylsilyl group, isopropyldimethylsilyl group, butyldimethylsilyl group, t-butyldimethylsilyl group, pentyldimethyl silyl group, hexyldimethylsilyl group, heptyldimethylsilyl group, octyldimethylsilyl group, 2-ethylhexyl-dimethylsilyl groups, nonyldimethylsilyl group, decyldimethylsilyl group, 3,7-dimethyloctyl-dimethylsilyl group and lauryldimethylsilyl group. Preferable examples thereof include pentylsilyl group, hexylsilyl group, octylsilyl group, 2-ethylhexylsilyl group, decylsilyl group, 3,7-dimethyloctylsilyl group, pentyldimethylsilyl group, hexyldimethylsilyl group, octyldimethylsilyl group, 2-ethylhexyl-dimethylsilyl groups, decyldimethylsilyl group and 3,7-dimethyloctyl-dimethylsilyl group.

The alkylamino group herein may be straight, branched or cyclic, and may be a monoalkylamino group or a dialkylamino group, and has generally carbon atoms of about 1 to 40. Specific examples thereof include a methylamino group, dimethylamino group, ethylamino group, diethylamino group, propylamino group, isopropylamino group, butylamino group, isobutylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group and lauryl amino group. Preferable examples thereof include a pentylamino group, hexylamino group, octylamino group, 2-ethylhexylamino group, decylamino group and 3,7-dimethyloctylamino group.

The aryl group has generally about 6 to 60 carbon atoms. Specific examples thereof include a phenyl group, C₁-C₁₂ alkoxyphenyl group, (C₁-C₁₂ represents 1 to 12 carbon atoms. Hereinafter, the same definition will be used), a C₁-C₁₂ alkylphenyl group and 1-naphthyl group and 2-naphthyl group. Preferable examples thereof include a C₁-C₁₂ alkoxyphenyl group and C₁-C₁₂ alkylphenyl group.

The aryloxy group has about 6 to 60 carbon atoms. Specific examples thereof include a phenoxy group, C₁-C₁₂ alkoxyphenoxy group, C₁-C₁₂ alkylphenoxy group, 1-naphthyloxy group and 2-naphthyloxy group. Preferable examples thereof include a C₁-C₁₂ alkoxyphenoxy group and C₁-C₁₂ alkylphenoxy group.

The arylalkyl group has generally about 7 to 60 carbon atoms. Specific examples thereof include a phenyl-C₁-C₁₂ alkyl group, C₁-C₁₂ alkoxyphenyl-C₁-C₁₂ alkyl group, C₁-C₁₂ alkylphenyl-C₁-C₁₂ alkyl group, 1-naphthyl-C₁-C₁₂ alkyl group and 2-naphthyl-C₁-C₁₂ alkyl group. Preferable examples thereof include a C₁-C₁₂ alkoxyphenyl-C₁-C₁₂ alkyl group and C₁-C₁₂ alkylphenyl-C₁-C₁₂ alkyl group.

The arylalkoxy group has generally about 7 to 60 carbon atoms. Specific examples thereof include a phenyl-C₁-C₁₂ alkoxy group, C₁-C₁₂ alkoxyphenyl-C₁-C₁₂ alkoxy-group, C₁-C₁₂ alkylphenyl-C₁-C₁₂ alkoxy group, 1-naphthyl-C₁-C₁₂ alkoxy group and 2-naphthyl-C₁-C₁₂ alkoxy group. Preferable examples thereof include a C₁-C₁₂ alkoxyphenyl-C₁-C₁₂ alkoxy group and C₁-C₁₂ alkylphenyl-C₁-C₁₂ alkoxy group.

The arylalkenyl group has generally about 8 to 60 carbon atoms. Specific examples thereof include a phenyl-C₂-C₁₂ alkenyl group, C₁-C₁₂ alkoxyphenyl-C₂-C₁₂ alkenyl group, C₁-C₁₂ alkylphenyl-C₂-C₁₂ alkenyl group, 1-naphthyl-C₂-C₁₂ alkenyl group and 2-naphthyl-C₂-C₁₂ alkenyl group. Preferable examples thereof include a C₁-C₁₂ alkoxyphenyl-C₂-C₁₂ alkenyl group and C₁-C₁₂ alkylphenyl-C₂-C₁₂ alkenyl group.

The arylalkynyl group has generally about 8 to 60 carbon atoms. Specific examples thereof include a phenyl-C₂-C₁₂ alkynyl group, C₁-C₁₂ alkoxyphenyl-C₂-C₁₂ alkynyl group, C₁-C₁₂ alkylphenyl-C₂-C₁₂ alkynyl group, 1-naphthyl-C₂-C₁₂ alkynyl group and 2-naphthyl-C₂-C₁₂ alkynyl group. Preferable examples thereof include a C₁-C₁₂ alkoxyphenyl-C₂-C₁₂ alkynyl group and C₁-C₁₂ alkylphenyl-C₂-C₁₂ alkynyl group.

The arylamino group has generally about 6 to 60 carbon atoms. Specific examples thereof include a phenyl amino group, diphenylamino group, C₁-C₁₂ alkoxyphenyl amino group, di(C₁-C₁₂ alkoxyphenyl)amino group, di(C₁-C₁₂ alkylphenyl)amino group, 1-naphthylamino group and 2-naphthylamino group. Preferable examples thereof include a C₁-C₁₂ alkylphenyl amino group, di(C₁-C₁₂ alkylphenyl)amino group.

The monovalent heterocyclic group refers to the remaining atomic group when a single hydrogen atom is removed from a heterocyclic compound and has generally about 4 to 60 carbon atoms. Specific examples include a thienyl group, C₁-C₁₂ alkylthienyl group, pyrrolyl group, furyl group, pyridyl group and C₁-C₁₂ alkylpyridyl group. Preferable examples include a thienyl group, C₁-C₁₂ alkylthienyl group, pyridyl group and C₁-C₁₂ alkylpyridyl group.

When the aforementioned substituents contain an alkyl chain, the alkyl chain may be broken at a hetero atom or group containing a hetero atom. Examples of the hetero atom include an oxygen atom, sulfur atom and nitrogen atom. Examples of the hetero atom or the group containing a hetero atom include the following groups.

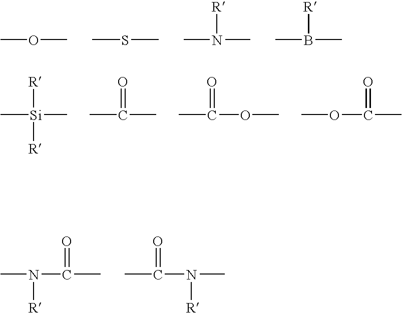

Examples of R′ herein include a hydrogen atom, an alkyl group having 1 to 20 carbon atoms, an aryl group having 6 to 60 carbon atoms and a monovalent heterocyclic group having 4 to 60 carbon atoms.

In the formula (1), the divalent heterocyclic group refers to the remaining atomic group when two hydrogen atoms are removed from a heterocyclic compound, and has generally about 4 to 60 carbon atoms, in which the carbon atoms of a substituent is not included.

The heterocyclic compound herein refers to an organic compound having a ring structure having not only a carbon atom(s) but also a hetero atom such as oxygen, sulfur, nitrogen, phosphorus or boron. For example, the following groups may be mentioned:

groups containing nitrogen as a hetero atom such as a pyridine-diyl group (the following formulas 39-44), a diazaphenylene group (the following formulas 45-48), a quinoline-diyl group (the following formulas 49-63), a quinoxaline-diyl group (the following formulas 64-68), an acridine-diyl group (the following formulas 69-72), a bipyridyl-diyl group (the following formulas 73-75) and a phenanthroline-diyl group (the following formulas 76-78);

groups containing a hetero atom such as silicon, nitrogen, oxygen, sulfur or selenium and having a fluorene structure (the following formulas 79 to 93);

groups having a 5-membered heterocyclic group containing a hetero atom such as silicon, nitrogen, oxygen, sulfur or selenium (the following formulas 94 to 98);

groups having a 5-membered condensed heterocyclic group containing a hetero atom such as silicon, nitrogen, oxygen, sulfur or selenium (the following formulas 99 to 108);

dimers or oligomers of 5-membered heterocyclic groups containing a hetero atom such as sulfur and joined at the α-position of the hetero atom (the following formulas 109 and 110); and

5-membered heterocyclic groups containing a hetero atom such as silicon, nitrogen, oxygen, sulfur or selenium and joined to phenyl groups at the α-position of the hetero atom (the following formulas 111 to 117).

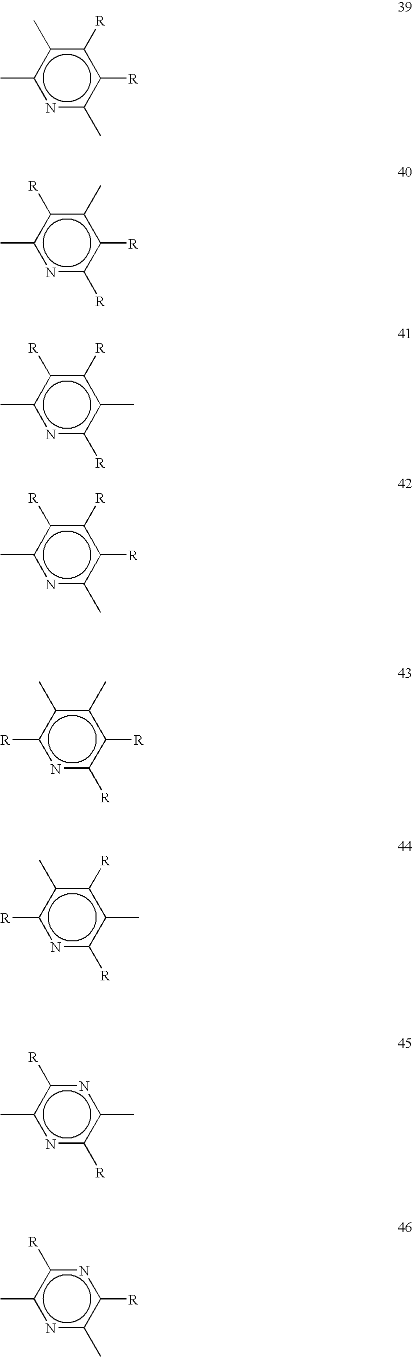

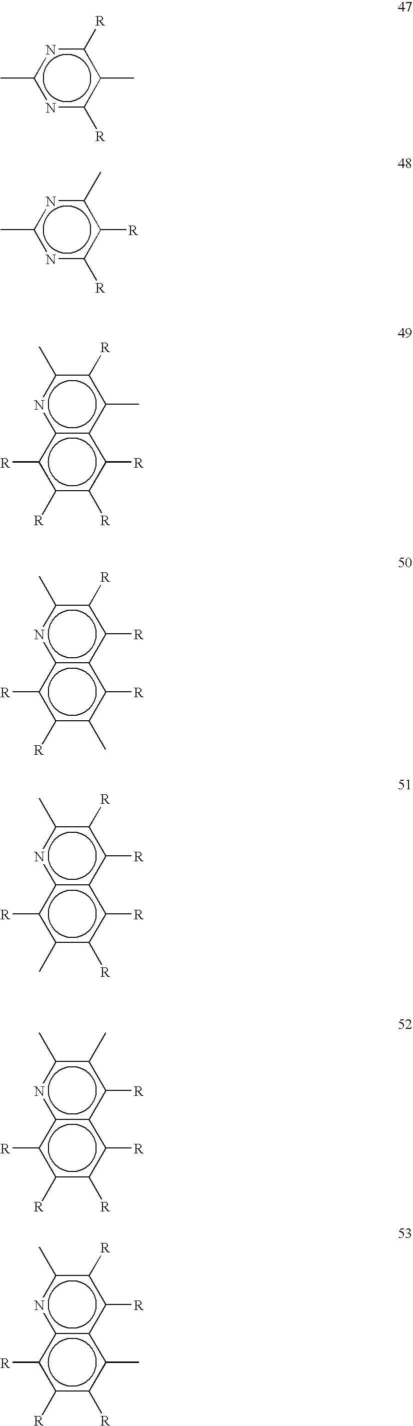

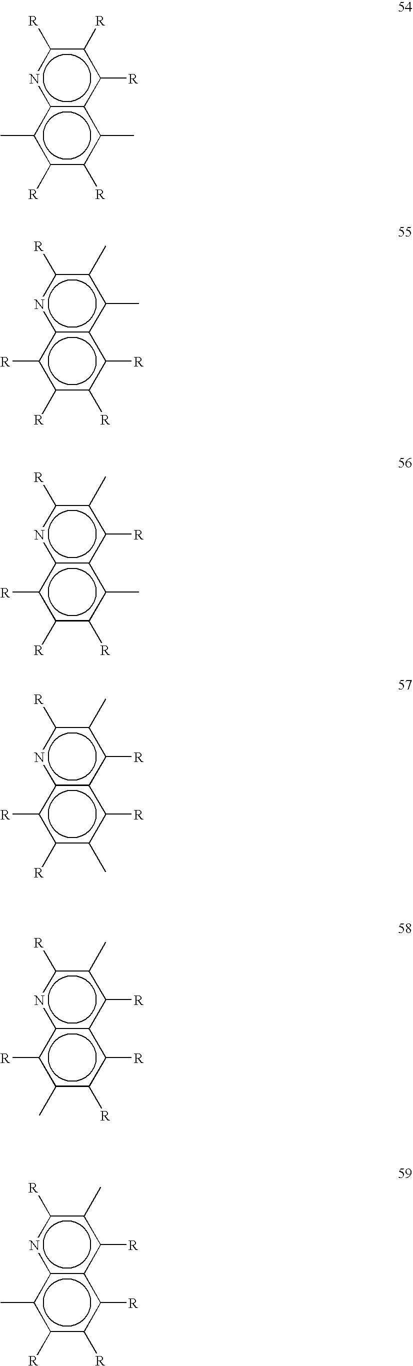

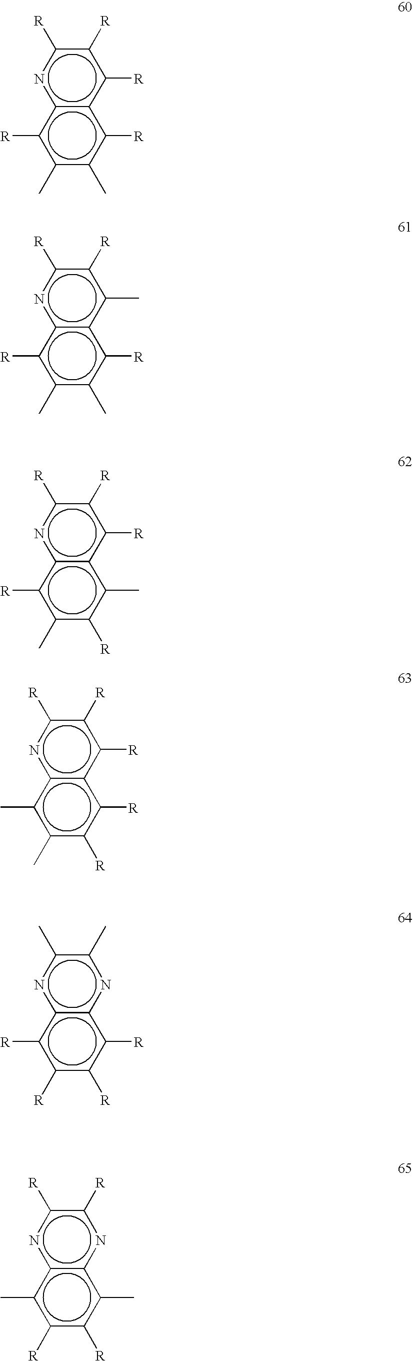

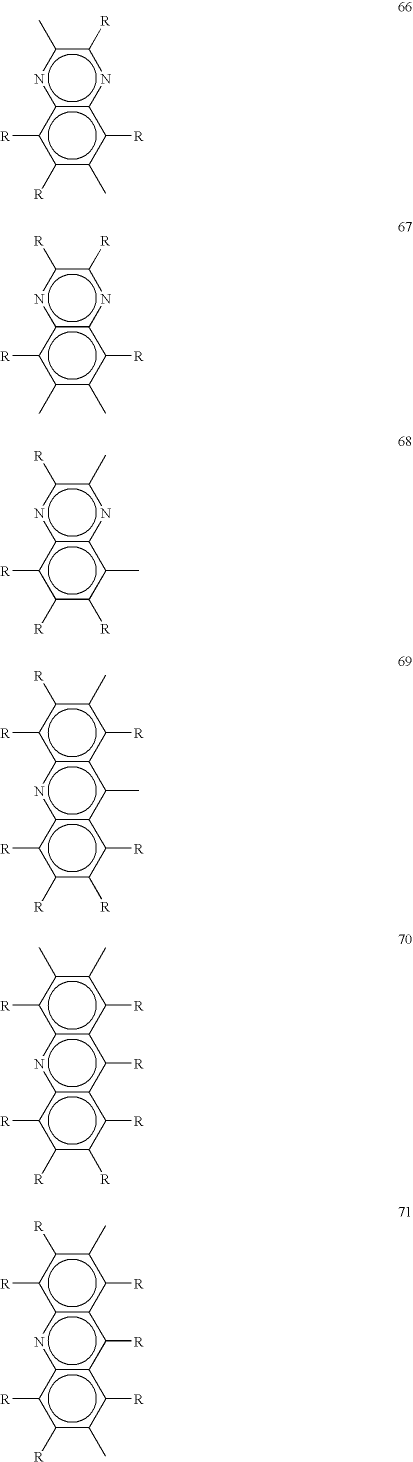

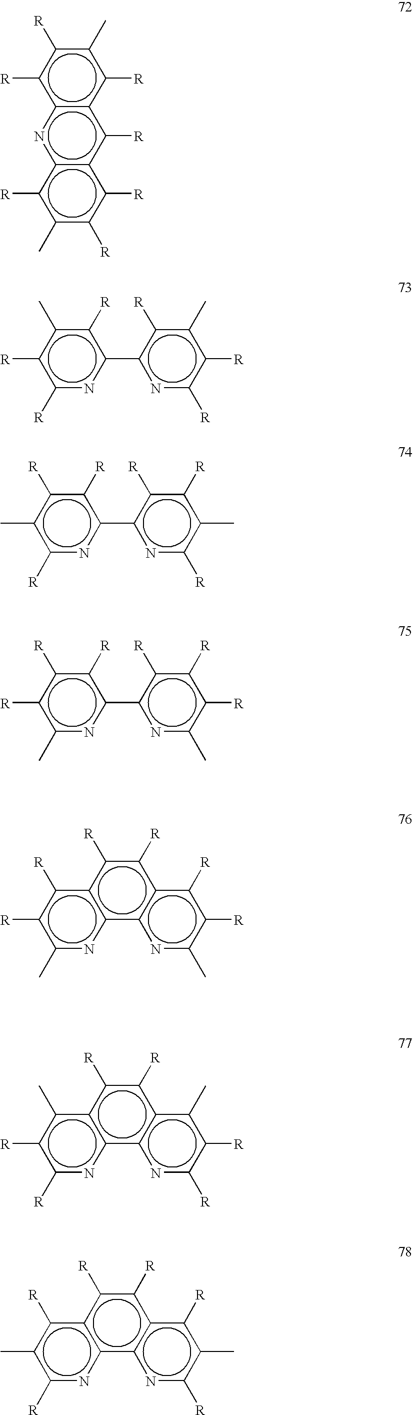

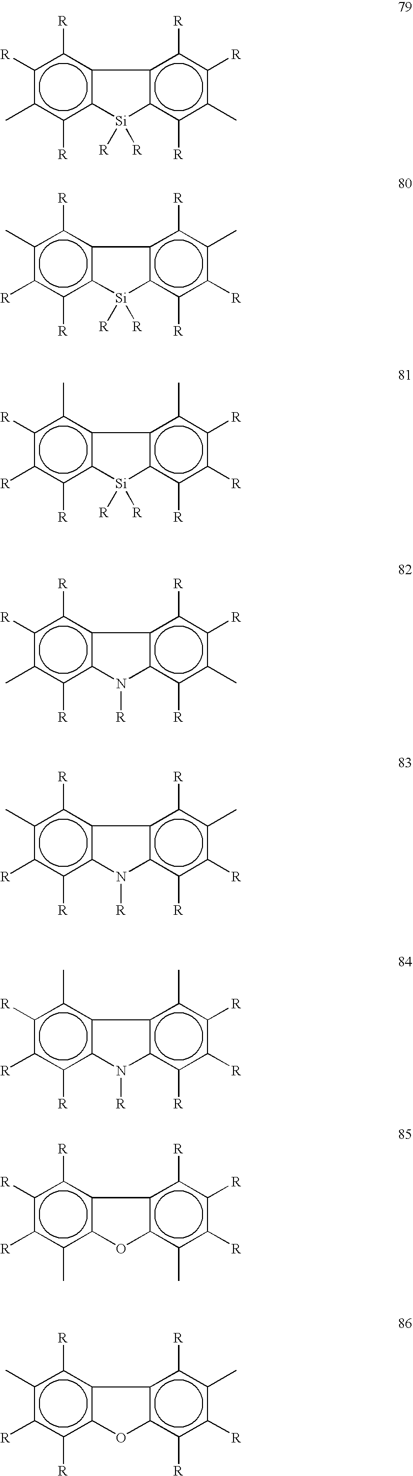

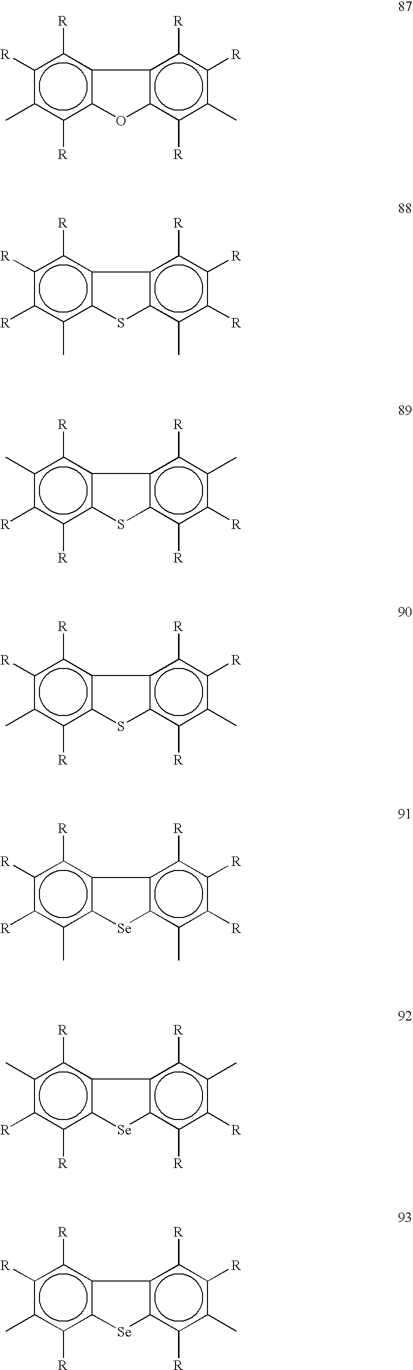

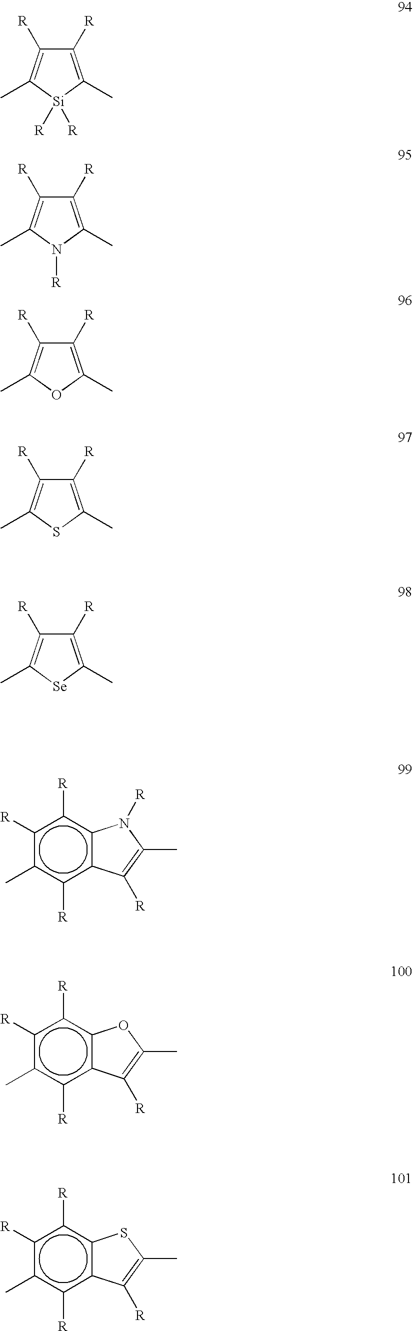

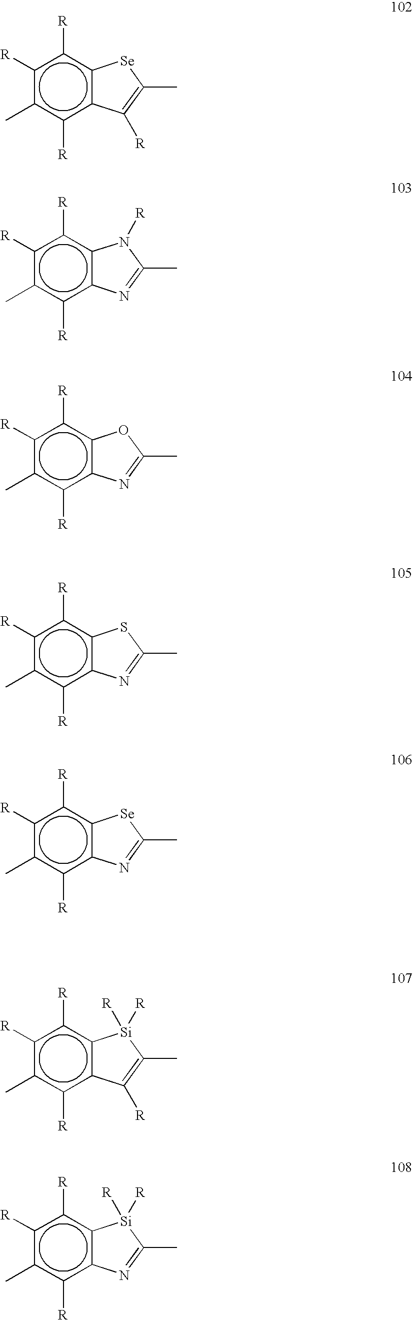

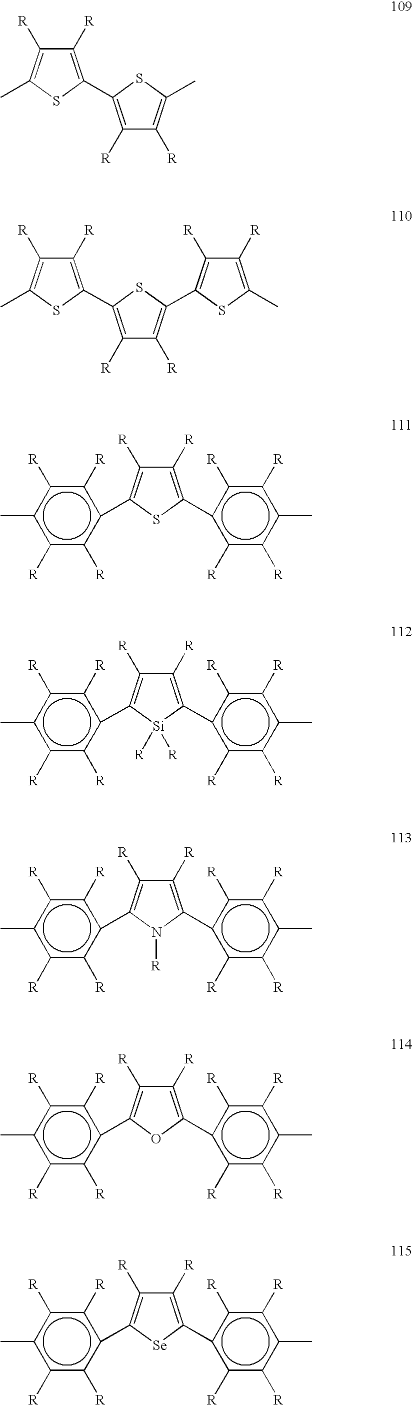

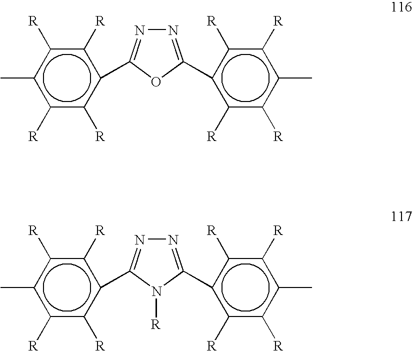

Of them, a dibenzofuran-diyl group (the aforementioned formulas 85-87) and a dibenzothiophene-diyl group (the aforementioned formulas 88 to 90) are preferable.

In the aforementioned formulas 39 to 117, R is defined as the same as above.

In the aforementioned formula (1), the divalent aromatic amine group refers to the remaining atomic group when two hydrogen atoms are removed from an aromatic amine and has generally about 4 to 60 carbon atoms in which the number of carbon atoms of a substituent is not included. Examples of the divalent aromatic amine group include the groups represented by the following general formula (50),

—Ar₆—N(Ar₅)—Ar₇— (50)

where Ar₆ and Ar₇ each independently represent an arylene group that may have a substituent; a group represented by the following general formula (4) or a group represented by the following general formula (5); Ar₅ represents an aryl group that may have a substituent, a group represented by the following general formula (6) or a group represented by the following general formula (7); and furthermore, a ring may be formed between Ar₆ and Ar₅, Ar₅ and Ar₆, or Ar₆ and Ar₇,

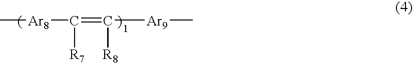

where Ar₈ and Ar₉ each independently represent an arylene group that may have a substituent; R₇ and R₈ each independently represent a hydrogen atom, an alkyl group, aryl group, monovalent heterocyclic group or cyano group; and l is 0 or 1,

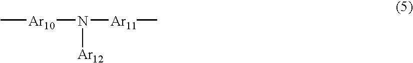

where Ar₁₀ and Ar₁₁ each independently represent an arylene group that may have a substituent; Ar₁₂ represents an aryl group that may have a substituent; and furthermore, a ring may be formed between Ar₁₀ and Ar₁₂, Ar₁₀ and Ar₁₁, or Ar₁₁ and Ar₁₂,

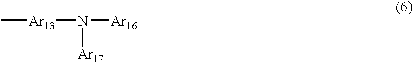

where Ar₁₃ represents an arylene group that may have a substituent; Ar₁₆ and Ar₁₇ each independently represent an aryl group that may have a substituent; and furthermore, a ring may be formed between Ar₁₃ and Ar₁₆, Ar₁₃ and Ar₁₇, or Ar₁₆ and Ar₁₇,

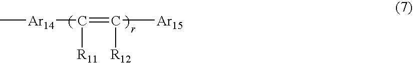

where Ar₁₄ represents an arylene group that may have a substituent; Ar₁₅ represents an aryl group that may have a substituent; R₁₁ and R₁₂ each independently represent a hydrogen atom, an alkyl group, aryl group, monovalent heterocyclic group or cyano group; and r is 0 or 1.

Ar₈ and Ar₉ of the aforementioned formula (4), Ar₁₀ and Ar₁₁ of the formula (5), Ar₁₃ of the formula (6) and Ar₁₄ of the formula (7) may have a substituent such as an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group.

Furthermore, Ar₅ of the aforementioned formula (50), Ar₁₂ of the formula (5), Ar₁₆ and Ar₁₇ of the formula (6) and Ar₁₅ of the formula (7) may have a substituent such as an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group.

Specific examples of the divalent aromatic amino group include the following groups.

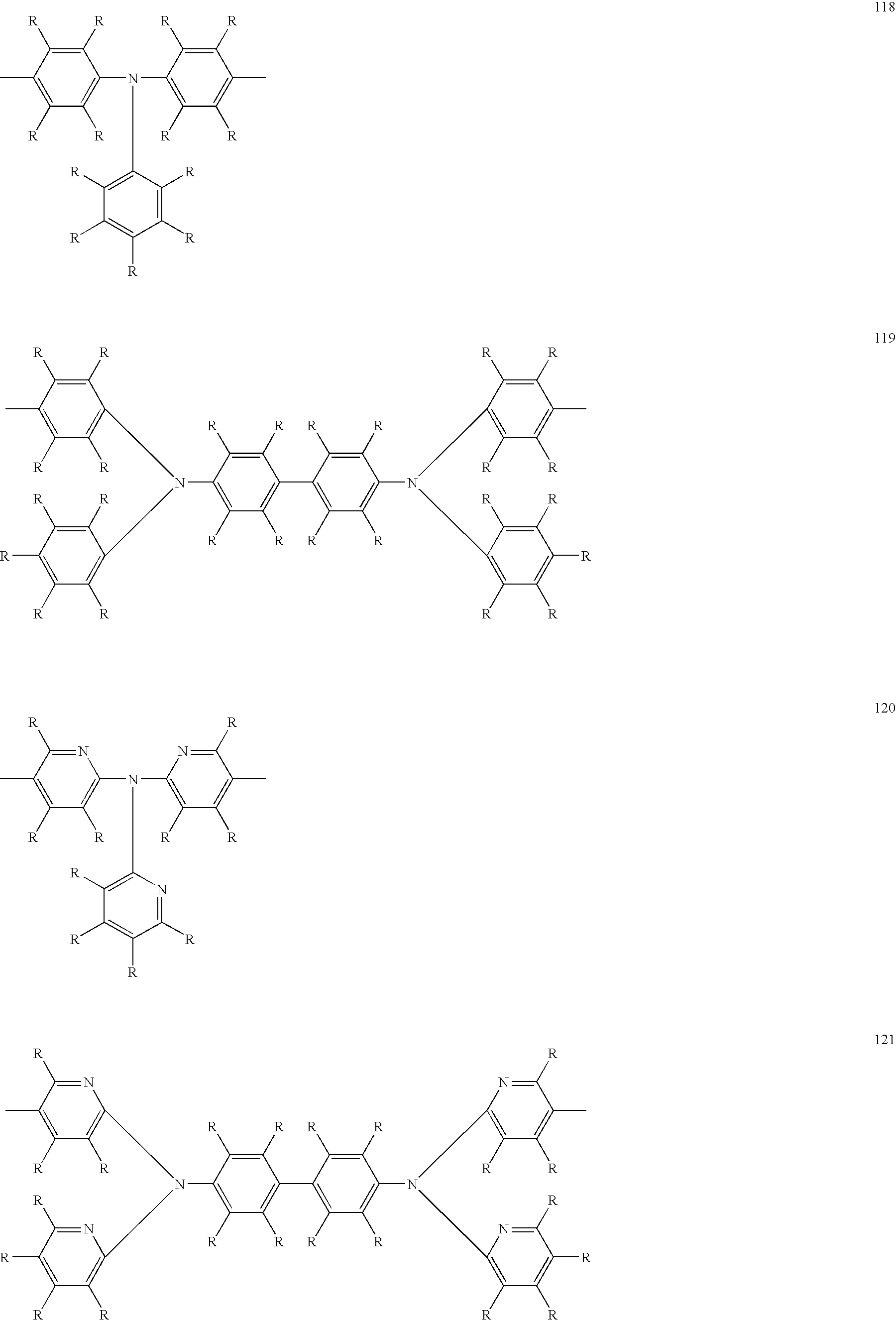

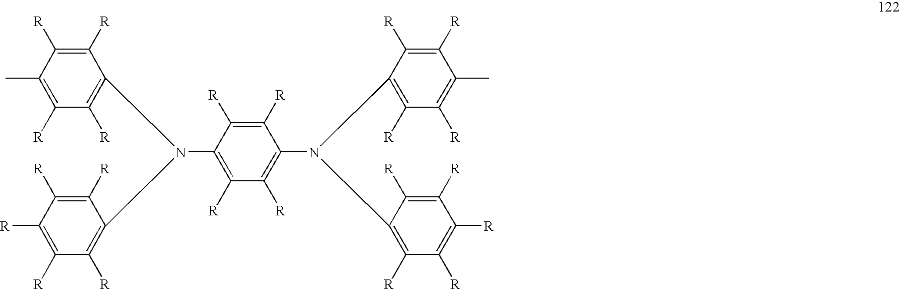

In the aforementioned formulas 118 to 122, R is defined as the same as above.

In a polymer compound according to the present invention, in view of fluorescent intensity and heat resistance of the polymer compound, the arylene group is preferably represented by the following formula (1-1) or (1-2) and particularly preferably represented by the following formula (1-3) or (1-4),

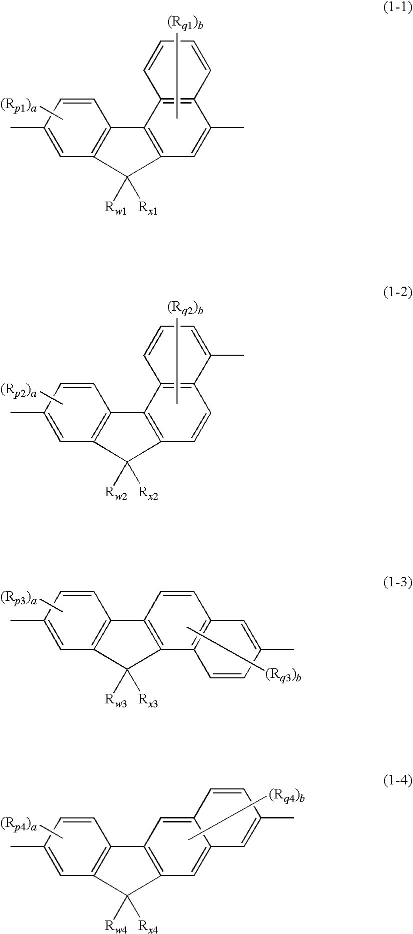

where Rₚ₁, R_{q1}, Rₚ₂, R_{q2}, Rₚ₃, R_{q3}, Rₚ₄ and R_{q4} each independently represent a group represented by the aforementioned formula (2), a group represented by the aforementioned formula (3), an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group; a represents an integer from 0 to 3; b represents an integer from 0 to 5; when a plurality of groups represented by Rₚ₁, R_{q1}, Rₚ₂, R_{q2}, Rₚ₃, R_{q3}, Rₚ₄ and R_{q4} are present, they may be the same or different; R_{w1}, Rₓ₁, R_{w2}, Rₓ₂, R_{w3}, Rₓ₃, R_{w4} and Rₓ₄ each independently represent a hydrogen atom, an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group or cyano group; and R_{w1} and Rₓ₁, R_{w2} and Rₓ₂, R_{w3} and Rₓ₃, and R_{w4} and Rₓ₄ each of the pairs may mutually join to form a ring.

In the aforementioned formulas (1-1), (1-2), (1-3) and (1-4), in view of solubility to an organic solvent, device characteristics, easiness of synthesis for a polymer compound and fluorescent intensity, each of Rₚ₁, R_{g1}, Rₚ₂, R_{q2}, Rₚ₃, R_{q3}, Rₚ₄ and R_{q4} is preferably a group represented by the aforementioned formula (2) and a group represented by the aforementioned formula (3), an alkyl group, an alkoxy group, an aryl group, an aryloxy group, an arylalkyl group, or an arylalkoxy group; and more preferably an alkyl group, an alkoxy group, or an aryl group.

In the aforementioned formulas (1-1), (1-2), (1-3) and (1-4), in view of solubility to an organic solvent, device characteristics, easiness of synthesis for a polymer compound and fluorescent intensity, each of R_{w1}, Rₓ₁, R_{w2}, Rₓ₂, R_{w3}, Rₓ₃, R_{w4} and Rₓ₄ is preferably an alkyl group, alkoxy group, aryl group, aryloxy group, arylalkyl group, or an arylalkoxy group; and more preferably, an alkyl group or an aryl group.

Examples of the alkyl group, alkoxy group and aryl group include straight, branched or cyclic alkyl groups having generally about 1 to 20 carbon atoms such as a methyl group, ethyl group, propyl group, isopropyl group, butyl group, isobutyl group, t-butyl group, pentyl group, isoamyl group, hexyl group, cyclohexyl group, heptyl group, cyclohexylmethyl group, octyl group, 2-ethylhexyl group, nonyl group, decyl group, 3,7-dimethyloctyl group, lauryl group, trifluoromethyl group, pentafluoroethyl group, perfluorobutyl group, perfluorohexyl group, and perfluorooctyl group; alkoxy groups having generally about 1 to 20 carbon atoms such as a methoxy group, ethoxy group, propyloxy group, isopropyloxy group, butoxy group, isobutoxy group, t-butoxy group, pentyloxy group, hexyloxy group, cyclohexyloxy group, heptyloxy group, cyclohexylmethyloxy group, octyloxy group, 2-ethylhexyloxy group, nonyloxy group, decyloxy group, 3,7-dimethyloctyloxy group, lauryloxy group, trifluoromethoxy group, pentafluoroethoxy group, perfluorobutoxy group, perfluorohexyl group, perfluorooctyl group, methoxymethyloxy group, and 2-methoxyethyloxy group; and aryl groups having generally about 6 to 60 carbon atoms such as a phenyl group, C₁-C₁₂ alkoxyphenyl group, C₁-C₁₂ alkylphenyl group, 1-naphthyl group, 2-naphthyl group, 1-anthracenyl group, 2-anthracenyl group, 9-anthracenyl group and pentafluorophenyl group.

Specific examples of the C₁-C₁₂ alkoxy include methoxy, ethoxy, propyloxy, isopropyloxy, butoxy, isobutoxy, t-butoxy, pentyloxy, hexyloxy, cyclohexyloxy, heptyloxy, octyloxy, 2-ethylhexyloxy, nonyloxy, decyloxy, 3,7-dimethyloctyloxy and lauryloxy. Specific examples of the C₁-C₁₂ alkylphenyl group include a methylphenyl group, ethylphenyl group, dimethylphenyl group, propylphenyl group, mesityl group, methylethylphenyl group, isopropylphenyl group, butylphenyl group, isobutylphenyl group, t-butylphenyl group, pentylphenyl group, isoamylphenyl group, hexylphenyl group, heptylphenyl group, octylphenyl group, nonylphenyl group, decylphenyl group and dodecylphenyl group.

Examples of the groups represented by the aforementioned formulas (1-1), (1-2), (1-3) and (1-4), in which R_{w1} and Rₓ₁, R_{w2} and Rₓ₂, R_{w3} and Rₓ₃, and R_{w4} and Rₓ₄ each of the pairs mutually joins to form a ring include groups represented by the following groups of formulas (1-1-2), (1-2-2), (1-3-2) and (1-4-2). These may further have a substituent.

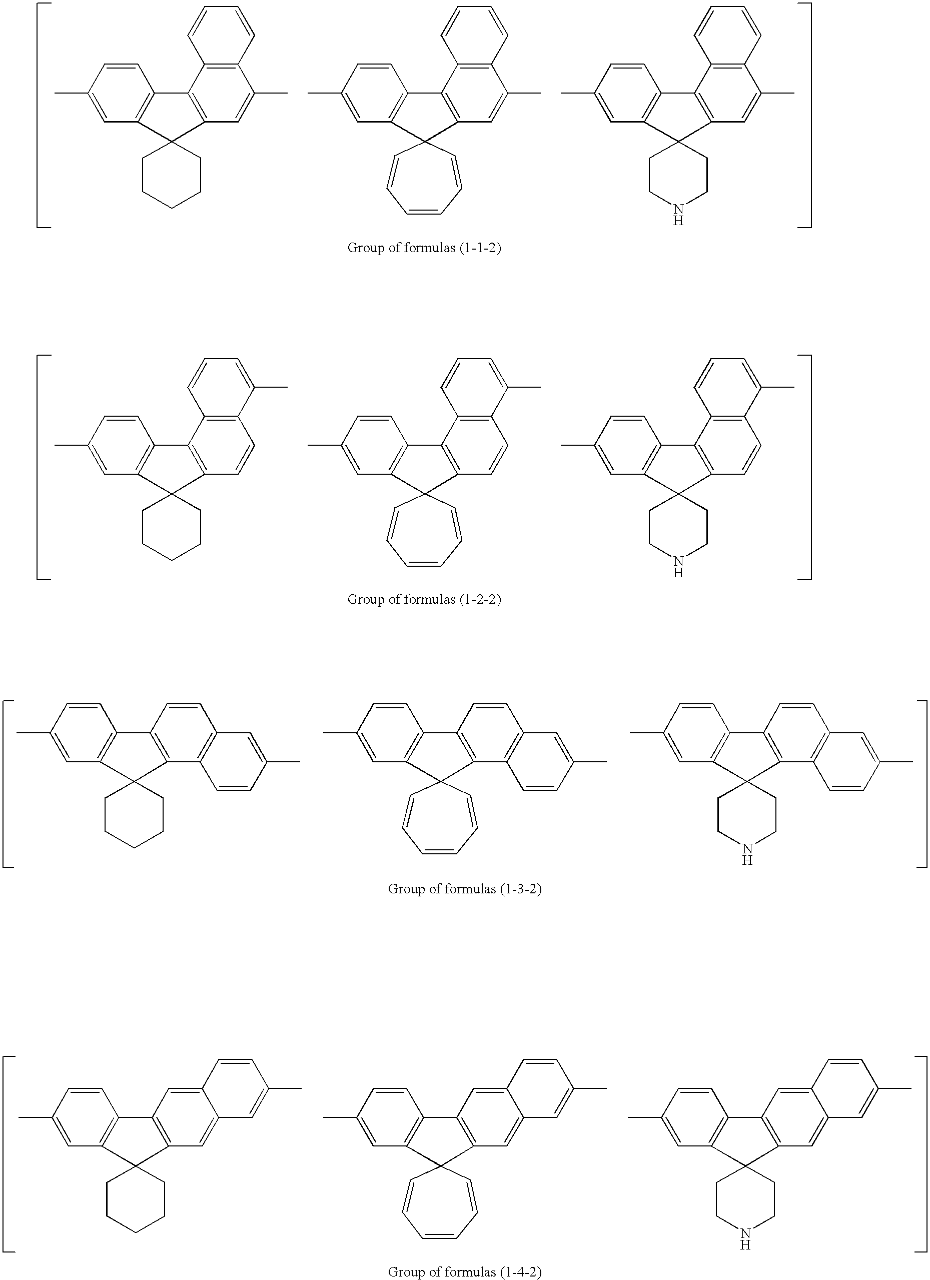

In the aforementioned formulas (1-1) and (1-2), in view of polymerization and improvement of heat resistance, a=b=0 is preferable.

Of the polymer compounds of the present invention, in view of easiness of synthesis for a monomer, polymer compounds containing groups represented by the formulas (1-1), (1-3) and (1-4) are preferable, and further preferably, polymer compounds containing a group represented by the formula (1-1).

In view of improving solubility of a synthesized polymer compound to an organic solvent in balance with heat resistance, R_{w1} and Rₓ₁ are each preferably an alkyl group, further preferably an alkyl group having 3 or more carbon atoms, more preferably having 7 or more carbon atoms and further preferably having 8 or more; and most preferably, an n-octyl group, which has a structure represented by the following formula (80).

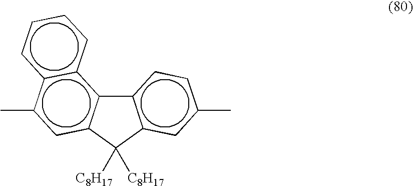

Furthermore, in view of easiness of synthesis for a polymer compound and fluorescent intensity, a divalent heterocyclic group is particularly preferably represented by the following formula (70):

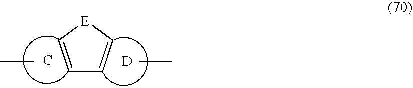

where ring C and ring D each independently represent an aromatic ring; ring C and ring D may have a substituent selected from the group consisting of a group represented by the aforementioned formula (2), a group represented by the aforementioned formula (3), an alkyl group, an alkoxy group, an alkylthio group, an alkylsilyl group, an alkylamino group, an aryl group, an aryloxy group, an arylalkyl group, an arylalkoxy group, an arylalkenyl group, an arylalkynyl group, an arylamino group, a monovalent heterocyclic group and a cyano group; when a plurality of substituents are present, they may be the same or different; and E is O or S.

As an example of the group represented by the aforementioned formula (70), mention may be made of any one of the groups represented by the following formulas (2a) to (2d):

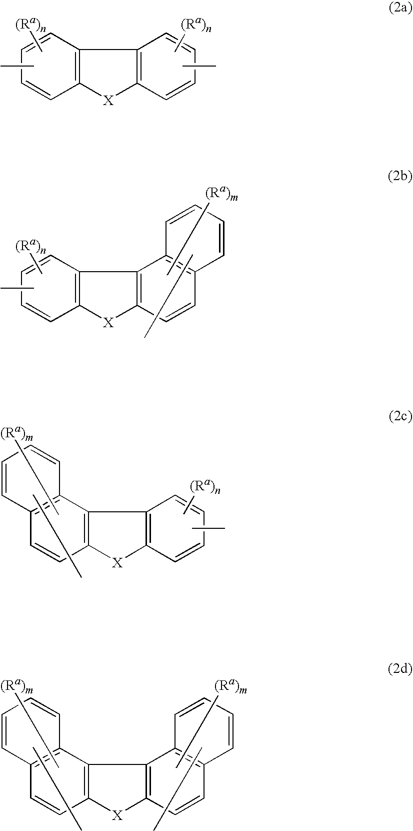

where X represents O or S; R^{a} represents a substituent; m independently represents an integer from 0 to 5; n independently represents an integer from 0 to 3. When a plurality of substituents represented by R^{a} are present, they may be the same or different.

Examples of the substituent represented by R^{a} are the same as those exemplified as the aforementioned substituents represented by R. In view of solubility of a polymer compound, m is preferably an integer from 1 to 3 and n is preferably an integer of 1 or 2.

The group represented by the aforementioned formula (2a) is preferably a group represented by the following formula (2E) in view of easiness of synthesis for a polymer compound and fluorescent intensity,

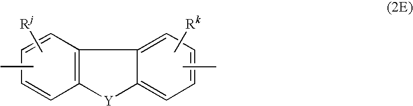

where Y represents O or S; R^{j} and R^{k} each independently represent a group represented by the aforementioned formula (2), a group represented by the aforementioned formula (3), a hydrogen atom, an alkyl group, an alkoxy group or an aryl group.

In the aforementioned formula (2E), R^{J} and R^{k} are preferably the same in view of easiness of synthesis for a polymer compound (more specifically, both of them are hydrogen atoms, alkyl groups, alkoxy groups, or aryl groups) and more preferably, alkoxy groups. Examples of the alkyl groups and aryl groups represented by R^{J} and R^{k} are the same as those exemplified as a substituent represented by R. Examples of the alkoxy groups represented by R^{J} and R^{k}, in view of solubility and fluorescent intensity of a polymer compound, preferably include a butoxy group, i-butoxy group, t-butoxy group, pentyloxy group, hexyloxy group, heptyloxy group, octyloxy group, 2-ethylhexyloxy group, nonyloxy group, decyloxy group, 3,7-dimethyloctyloxy group and lauryloxy group; and further preferably, include a pentyloxy group, hexyloxy group, octyloxy group, 2-ethylhexyloxy group, decyloxy group and 3,7-dimethyloctyloxy group.

Examples of a repeat unit represented by the aforementioned formula (70) include a group represented by

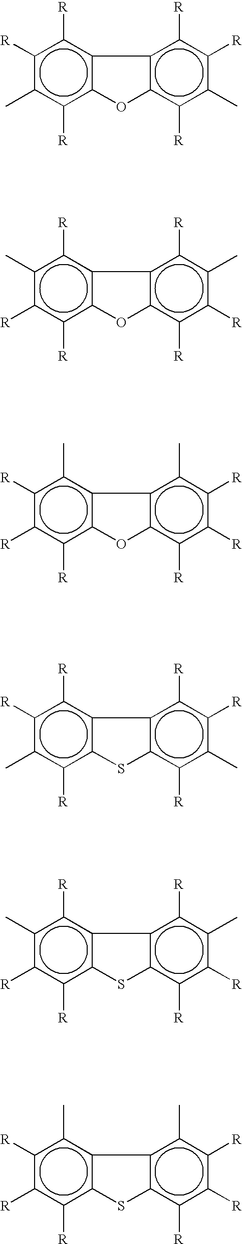

where R each independently represent a hydrogen atom, a group represented by the aforementioned formula (2), a group represented by the aforementioned formula (3), an alkyl group, an alkoxy group, an alkylthio group, an alkylsilyl group, an alkylamino group, an aryl group, an aryloxy group, an arylalkyl group, an arylalkoxy group, an arylalkenyl group, an arylalkynyl group, an arylamino group, a monovalent heterocyclic group or a cyano group; and, in view of heat resistance of a polymer compound or polymerization thereof, preferably a group represented by

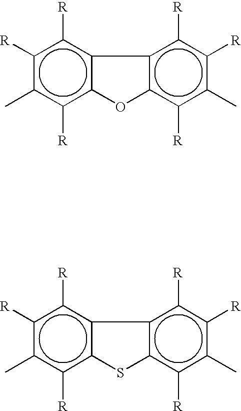

where R is defined as the same as above.

In the above formula, a single structural formula has a plurality of Rs. They may be the same or different. Examples of a group represented by R in the formula are the same as those exemplified as substituents represented by R.

In the aforementioned formula (1), Z′ represents —C(R₄)═C(R₅)—, or —C≡C— where R₄ and R₅ each independently represent a hydrogen atom, an alkyl group, aryl group, monovalent heterocyclic group or cyano group. In view of stability, —C(R₄)═C(R₅)— is preferable.

Preferable examples of the repeat units where Z′ is —C(R₄)═C(R₅)— include those represented by the following formulas 128 to 135:

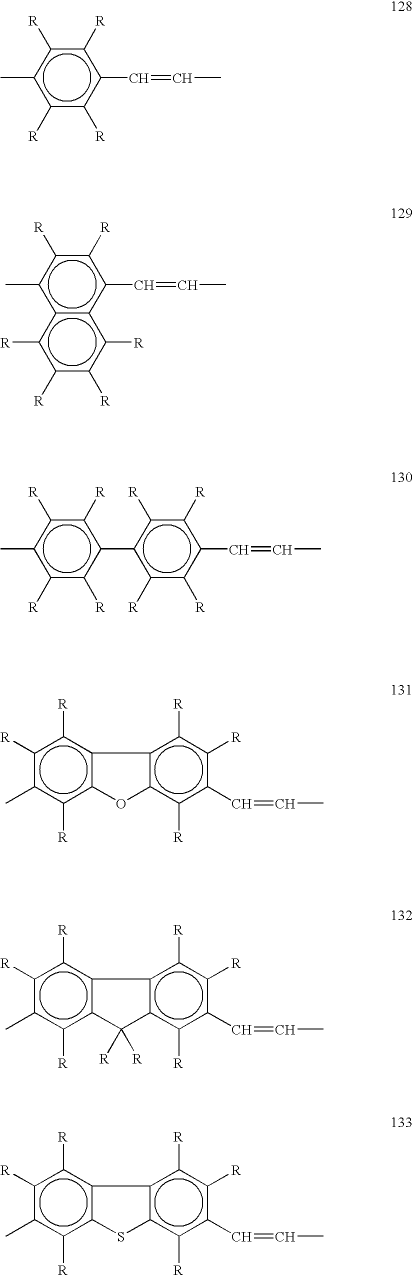

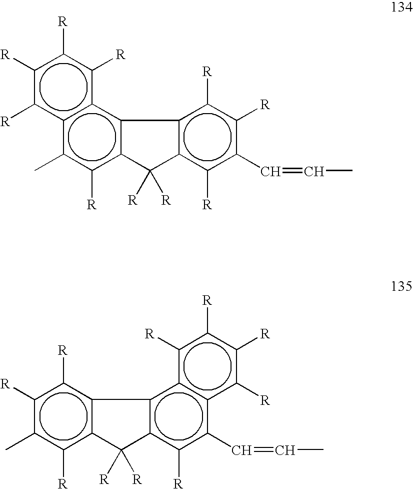

where R is defined as the same as above.

Reference symbol p is 0 or 1. In view of photooxidation stability, p is preferably 0.

In the aforementioned formula (2), A₁ represents —O—, —S— or —C(O)—.

In the aforementioned formula (2), Ar⁰¹ represents a direct bond, an arylene group, a divalent heterocyclic group or a divalent aromatic amine group. The arylene group, divalent heterocyclic group or divalent aromatic amine group is defined as the same as above.

In the aforementioned formula (2), R⁰⁵ represents a direct bond, —R₁—, *—O—R₁—, *—R₁—O—, *—R₁—C(O)O—, *—R₁—OC(O)—, *—R¹—N(R₂₀)—, —O—, —S—, *—C(O)O— or —C(O)— (where * represents a site for bonding to Ar⁰¹); R⁰⁷ represents a direct bond, —R₁—, —O—R₁—*, —R₁—O—*, —R₁—C(O)O —*, —R₁—OC(O)—*, —R₁—N(R₂₀)—*, —O—, —S—, —C(O)O—* or —C(O)— (where * represents a site for bonding to Ar⁰¹). R₁ represents an alkylene group or an alkenylene group. R₂₀ represents a hydrogen atom, an alkyl group, aryl group, monovalent group or cyano group. In view of easiness of synthesis and stability, R⁰⁵ is preferably a direct bond, —R₁— or *—O—R₁—, and R⁰⁷ is preferably a direct bond, —R₁— or —R₁—O—*.

In the aforementioned formula (2), R⁰¹ and R⁰² are each independently a substituent. Examples of the substituent include an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group and cyano group.

Reference symbols a and b are each independently an integer from 0 to 4 and a plurality of substituents represented by R⁰¹ and R⁰² may be the same or different.

Specific examples of the group represented by the aforementioned formula (2) include those shown below,

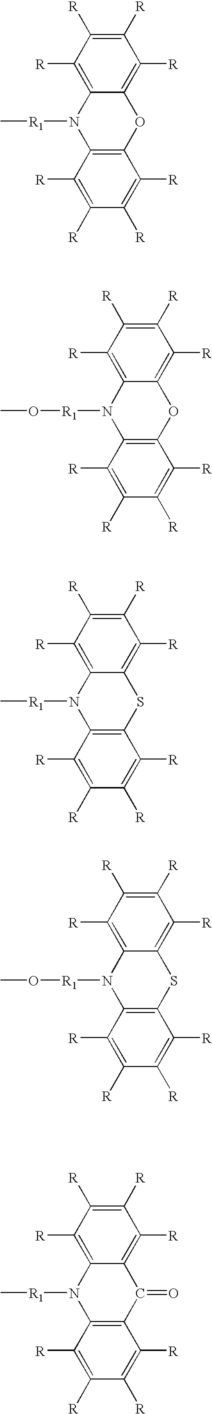

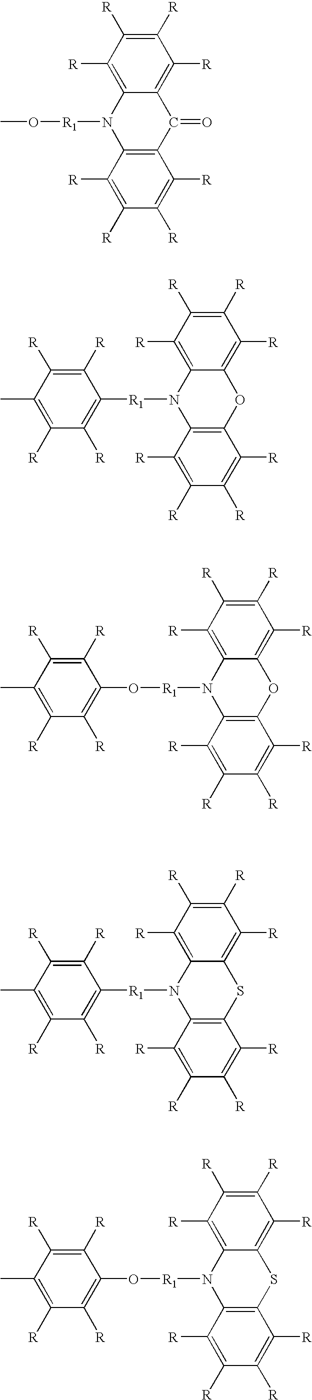

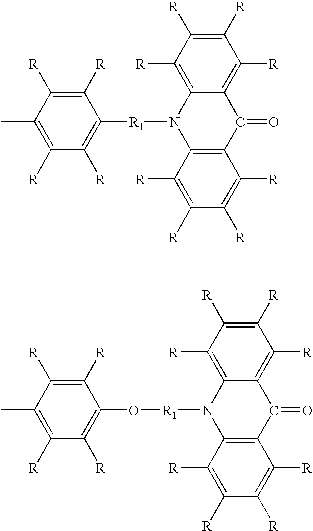

where R is defined as the same as in R⁰¹. R₁ is defined as the same as above.

In the aforementioned formula (3), B₁ represents —O—, —S— or —C(O)—.

In the aforementioned formula (3), Ar⁰² represents a hydrogen atom, an aryl group, a monovalent heterocyclic group or a monovalent aromatic amine group.

The aryl group herein has generally about 6 to 60 carbon atoms. Specific examples thereof include a phenyl group, C₁-C₁₂ alkoxyphenyl group (C₁-C₁₂ represents 1 to 12 carbon atoms and hereinafter the same definition will be used), C₁-C₁₂ alkylphenyl group, 1-naphthyl group and 2-naphthyl group. Of them, C₁-C₁₂ alkoxyphenyl group and C₁-C₁₂ alkylphenyl group are preferable.

The monovalent heterocyclic group refers to the remaining atomic group when a single hydrogen atom is removed from a heterocyclic group and having generally about 2 to 60 carbon atoms.

Examples of the monovalent heterocyclic group include those mentioned below.

monovalent heterocyclic groups containing nitrogen as a hetero atom such as a pyridinyl group, diazaphenyl group, quinolinyl group, quinoxalinyl group, acridinyl group, bipyridinyl group and phenanthroline-yl group;

groups containing a hetero atom such as silicon, nitrogen, sulfur, selenium or oxygen and having a fluorene structure (groups having rings and represented by the aforementioned formulas 79 to 93);

5-membered heterocyclic groups containing a hetero atom such as silicon, nitrogen, sulfur, selenium or oxygen (groups having a ring and represented by the aforementioned formulas 94 to 98);

5-membered condensed heterocyclic groups containing a hetero atom such as silicon, nitrogen, sulfur, selenium or oxygen (groups having rings represented by the aforementioned formulas 99 to 108);

dimers or oligomers of 5-membered heterocyclic groups containing a hetero atom such as sulfur and joined at the α-position of the hetero atom (groups having rings represented by the aforementioned formulas 109 and 110); and

5-membered heterocyclic group containing a hetero atom such as silicon, nitrogen, sulfur, selenium or oxygen and joined to phenyl groups at the α-position of the hetero atom (groups having rings represented by the aforementioned formulas 111 to 117).

The monovalent aromatic amine group refers to the remaining atomic group when a single hydrogen atom is removed from an aromatic amine and having generally about 4 to 60 carbon atoms, in which the number of carbon atoms of a substituent is not included. Examples of the monovalent aromatic amine group include groups represented by the following formulas 123 to 127,

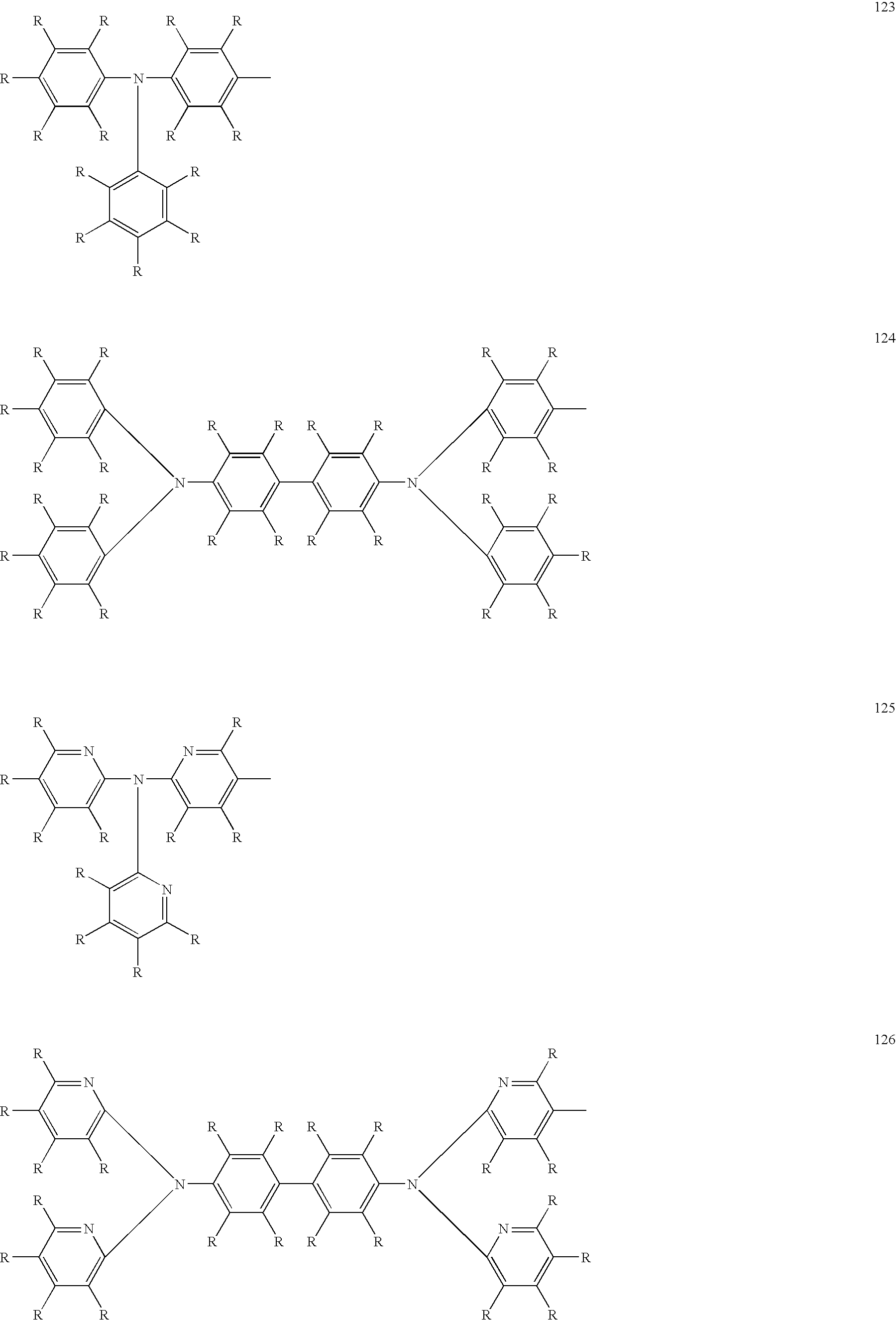

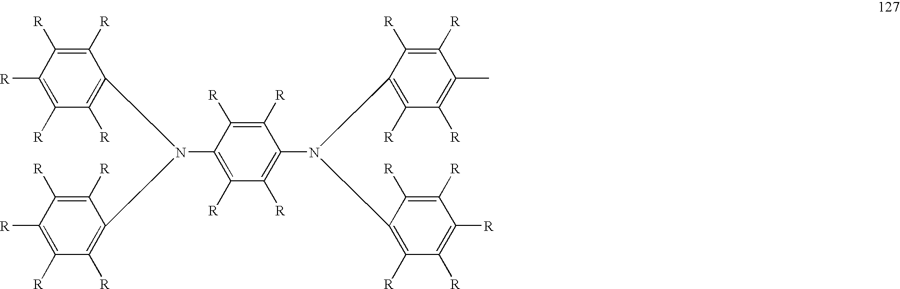

where R is defined as the same as in R⁰¹.

In the aforementioned formula (3), R⁰⁶ represents a direct bond, —R₁—, —O—R₁—*, —R₁—O—*, —R₁—C(O)O—*, —R₁—OC(O)—*, —R₁—N(R₂₀)—*, —O—, —S—, —C(O)O—* or —C(O)— (where * represents a site for bonding to Ar⁰²); R¹ represents an alkylene group or an alkenylene group; and R₂₀ represents a hydrogen atom, an alkyl group, aryl group, monovalent group or cyano group. In view of easiness of synthesis and stability, R⁰⁶ is preferably a direct bond, —R₁— or —R₁—O—*.

R⁰⁸ represents a direct bond, —R₁—, *—O—R₁—, *—R₁—O—, *—R₁—C(O)O—, *—R₁—OC(O)—, *—R₁—N(R₂₀)—, —O—, —S—, *—C(O)O— or —C(O)— (where * represents a site for bonding to Ar⁰³); and R⁰⁹ represents a direct bond, —R₁—, —O—R₁—*, —R₁—O—*, —R₁—C(O)O—*, —R₁—OC(O)—*, —R₁—N(R₂₀)—*, —O—, —S—, —C(O)O—* or —C(O)— (where * represents a site for bonding to Ar⁰³). R¹ represents an alkylene group or an alkenylene group. R₂₀ represents a hydrogen atom, an alkyl group, aryl group, monovalent group or cyano group. In view of easiness of synthesis and stability, R⁰⁸ is preferably a direct bond, —R₁— or *—R₁—O—, and R⁰⁹ is preferably a direct bond, or —R₁— or —R₁—O—*.

R⁰³ and R⁰⁴ are each independently a substituent. Examples of the substituent include an alkyl group, alkoxy group, alkylthio group, alkylsilyl group, alkylamino group, aryl group, aryloxy group, arylalkyl group, arylalkoxy group, arylalkenyl group, arylalkynyl group, arylamino group, monovalent heterocyclic group and cyano group.

Reference symbol c is an integer from 0 to 4 and d is an integer from 0 to 3. A plurality of substituents represented by R⁰³ and R⁰⁴ may be the same or different.

Specific examples of the group represented by the aforementioned formula (3) include those shown below,

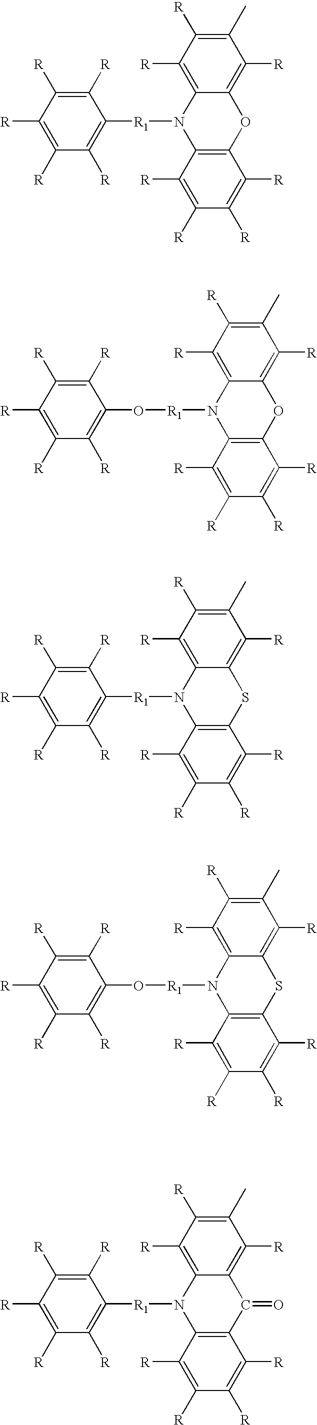

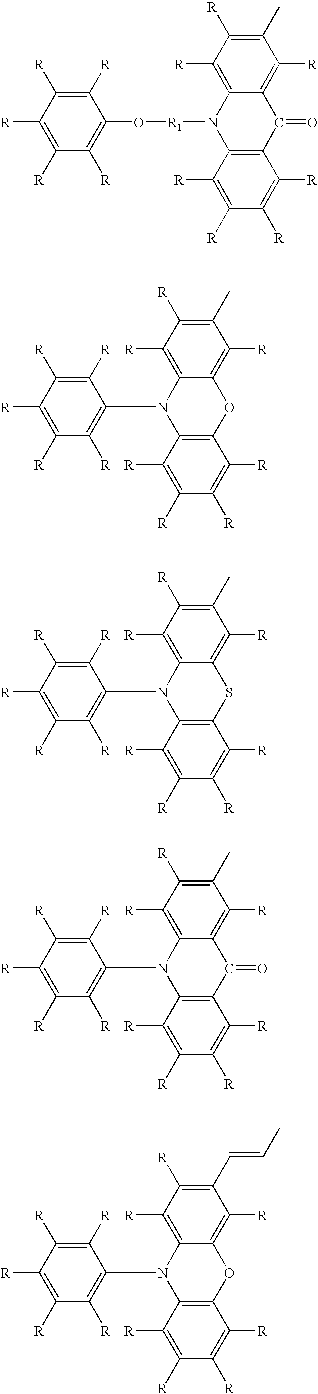

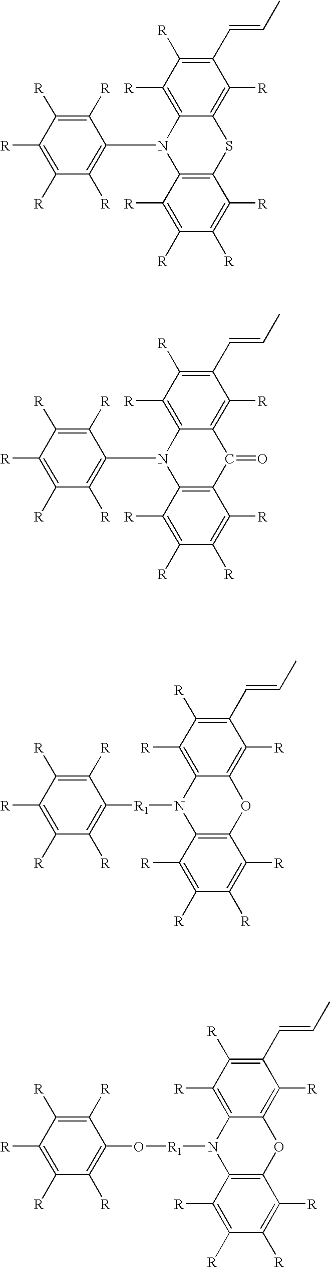

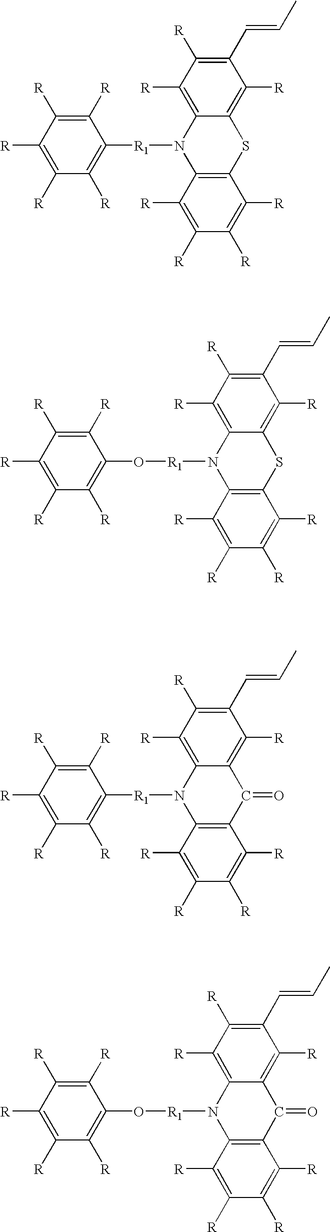

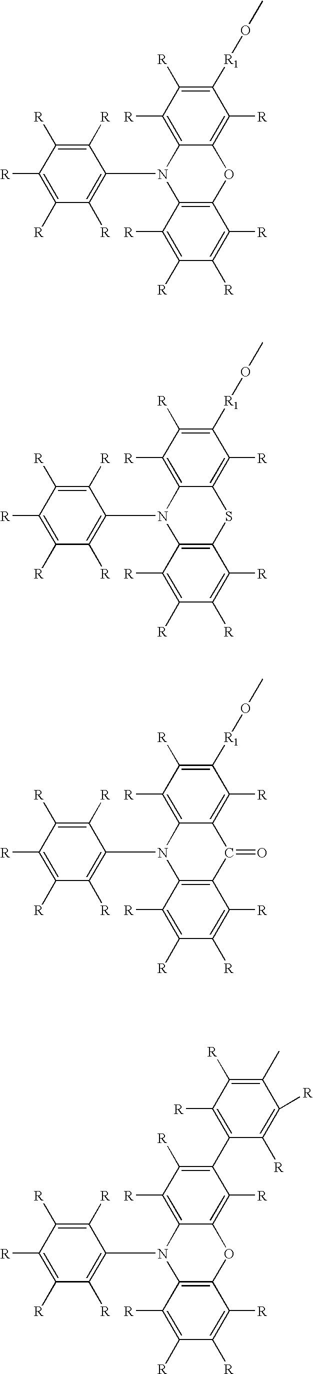

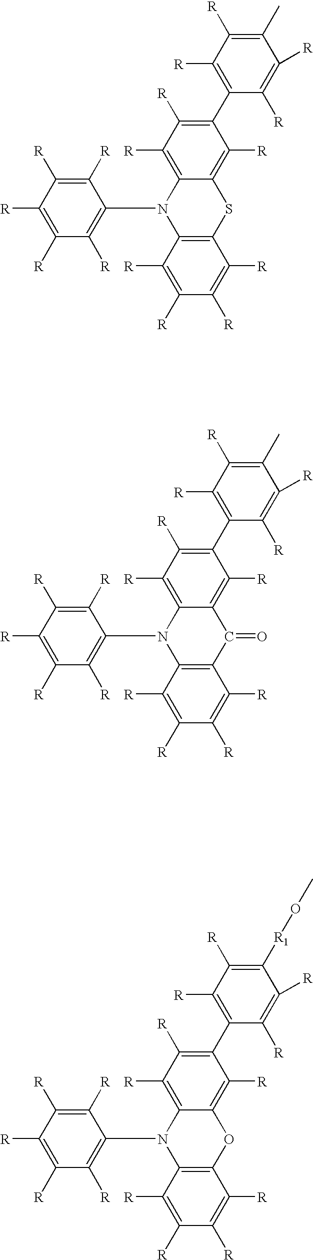

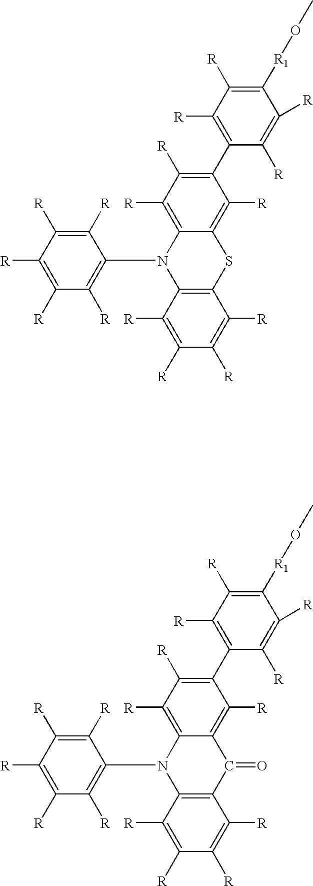

where R is defined as the same as in R⁰³. R₁ is defined as the same as above.

Of the polymer compounds of the present invention, those having a repeat unit represented by the following formula (30) are preferable in view of solubility and fluorescent intensity.

—Ar₄—(Z)ₜ— (30)

Ar₄ of the aforementioned formula (30) represents an arylene group, divalent heterocyclic group or divalent aromatic amine group. Examples of Ar₄ are the same as those exemplified in Ar₁. However, the examples of Ar₄ include none of those represented by the aforementioned formulas (2) and (3).

In the formula (30), Z represents —CR₇═CR₈— or —C≡C—. R₇ and R₈ each independently represent a hydrogen atom, an alkyl group, aryl group, monovalent heterocyclic group or cyano group and t represents 0 or 1. In view of stability, —CR₇═CR₈— is preferable. In view of photooxidation stability, t is more preferably 0.

Specific examples of the repeat unit represented by the formula (30) preferably include the structures represented by the aforementioned formulas 1 to 117, A to F, 118 to 122 and the following formulas 128 to 133. Of them, preferable examples include a phenylene group (for example, the aforementioned formulas 1 to 3), a naphthalene-diyl group (the aforementioned formulas 4 to 13), an anthracenylene group (the aforementioned formulas 14 to 19), a biphenylene group (the aforementioned formulas 20 to 25), a triphenylene group (the aforementioned formulas 26 to 28), a condensed ring compound group (the aforementioned formulas 29 to 38), a dibenzofuran-diyl group (the aforementioned formulas 85 to 87), a dibenzothiophene-diyl group (the aforementioned formulas 88 to 90), a stilbene-diyl group, a distilbene-diyl group, a divalent aromatic amine group (the aforementioned formulas 118, 119 and 122), an arylenevinylene group (the aforementioned formulas 128 to 133) and a benzofluorene-diyl (the aforementioned formulas G, H, I and K). Of them, particularly preferable examples thereof include a phenylene group, a biphenylene group, a fluorene-diyl group (the aforementioned formulas 36 to 38), a dibenzofuran-diyl group (the aforementioned formulas 85 to 87), a dibenzothiophene-diyl group (the aforementioned formulas 88 to 90), a stilbene-diyl group, a distilbene-diyl group, a benzofluorene-diyl group (the aforementioned formulas G, H, I and K) and divalent aromatic amine group,

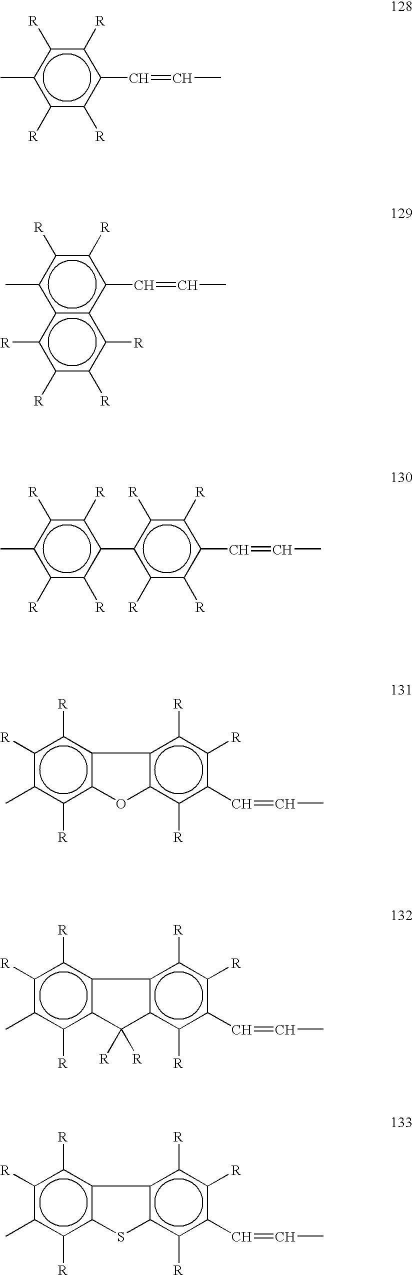

where R is defined as the same as above. However, the groups represented by the aforementioned formulas (2) and (3) are not included.

A polymer compound according to the present invention may have at least one of the groups represented by the aforementioned formulas (2) and/or (3) as a substituent(s) of Ar₁ of the aforementioned formula (1) constituting the main chain of the polymer, i.e., substituent (s) of an arylene group, divalent heterocyclic group or divalent aromatic amine group (the number of types of substituents may be one or two or more), or as at least one of the terminal groups present at the ends of the polymer chain molecule (the number of types of terminal groups may be one or two or more).

In view of polymerization of a polymer compound, Ar₁ of the aforementioned formula (1) preferably has at least one of the groups represented by the aforementioned formulas (2) and/or (3).

Note that a polymer compound according to the present invention may have a repeat unit other than the repeat units represented by the aforementioned formulas (1) and (30) unless fluorescent properties and charge transport properties are damaged. More specifically, a polymer compound substantially formed of the repeat units represented by the formula (1) and a polymer compound substantially formed of the repeat units represented by the formulas (1) and (30) are preferable. The repeat units may be linked by vinylene or at non-conjugated moiety or may contain the vinylene and non-conjugated moiety. Examples of the linking structure containing the non-conjugated moiety include the groups shown below, combinations of the groups shown below and a vinylene group and combination of two or more of the groups shown below. R′ herein is a group selected from the same substituents as mentioned above and Ar represents a hydrocarbon group having 6 to 60 carbon atoms.

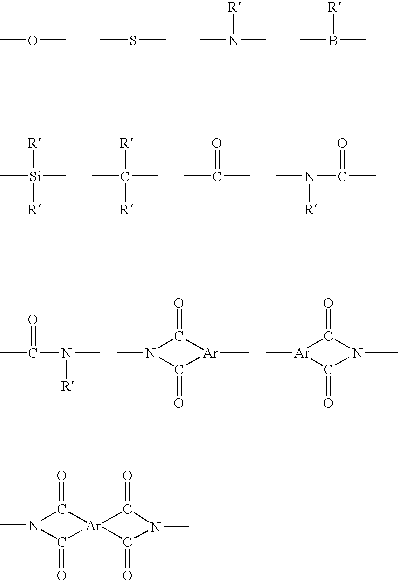

A polymer compound according to the present invention has a polystyrene-reduced number average molecular weight of 10³ to 10⁸ and preferably 3×10³ to 5×10⁶ in view of film-formability, more preferably 5×10³ to 2×10⁶ and further preferably 1×10⁴ to 1×10⁶.

A polymer compound according to the present invention preferably is fluorescent in a state of solid. A polymer compound is more preferably fluorescent in a state of solid and has a polystyrene-reduced number average molecular weight of 10³ to 10⁸.

Furthermore, a polymer compound according to the present invention may be phosphorescent.

Examples of a good solvent for a polymer compound according to the present invention include chloroform, methylene chloride, dichloroethane, tetrahydrofuran, toluene, xylene, mesitylene, decalin and n-butylbenzene. The amount of a polymer compound varies depending upon the structure and molecular weight thereof; however, the polymer compound can be generally contained in each of these solvents in an amount of 0.1 wt % or more.

A polymer compound according to the present invention may be a random, block or graft copolymer, a polymer having an intermediate structure of these, for example, a random copolymer partly having a block copolymer structure. To obtain a polymer compound having a high fluorescent quantum yield, a random copolymer partly having a block copolymer structure, a block copolymer or a graft copolymer is preferred rather than a complete random copolymer. Also, a dendrimer having a branched main chain and a dendrimer having three or more terminal portions are included.

A method for producing a polymer compound according to the present invention will be now described.

<<The case where repeat unit Ar₁ represented by the aforementioned formula (1) has a group represented by the aforementioned formula (2) or (3) (side-chain substitution) as a substituent>>

A polymer compound according to the present invention can be produced by condensation polymerization using a compound represented by the following formula as one of the materials,

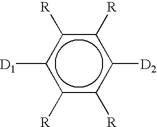

where R is a group represented by the aforementioned formula (2), a group represented by the aforementioned formula (3), a hydrogen atom, an alkyl group, an alkoxy group, an alkylthio group, an alkylsilyl group, an alkylamino group, an aryl group, an aryloxy group, an arylalkyl group, an arylalkoxy group, an arylalkenyl group, an arylalkynyl group, an arylamino group, a monovalent heterocyclic group or a cyano group. In the aforementioned case, a plurality of Rs are present. They may be the same or different. However, at least one of the Rs is a group represented by the aforementioned formula (2) or (3). D₁ and D₂ each independently represent a halogen atom, an alkylsulfonate group, arylsulfonate group, arylalkylsulfonate group, a boric acid ester group, sulfonium-methyl group, phosphonium-methyl group, phosphonate-methyl group, monohalogenated methyl group, boric acid group, formyl group, cyanomethyl group or vinyl group.

Examples of the alkylsulfonate group include a methanesulfonate group, ethanesulfonate group and trifluoromethanesulfonate group. Examples of the arylsulfonate group include a benzenesulfonate group and p-toluenesulfonate group. Examples of the arylalkylsulfonate group include a benzylsulfonate group. Examples of the boric acid ester group include the groups represented by the following formulas.

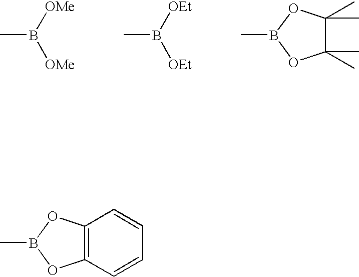

Examples of the sulfonium-methyl group include the groups represented by the following formulas:

—CH₂S⁺Me₂X⁻,

—CH₂S⁺Ph₂X⁻

(X represents a halogen atom).

Examples of the phosphonium-methyl group include the groups represented by the following formula:

—CH₂P⁺Ph₃X⁻

(X represents a halogen atom).

Examples of phosphonate-methyl group include the groups represented by the following formula:

—CH₂P(O)(OR′″)₂

(R′″ represents an alkyl group, aryl group or arylalkyl group).

Examples of the monohalogenated methyl group include a methyl fluoride group, methyl chloride group, methyl bromide group and methyl iodide group.

Examples of a condensation polymerization method include those mentioned below, with the proviso that when a main chain has a vinylene group, other monomers may be used as needed.

[1] polymerization of a compound having an aldehyde group and a compound having a phosphonium base by the Wittig reaction;

[2] polymerization of a compound having an aldehyde group and a phosphonium base by the Wittig reaction;

[3] polymerization of a compound having a vinyl group and a compound having a halogen atom by the Heck reaction;

[4] polymerization of a compound having a vinyl group and a halogen atom by the Heck reaction;

[5] polymerization of a compound having an aldehyde group and a compound having an alkylsulfonate group by the Horner-Wadsworth-Emmons method;

[6] polymerization of a compound having an aldehyde group and an alkylsulfonate group by the Horner-Wadsworth-Emmons method;

[7] condensation polymerization of a compound having two or more halogenated methyl groups by the dehalogenated hydrogen method;

[8] condensation polymerization of a compound having two or more sulfonium bases by the sulfonium salt decomposition method;

[9] polymerization of a compound having an aldehyde group and a group having an acetonitrile group by the Knoevenagel reaction;

[10] polymerization of a compound having an aldehyde group and an acetonitrile group by the Knoevenagel reaction; and

[11] polymerization of a compound having two or more aldehyde groups by the McMurry reaction.

Examples of a method for producing a polymer compound according to the present invention include

[12] a polymerization method by the Suzuki coupling reaction;

[13] a polymerization method by the Grignard reaction;

[14] a polymerization method by a Ni(0) catalyst;

[15] a polymerization method by an oxidant such as FeCl₃, a electrochemical oxidization-polymerization; and

[16] a decomposition method of an intermediate polymer having an appropriate leaving group.

As the reaction using a Ni(0) catalyst, a polymerization method in the presence of a null-valent nickel complex {Ni(COD)₂} may be mentioned.

Examples of the null-valent nickel(0) complex include bis(1,5-cyclooctadiene)nickel(0), (ethylene)bis(triphenylphosphine)nickel and tetrakis(triphenylphosphine)nickel. Of them, bis(1,5-cyclooctadiene)nickel(0) is preferable since it is commonly used and inexpensive.

Furthermore, a neutral ligand is preferably added to improve yield.

The neutral ligand used herein is a ligand having neither an anion nor a cation. Examples thereof include nitrogen-containing ligands such as 2,2′-bipyridyl, 1,10-phenanthroline, methylenebisoxazoline and N,N′-tetramethylethylenediamine; and tertiary phosphine ligands such as triphenylphosphine, tritolylphosphine, tributylphosphine and triphenoxyphosphine. A nitrogen-containing ligand is preferable since it is generally used and inexpensive and 2,2′-bipyridyl is particularly preferable in view of high reactivity and high yield. To improve the yield of a polymer, it is preferable to use a system containing bis(1,5-cyclooctadiene)nickel(0) and having 2,2′-bipyridyl added thereto as a neutral ligand.

The polymerization solvent is not particularly limited unless it inhibits polymerization. Examples thereof include an amide based solvent, an aromatic hydrocarbon based solvent, an ether based solvent and an ester based solvent.

Examples of the amide based solvent include N,N-dimethylformamide and N,N-dimethylacetamide.

Examples of the aromatic hydrocarbon based solvent, which is a solvent composed of an aromatic hydrocarbon compound, preferably include benzene, toluene, xylene, trimethylbenzene, tetramethylbenzene, butylbenzene, naphthalene and tetralin. Of them, toluene, xylene, tetralin and tetramethylbenzene, etc. are preferable.

Furthermore, examples of the ether based solvent, which is a solvent composed of a compound in which hydrocarbon groups are bonded with an oxygen atom, include diisopropyl ether, tetrahydrofuran, 1,4-dioxane, diphenyl ether, ethylene glycol dimethyl ether, and tert-butylmethyl ether. Of them, tetrahydrofuran and 1,4-dioxane are preferable since they are good solvents for a polymer compound.

To improve polymerization and solubility, these solvents may be used in mixture.

A polymerization reaction is generally performed in an inert gas atmosphere such as argon or nitrogen.

The polymerization time is generally about 0.5 to 100 hours. In view of manufacturing cost, 30 hours or less is preferable.

The polymerization temperature is generally about 0 to 200° C. To increase yield and lower heat cost, 0 to 100° C. is preferable.

Note that the polymerization reaction is generally performed under an inert gas atmosphere such as argon or nitrogen in a reaction system in which a null-valent nickel catalyst is not inactivated.

Examples of the reaction performed in the presence of a Pd catalyst include the Suzuki coupling reaction.

Examples of the palladium catalyst to be used in the Suzuki coupling reaction include palladium acetate, a palladium[tetrakis(triphenylphosphine)] complex and a bis(tricyclohexylphosphine)palladium complex.

Examples of the phosphorus ligand include triphenylphosphine, tri(o-tolyl)phosphine and 1,3-bis(diphenylphosphino)propane.

For example, the reaction is performed in a system using palladium[tetrakis(triphenylphosphine)] complex, with the addition of an inorganic base such as potassium carbonate, sodium carbonate, or barium hydroxide, an organic base such as triethylamine, or an inorganic salt such as cesium fluoride in an amount of an equivalent or more, preferably 1 to 10 equivalents relative to the monomer. The reaction may be performed in a two-phase system using an aqueous inorganic salt solution. Examples of the solvent include N,N-dimethylformamide, toluene, dimethoxyethane and tetrahydrofuran. The reaction temperature varies depending upon the solvent to be used; however, a temperature of about 50 to 160° C. is preferably used. The reaction temperature may be raised in the proximity of the boiling point of the solvent to be used and reflux may be performed. The reaction time is about 0.2 hours to 200 hours. Note that the polymerization reaction is performed generally under an inert gas atmosphere such as argon or nitrogen in a reaction system in which a Pd(0) catalyst is not inactivated.

Of them, polymerization in accordance with the Wittig reaction, polymerization by the Heck reaction, polymerization by the Horner-Wadsworth-Emmons method, polymerization by Knoevenagel reaction, polymerization by the Suzuki coupling reaction, polymerization by the Grignard reaction and polymerization by a Ni(0) catalyst are preferable since structural control can be easily made. Furthermore, polymerization by the Ni(0) catalyst is more preferable because of availability of the raw materials and simple polymerization operation.

<<The case where a polymer chain having a repeat unit represented by the formula (1) and having a group represented by the aforementioned formula (2) and/or (3) at least one of the terminals of the molecular chain>>

A polymer compound according to the present invention can be produced, for example, by polymerizing a monomer corresponding to one or more types of repeat units to obtain a polymer having a leaving group at an end thereof and reacting the polymer with a monomer corresponding to those represented by the formula (2) and/or (3); or can be produced by polymerizing a monomer corresponding to one or more types of repeat units in the presence of a monomer corresponding to those represented by the formula (2) and/or (3).

A polymer compound according to the present invention can be produced by reacting one or more types of monomers represented by the general formula (101) and/or (102) with monomers represented by the general formula (104) and/or (105).

Y₁—Ar₁—Y₂ (101)

Y₃—Ar₂—Y₄ (102)

Y₇-E₁ (104)

Y₈-E₂ (105)

where Ar₁ and Ar₂ each independently represent an arylene group, divalent heterocyclic group or divalent aromatic amine group; E₁ and E₂ each independently represent a group represented by the aforementioned formula (2) and/or (3); Y₁, Y₂, Y₃, Y₄, Y₇ and Y₈ each independently represent a leaving group; however, E₁ and E₂ differ from each other.

Examples of the leaving group include a halogen atom, alkylsulfonyloxy group, arylsulfonyloxy group and a group represented by —B(OR₁₁)₂ (where R₁₁ is a hydrogen atom or an alkyl group).

Examples of the halogen atom include a chlorine atom, bromine atom and iodine atom. Of them, a chlorine atom and a bromine atom are preferable and a bromine atom is the most preferable. The alkylsulfonyloxy group may be substituted with a fluorine atom. For example, trifluoromethanesulfonyloxy group may be mentioned. The arylsulfonyloxy group may be substituted with an alkyl group. For example, a phenylsulfonyloxy group and a trisulfonyloxy group may be mentioned.

In the group represented by —B(OR₁₁)₂, R₁₁ is a hydrogen atom or an alkyl group. Examples of the alkyl group, which has generally about 1 to 20 carbon atoms, include a methyl group, ethyl group, propyl group, butyl group, hexyl group, octyl group and dodecyl group. The alkyl groups may be linked to each other to form a ring.

Specific examples of the group represented by —B(OR₁₁)₂ include the groups represented by

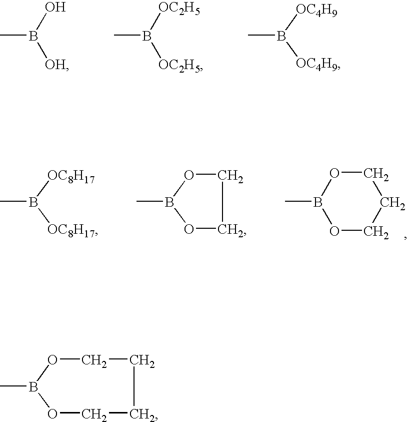

Preferable examples of them are the groups represented by

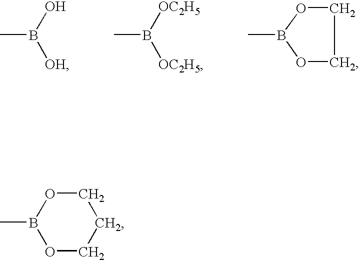

The total supply amount of monomers represented by the general formulas (104) and (105) is generally 0.1 to 20 mol % and preferably 0.2 to 10 mol % relative to the total supply amount of the monomers represented by the general formulas (101) and (102).

Examples of the method for producing a polymer compound according to the present invention include a method of polymerizing the aforementioned corresponding monomers in accordance with the Suzuki reaction (Chem. Rev.) Vol. 95, p. 2457, (1995); a method of polymerizing the monomers in accordance with the Grignard reaction (high-performance material series, Vol. 2, Synthesis and Reaction of a polymer (II), p. 432-433, published by Kyoritsu Shuppan Co., Ltd.); a method of polymerizing the monomers in accordance with the Yamamoto polymerization method (Prog. Polym. Sci.), Vol. 17, p. 1153-1205, (1992), a method of polymerizing the monomers by an oxidant such as FeCl₃; and a method of polymerizing the monomers in accordance with electrochemical oxidation polymerization (Experimental Chemical Course, 4th Edition, Vol. 28, p. 339-340, published by Maruzen Co., Ltd.).

The case where the Suzuki reaction is employed will be explained. In this case, a polymer is produced by reacting monomers where Y₁ and Y₂ each independently represent a group represented by the formula —B(OR₁₁)₂, (where R₁₁ is a hydrogen atom or an alkyl group); Y₃ and Y₄ each independently represent a halogen atom, an alkylsulfonyloxy group or an arylsulfonyloxy group; Y₇ is the group represented by the formula B(OR₁₁)₂, (where R₁₁ is a hydrogen atom or an alkyl group); and Y₈ represents a halogen atom, an alkylsulfonyloxy group or an arylsulfonyloxy group in the presence of a Pd(0) catalyst.

Note that, sometimes in this case, it is required that at least one type of the monomers (two or more types) having two leaving groups, which are to be subjected to the reaction, has two groups represented by the formula —B(OR₁₁)₂ (where R₁₁ is a hydrogen atom or an alkyl group) and at least one of them has two halogen atoms, two alkylsulfonyloxy groups or two arylsulfonyloxy groups. In such a reaction case, monomers represented by the formula (101) and (102) are reacted for about 0.2 to 100 hours and then, a monomer (105) is added in the reaction system and allowed to react for about 0.5 to 50 hours, and then, a monomer (104) is added to the reaction system and allowed to react for about 0.5 to 50 hours.

The reaction is performed by using a Pd(0) catalyst such as palladium[tetrakis(triphenylphosphine)](0), palladium acetate (e.g., a catalyst obtained by reducing palladium acetate with a triphenyl phosphine derivative) or a dichlorobis(triphenylphosphine) palladium (II) and adding an inorganic base such as potassium carbonate, sodium carbonate or barium carbonate, an organic base such as triethylamine or an inorganic salt such as cesium fluoride in an amount of an equivalent or more, preferably, 1 to 10 equivalents relative to the monomer. The reaction may be performed in a two phase system using an aqueous inorganic salt solution. Examples of the solvent include N,N-dimethylformamide, toluene, dimethoxyethane and tetrahydrofuran. The reaction temperature varies depending upon the solvent to be used; however, a temperature of about 50 to 160° C. is preferably used. The reaction temperature may be raised in the proximity of the boiling point of the solvent to be used and reflux may be performed. The reaction time is about 0.2 hours to 200 hours. Note that the polymerization reaction is generally performed under an inert gas atmosphere such as argon or nitrogen in a reaction system in which a Pd(0) catalyst is not inactivated.

The case where the Yamamoto polymerization method is used will be explained. In the case, a reaction is performed using monomers in which Y₁, Y₂, Y₃, Y₄, Y₇ and Y₈ are each independently a halogen atom, alkylsulfonyloxy group or arylsulfonyloxy group in the presence of a Ni(0) complex to obtain a desired polymer. The reaction is generally performed by blending all of the monomers (102), (103), (104), and (105).

Polymerization was performed in the presence of a Ni(0) complex. As the nickel complex, null-valent nickel may be used as it is. Alternatively, a nickel salt is reacted in the presence of a reducing agent to produce a null valent nickel in a reaction system and used in the reaction. Examples of the null valent nickel complex include bis(1,5-cyclooctadiene)nickel(0), (ethylene)bis(triphenylphosphine)nickel(0) and tetrakis(triphenylphosphine)nickel. Of them, bis(1,5-cyclooctadiene)nickel(0) is preferable since it is generally used and inexpensive. Furthermore, a neutral ligand is preferably added to improve the yield. The neutral ligand used herein refers to a ligand having no anions and cations. Examples thereof include nitrogen containing ligands such as 2,2′-bipyridyl, 1,10-phenanthroline, methylenebisoxazoline and N,N′-tetramethylethylenediamine; and tertiary phosphine ligands such as triphenylphosphine, tritolylphosphine, tributylphosphine and triphenoxyphosphine. In view of general versatility and low cost, a nitrogen-containing ligand is preferable and 2,2′-bipyridyl is particularly preferable in view of high reactivity and high yield. In particular, to improve the yield of a polymer, it is preferable to use a reaction system containing bis(1,5-cyclooctadiene)nickel(0), with the addition of 2,2′-bipyridyl as a neutral ligand. In a method of reacting null-valent nickel in the reaction system, for example, nickel chloride or nickel acetate may be mentioned as a nickel salt. Examples of the reducing agent include zinc, sodium hydride, hydrazine and a derivative thereof, and lithium aluminium hydride. If necessary, additives such as ammonium iodide, lithium iodide or potassium iodide may be used. A polymerization solvent is not particularly limited unless it inhibits polymerization; however, the solvent preferably contains one type or more aromatic hydrocarbon solvent and/or an ether solvent. Examples of the aromatic hydrocarbon solvent include benzene, toluene, xylene, trimethylbenzene, tetramethylbenzene, butylbenzene, naphthalene and tetralin. Of them, toluene, xylene, tetralin and tetramethylbenzene are preferable. Examples of the ether solvent include diisopropyl ether, tetrahydrofuran, 1,4-dioxane, diphenyl ether, ethylene glycol dimethyl ether and tert-butylmethyl ether. Of them, a good solvent for a polymer compound such as tetrahydrofuran or 1,4-dioxane is preferable. Of the solvents, tetrahydrofuran is the most preferable. To improve polymerization and solubility, a solvent mixture of an aromatic hydrocarbon based solvent and/or an ether solvent and any other solvent(s) (except the aromatic hydrocarbon based solvent and/or the ether solvent) may be used unless the mixture inhibits polymerization.

The reaction operation can be made in accordance with the method described in JP-A-2000-44544. In the Yamamoto polymerization, a polymerization reaction can be performed generally under an inert gas atmosphere such as argon or nitrogen in a tetrahydrofuran solvent at a temperature of 60° C. in the presence of a null-valent nickel complex and a neutral ligand. The polymerization time is generally from about 0.5 to 100 hours. In view of manufacturing cost, 10 hours or less is preferable. The polymerization temperature is generally about 0 to 200° C. To increase yield and lower heat cost, 20 to 100° C. is preferable.

When a neutral ligand is used, the use amount thereof is preferably about 0.5 to 10 moles relative to null-valent nickel complex (1 mole) in view of reaction yield and cost, more preferably, 0.8 to 1.5 moles and further preferably 0.9 to 1.1 moles.

The use amount of a null-valent nickel complex is not particularly limited unless it inhibits a polymerization reaction. However, when the use amount is low, the molecular weight tends to be low. When the use amount is excessively large, a post treatment tends to be complicated. For this reason, the use amount is preferably 0.1 to 10 moles relative to a monomer (1 mole), more preferably, 1 to 5 moles, and further preferably, 1.7 to 3.5 moles. Note that the polymerization reaction is performed generally under an inert gas atmosphere such as argon or nitrogen in a reaction system in which a null-valent nickel complex catalyst is not inactivated.

After completion of manufacturing a polymer compound according to the present invention, if necessary, the polymer compound may be subjected to customary operations such as a separation operation, purification operation and dehydration operation including washing with acid, washing with alkali, neutralization, washing with water, washing with an organic solvent, reprecipitation, centrifugal separation, extraction and column chromatography.

When a polymer compound according to the present invention is used as an electronic material, the purity thereof has an effect upon various properties thereof. Therefore, in the production method of the present invention, the aforementioned separation operation and purification operation are preferably performed well to sufficiently remove an unreacted monomer, a side product, a catalyst residue, and so forth.

Dehydration may be performed in the conditions under which a remaining solvent can be sufficiently removed. To prevent denaturation of a polymer compound, dehydration is preferably performed in an inert atmosphere and under light proof conditions. It is further preferable that dehydration is performed at a temperature at which a polymer compound cannot be thermally denatured.

A polymer compound of the present invention can be used as a luminescent material and further as a charge transport material, organic semiconductor material, optical material or conductive material by doping.

### <Polymer Composition>

A polymer composition of the present invention contains a polymer compound (which differs from a polymer compound according to the present invention) fluorescent in a state of solid and having a polystyrene-reduced number average molecular weight of 10³ to 10⁸ and contains a polymer compound according to the present invention. The polymer compound (which differs from a polymer compound according to the present invention) is not particularly limited as long as it improves characteristics of the resultant device such as solubility to a solvent, fluorescent intensity, life and brightness. Examples of such a polymer compound include, but not limited to, those described in JP-A-2001-247861, JP-A-2001-507511, JP-A-2001-504533, JP-A-2001-278958, JP-A-2001-261796, JP-A-2001-226469, and Japanese Patent No. 3161058. Examples of the polymer compound (which differs from a polymer compound according to the present invention) include, but not limited to, a polyfluorene compound, polyfluorene polymer compound, polyarylene compound, polyarylene polymer compound, polyarylene-vinylene compound, polyarylene-vinylene polymer compound, polystilbene compound, polystilbene polymer compound, polystilbene-vinylene compound, polystilbene-vinylene polymer compound, polypyridine-diyl compound, polypyridine-diyl polymer compound, alkoxypolythiophene compound and alkoxypolythiophene polymer compound. Of them, a polyfluorene polymer compound, polyarylene polymer compound, polyarylene-vinylene polymer compound, polystilbene polymer compound and polystilbene-vinylene polymer compound are preferable.

A mixing ratio of a polymer compound according to the present invention may not be limited as long as it improves the characteristics of the resultant device such as solubility to a solvent, fluorescent intensity, life and brightness. The mixing ratio thereof falls generally within the range of 5 to 95% relative to the total polymer composition.

As a polymer composition according to the present invention, mention may be made of a composition containing two or more types of polymer compounds according to the present invention having a substituent. Examples of the polymer compound according to the present invention having a substituent include a polyfluorene polymer, polyarylene polymer, polyarylene-vinylene polymer, polystilbene polymer, polystilbene-vinylene polymer, polypyridine polymer and alkoxypolythiophene polymer. A polymer compound according to the present invention is obtained by using the aforementioned polymer compounds in an appropriate combination of two or more types. The mixing ratio thereof is not particularly limited; however, the ratio of the polymer compound contained in a composition at the largest amount preferably fall within the range of 5 to 90 wt % relative to the total polymer composition.

### <Composition (Liquid Composition)>

A composition according to the present invention contains a polymer compound according to the present invention and a polymer compound (which differs from the polymer compound of the present invention) having a polystyrene-reduced number average molecular weight of 10³ to 10⁸. Examples of the polymer compound (which differs from the polymer compound of the present invention) having a polystyrene-reduced number average molecular weight of 10³ to 10⁸ include a poly(phenylene) and a derivative thereof, poly(benzofluorene) and a derivative thereof, a poly(dibenzofuran) and a derivative thereof, a poly(dibenzothiophene) and a derivative thereof, a poly(carbazole) and a derivative thereof, a poly(thiophene) and a derivative thereof, a poly(phenylenevinylene) and a derivative thereof, a poly(fluorenevinylene) and a derivative thereof, a poly(benzofluorenevinylene) and a derivative thereof and a poly(dibenzofuranvinylene) and a derivative thereof. Note that these derivatives are other than the repeat units represented by the aforementioned formula (1).

A liquid composition according to the present invention is useful for forming a luminescent device such as polymer luminescent device and an organic transistor. The liquid composition consists of the polymer compounds mentioned above and a solvent. The term “liquid composition” used herein refers to a liquid-state composition at the time the manufacturing of a device is initiated, and more specifically, refers to a liquid-state composition at normal pressure (i.e., 1 atom) and 25° C. Furthermore, the liquid composition is generally referred to as, for example, ink, an ink composition or a solution in some cases.

A liquid composition according to the present invention may contain, other than the aforementioned polymer compounds, a low molecular weight luminescent material, a hole transport material, an electron transport material, a stabilizer, an additive for controlling viscosity and/or surface tension, an antioxidant, and so forth. These optional components may be used singly or in combination with two or more types.

Examples of the low molecular weight fluorescent material that may be contained in a liquid composition according to the present invention include fluorescent materials of low molecular weight compounds such as a naphthalene derivative, anthracene, an anthracene derivative, perylene, a perylene derivative, a polymethine pigment, a xanthene pigment, a coumarin pigment, a cyanine pigment, a metal complex having a metal complex of 8-hydroxyquinoline as a ligand, a metal complex having a 8-hydroxyquinoline derivative as a ligand, other fluorescent metal complexes, an aromatic amine, tetraphenylcyclopentadiene, a tetraphenylcyclopentadiene derivative, tetraphenylcyclobutadiene, a tetraphenylcyclobutadiene derivative, a stilbene compound, a silicon-containing aromatic compound, an oxazole compound, a furoxane compound, a thiazole compound, a tetraarylmethane compound, a thiadiazole compound, a pyrazole compound, a metacyclophane compound and an acetylene compound.

More specifically, mention may be made of known compounds described in JP-A-57-51781 and JP-A-59-194393.

Examples of the hole transport material that may be contained in a liquid composition according to the present invention include a polyvinylcarbazole and a derivative thereof, a polysilane and a derivative thereof, a polysiloxane derivative having an aromatic amine in a side chain or the main chain, a pyrazoline derivative, an arylamine derivative, a stilbene derivative, a triphenyldiamine derivative, polyaniline and a derivative thereof, a polythiophene and a derivative thereof, a polypyrrole and a derivative thereof, a poly(p-phenylenevinylene) and a derivative thereof, and poly a (2,5-thienylenevinylene) and a derivative thereof.

Examples of the electron transport material that may be contained in a liquid composition according to the present invention include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, metal complexes of 8-hydroxyquinoline and a derivative thereof, a polyquinoline and a derivative thereof, a polyquinoxaline and a derivative thereof, and a polyfluorene and a derivative thereof.

Examples of the stabilizer that may be contained in a liquid composition according to the present invention include a phenolic antioxidant and a phosphorus antioxidant.

Examples of the additive for controlling viscosity and/or surface tension that may be contained in a liquid composition according to the present invention include a high molecular weight compound (thickener) for increasing viscosity, a poor solvent, a low molecular weight compound for reducing viscosity and a surfactant for reducing surface tension. These may be used in an appropriate combination.

As the high molecular weight compound, any compound may be used unless it inhibits light emission and charge transport. Generally, a compound soluble to the solvent of a liquid composition is used. As an example of the high molecular weight compound, use may be made of a polystyrene having a high molecular weight or a polymethylmethacrylate having a high molecular weight. The polystyrene-reduced weight average molecular weight of the high molecular weight compound is preferably 500,000 or more, and more preferably, 1,000,000. Furthermore, a poor solvent may be used as a thickener.

As the antioxidant that may be contained in a liquid composition according to the present invention, any antioxidant may be used unless it inhibits light emission and charge transport. When a composition contains a solvent, an antioxidant soluble to the solvent is generally used. Examples of the antioxidant include a phenolic antioxidant and a phosphorus antioxidant. Use of the antioxidant can improve storage stability of the polymer compounds and the solvent.

When a liquid composition according to the present invention contains a hole transport material, the content of the hole transport material in the liquid composition is generally 1 wt % to 80 wt %, and preferably 5 wt % to 60 wt %. When a liquid composition according to the present invention contains an electron transport material, the content of the electron transport material in the liquid composition is generally 1 wt % to 80 wt %, and preferably 5 wt % to 60 wt %.

In manufacturing a polymer luminescent device, a film is formed by use of the liquid composition. In this case, all that should be done is just applying the liquid composition and removing a solvent by dehydration. A liquid composition containing a charge transfer material and a luminescent material can be applied in the same manner. Therefore, the liquid composition is useful in view of manufacturing. Dehydration may be performed in a heated condition of about 50° C. to 150° C. or in a reduced pressure condition of about 10⁻³ Pa.

Examples of the film-formation method using a liquid composition include a spin coat method, casting method, microgravure coat method, gravure coat method, bar coat method, roll coat method, wire-bar coat method, dip coat method, spray coat method, screen printing, flexographic printing method, offset printing method and inkjet printing method.

The content of the solvent in a liquid composition is generally 1 wt % to 99.9 wt %, preferably 60 wt % to 99.9 wt %, and further preferably, 90 wt % to 99.8 wt % relative to the total weight of the liquid composition. The viscosity of a liquid composition varies depending upon the printing method; however, it preferably falls within the range of 0.5 to 500 mPa·s at 25° C. When a liquid composition is passed through an ejection apparatus as is in the case of inkjet printing, the viscosity at 25° C. preferably falls within the range of 0.5 to 20 mPa·s in order to prevent clogging of ejection nozzles and to prevent spray liquid droplets from flying away from a right direction.

As the solvent to be contained in a liquid composition, a solvent capable of dissolving and dispersing components (except the solvent) contained in the liquid composition is preferable. Examples of the solvent include chlorine based solvents such as chloroform, methylene chloride, 1,2-dichloroethane, 1,1,2-trichloroethane, chlorobenzene and o-dichlorobenzene; ether based solvents such as tetrahydrofuran and dioxane; aromatic hydrocarbon based solvents such as toluene, xylene, trimethylbenzene and mesitylene; aliphatic hydrocarbon based solvents cyclohexane, methylcyclohexane, n-pentane, n-hexane, n-heptane, n-octane, n-nonane and n-decane; ketone based solvents such as acetone, methylethylketone and cyclohexanone; ester based solvents such as ethyl acetate, butyl acetate, methylbenzoate and ethyl cellosolve acetate; polyhydric alcohols and derivatives thereof such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin and 1,2-hexane diol; alcohol based solvents such as methanol, ethanol, propanol, isopropanol and cyclohexanol; sulfoxide based solvents such as dimethylsulfoxide; amide based solvents such as N-methyl-2-pyrrolidone and N,N-dimethylformamide. These solvents may be used singly or in combination of two or more types. At least one type of solvent selected from the aforementioned solvents and having at least one benzene ring, a melting point of 0° C. or less and a boiling point of 100° C. or more, is preferably contained in view of viscosity and film-formability.

As the type of solvent, an aromatic hydrocarbon based solvent, aliphatic hydrocarbon solvent, ester based solvent and ketone based solvent are preferable in view of properties such as solubility of components (except a solvent) of a liquid composition to an organic solvent, uniformity of formed film and viscosity. Preferable examples thereof include toluene, xylene, ethylbenzene, diethylbenzene, trimethylbenzene, mesitylene, n-propylbenzene, isopropylbenzene, n-butylbenzene, isobutylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexane, methylbenzoate, 2-propylcyclohexanone, 2-heptanon, 3-heptanon, 4-heptanon, 2-octanone, 2-nonane, 2-decanone and dicyclohexyl ketone. More preferably, at least one type of solvent selected from xylene, anisole, mesitylene, cyclohexylbenzene and bicyclohexylmethylbenzoate is contained.

The number of types of solvents contained in a liquid composition is preferably 2 or more, more preferably 2 to 3 and further preferably 2, in view of film formability and characteristics of the resultant device.

When 2 types of solvents are contained in a liquid composition, one of them may be present in a solid state at 25° C. In view of film formability, preferably, one of the 2 types of solvents has a boiling point of 180° C. or more and the other has a boiling point of less than 180° C. More preferably, one of the 2 types of solvents has a boiling point of 200° C. or more, and the other has a boiling point of less than 180° C. Furthermore, in view of viscosity, 0.2 wt % or more of components (except the solvent) of a liquid composition is preferably dissolved in the solvent at 60° C. 0.2 wt % or more of components (except the solvent) of a liquid composition is preferably dissolved in one of the 2 types of solvents at 25° C.

When 3 types of solvents are contained in a liquid composition, 1 to 2 types of solvents of them may be present in a solid state at 25° C. In view of film formability, at least one type of solvent of the 3 types of solvents preferably has a boiling point of 180° C. or more and at least one type of solvent has a boiling point of 180° C. or less. More preferably, at least one type of solvent of the 3 types of solvents has a boiling point of 200° C. to 300° C. (both inclusive) and at least one type of solvent has a boiling point of 180° C. or less. Furthermore, in view of viscosity, two types of solvents of the 3 types of solvents preferably dissolve 0.2 wt % or more of the components (except the solvent) of a liquid composition at 60° C. One type of solvent of the 3 types of solvents preferably dissolves 0.2 wt % or more of the components (except the solvent) of a liquid composition at 25° C.

When two types or more of solvents are contained in a liquid composition, in view of viscosity and film formability, the solvent having the highest boiling point is preferably contained in an amount of 40 to 90 wt %, more preferably 50 to 90 wt %, and further preferably, 65 to 85 wt % based on the weight of the all solvents contained in the liquid composition.

### —Thin Film—

A thin film according to the present invention will be described. The thin film is formed of a polymer compound as mentioned above. As the types of thin film, for example, a luminous thin film, conductive thin film and organic semiconductor thin film may be mentioned.

The luminous thin film preferably has a luminescent quantum yield of 50% or more, more preferably, 60% or more and further preferably 70% or more, in view of brightness of the resultant device and voltage for light emission.

The conductive thin film preferably has a surface resistance of 1 KΩ/□ or less. The thin film doped with a Lewis acid or an ionic compound can be improved in electroconductivity. The surface resistance is more preferably 100 KΩ/□ or less, and further preferably, 10 KΩ/□ or less.

The organic semiconductor thin film preferably has a larger electron mobility or a larger hole mobility. The mobility of either one of them is preferably 10⁻⁵ cm²/V/second or more, more preferably 10⁻³ cm²/V/second or more, and further preferably 10⁻¹ cm²/V/second or more. The organic semiconductor thin film can be used for forming an organic transistor. To describe more specifically, an organic semiconductor thin film is formed on an Si substrate having an insulating film such as SiO₂ and a gate electrode formed thereon, and a source electrode and drain electrode are formed of, for example, Au. In this manner, an organic transistor can be obtained.

### —Organic Transistor (Polymer Electric Field Effect Transistor)—

Next, a polymer electric field effect transistor belonging to a group of organic transistors will be described.

A polymer compound according to the present invention can be suitably used as a material for a polymer electric field effect transistor, more specifically, as an active layer. In the structure of the polymer electric field effect transistor, a source electrode and a drain electrode are generally arranged in contact with an active layer composed of a polymer. Furthermore a gate electrode may be formed so as to sandwich an insulating layer, which is formed in contact with the active layer.

A polymer electric field effect transistor is generally formed on a support substrate. The material for the support substrate is not particularly limited unless it inhibits characteristics of the polymer electric field effect transistor. A glass substrate, a flexible film substrate and plastic substrate can be used.

A polymer electric field effect transistor can be manufactured by a known method, for example, a method described in JP-A-5-110069.

In forming the active layer, a polymer compound soluble to an organic solvent is very useful and preferable from a manufacturing point of view. Examples of a method used for forming a film from a solution in which a polymer compound soluble to an organic solvent is dissolved in the organic solvent include a spin coat method, casting method, microgravure coat method, gravure coat method, bar coat method, roll coat method, wire-bar coat method, dip coat method, spray coat method, screen printing, flexographic printing method, offset printing method and inkjet printing method.

After a polymer electric field effect transistor is formed, it is preferably sealed to obtain a sealed polymer electric field effect transistor. By virtue of sealing, the polymer electric field effect transistor is isolated from air, thereby suppressing a reduction of characteristics of the transistor.

As a sealing method, mention may be made of a method of covering a transistor with a UV curing resin, a thermosetting resin or an inorganic film of, for example, a SiONx film, and a method of adhering a glass plate or a film with a UV curing resin or a thermosetting resin. To effectively isolate a polymer electric field effect transistor from air, after the transistor is manufactured, a process including a sealing step is preferably performed without exposing to air (for example, in a dry nitrogen atmosphere or in a vacuum).

### —Organic Solar Battery—

Next, an organic solar battery will be explained. More specifically, an organic photoelectric conversion device belonging to a group of organic solar batteries, for example, a solid photoelectric conversion device using photovoltaic effect, will be explained.

A polymer compound according to the present invention can be suitably used as a material for an organic photoelectric conversion device. More specifically, the polymer compound can be suitably used as the organic semiconductor layer of a Schottky barrier type device using the interface between an organic semiconductor and a metal. Furthermore, the polymer compound can be suitably used as the organic semiconductor layer of a pn heterojunction-type device using the interface between an organic semiconductor and an inorganic semiconductor or between organic semiconductors.

Furthermore, a polymer compound according to the present invention can be suitably used as an electron donating polymer or an electron accepting polymer of a bulk-heterojunction type device increased in a donor-acceptor contact area, and used as an electron donating conjugated polymer (dispersion support) of an organic photoelectric conversion device using a polymer/low molecular compound composite system, such as a bulk-heterojunction type organic photoelectric conversion device in which a fullerene derivative serving as an electron acceptor is dispersed.

The organic photoelectric conversion device, for example, a pn heterojunction-type device may be constructed by forming a p-type semiconductor layer on an ohmic electrode, for example, ITO, and further laminating an n-type semiconductor layer and providing an ohmic electrode on the n-type semiconductor layer.

An organic photoelectric conversion device is generally formed on a support substrate. The material for the support substrate is not particularly limited unless it inhibits the characteristics of the resultant organic photoelectric conversion device; however, a glass substrate, flexible film substrate and plastic substrate can be also used.

An organic photoelectric conversion device can be manufactured by a known method, for example, the methods described in Synth. Met., 102, 982 (1999) and Science, 270, 1789 (1995).

### —Polymer Luminescent Device (Polymer LED)—

When a polymer compound according to the present invention is used as a luminescent material for a polymer LED, since luminescence and phosphorescence from a thin film are used, the polymer compound of the present invention is preferably fluorescent or phosphorescent in a solid state.

A polymer LED according to the present invention has a luminescent layer between the electrodes composed of an anode and a cathode and characterized in that the luminescent layer contains a polymer compound or a polymer composition according to the present invention.

Examples of the polymer LED according to the present invention include a polymer luminescent device having a layer containing a conductive polymer between at least one of the electrodes and the luminescent layer in adjacent to the electrode, and a polymer luminescent device having an insulating layer of 2 nm or less in average thickness between at least one of the electrodes and the luminescent layer and in adjacent to the electrode.

Examples of the polymer LED according to the present invention include a polymer LED having an electron transport layer between a cathode and a luminescent layer, a polymer LED having a hole transport layer between an anode and a luminescent layer, a polymer LED having an electron transport layer between a cathode and a luminescent layer and a hole transport layer between an anode and the luminescent layer.

Examples of the structure of a polymer LED according to the present invention include structures represented by the following a) to d).

a) Anode/luminescent layer/cathode

b) Anode/hole transport layer/luminescent layer/cathode

c) Anode/luminescent layer/electron transport layer/cathode

d) Anode/hole transport layer/luminescent layer/electron transport layer/cathode

(Symbol “/” means that individual layers are laminated in adjacent to each other. The same definition will be employed hereinafter.)

The luminescent layer is a layer having a luminescent function. The hole transport layer is a layer having a function of transporting holes. The electron transport layer is a layer having a function of transporting electrons. Note that the electron transport layer and hole transport layer are collectively called as a charge transport layer. The number of luminescent layers, hole transport layers and electron transport layers may be each independently 2 or more.

Of the charge transport layers provided in adjacent to an electrode, the layer having a function of improving charge injection efficiency from the electrode, thereby effectively reducing the drive voltage of a device is generally called particularly as a charge injection layer (hole injection layer or electron injection layer).

Furthermore, to improve adhesion to an electrode and to improve charge injection from the electrode, a charge injection layer as mentioned above or an insulating layer having a thickness of 2 nm or less may be provided in adjacent to the electrode. Alternatively, for improving the adhesion to the interface, preventing contamination and for other purpose, a thin insulating layer may be inserted between the charge transport layer and the luminescent layer. The laminate order, number, and thickness of layers may be appropriately set in view of luminous efficiency and the working life of a device.

In the present invention, examples of a polymer LED having a charge injection layer (electron injection layer and hole injection layer) include a polymer LED having a charge injection layer in adjacent to a cathode; and a polymer LED having a charge injection layer in adjacent to an anode. Specific examples thereof are polymer LED having the following structures (e) to (p).

e) anode/charge injection layer/luminescent layer/cathode

f) anode/luminescent layer/charge injection layer/cathode

g) anode/charge injection layer/luminescent layer/charge injection layer/cathode

h) anode/charge injection layer/hole transport layer/luminescent layer/cathode

i) anode/hole transport layer/luminescent layer/charge injection layer/cathode

j) anode/charge injection layer/hole transport layer/luminescent layer/charge injection layer/cathode

k) anode/charge injection layer/luminescent layer/charge transport layer/cathode

l) anode/luminescent layer/electron transport layer/charge injection layer/cathode

m) anode/charge injection layer/luminescent layer/electron transport layer/charge injection layer/cathode

n) anode/charge injection layer/hole transport layer/luminescent layer/electron transport layer/cathode

o) anode/hole transport layer/luminescent layer/electron transport layer/charge injection layer/cathode

p) anode/charge injection layer/hole transport layer/luminescent layer/electron transport layer/charge injection layer/cathode

Specific examples of the charge injection layer include a layer containing a conductive polymer; a layer provided between an anode and a hole transport layer and containing a material having an ionization potential, which is a medium value between that of an anode material and that of a hole transport material contained in the hole transport layer; and a layer provided between a cathode and an electron transport layer and containing a material having an electron affinity, which is a medium value between that of a cathode material and that of an electron transport material contained in the electron transport layer.

When the charge injection layer contains a conductive polymer, the electric conductivity of the conductive polymer is preferably 10⁻⁵ S/cm to 10³ S/cm (both inclusive). To reduce current leakage between luminescent pixels, the electric conductivity is more preferably 10⁻⁵ S/cm to 10² S/cm (both inclusive), and further preferably, 10⁻⁵ S/cm to 10¹ S/cm (both inclusive).

When the charge injection layer is the layer containing a conductive polymer, the electric conductivity of the conductive polymer is preferably from 10⁻⁵ S/cm to 10³S/cm (both inclusive). To reduce leak current between luminescent pixels, the electric conductivity is preferably from 10⁻⁵ S/cm to 10²S/cm (both inclusive), and further preferably, from 10⁻⁵ S/cm to 10¹ S/cm (both inclusive). To set the electric conductivity of the conductive polymer at 10⁻⁵ S/cm to 10³ (both inclusive), generally an appropriate amount of ions is doped into the conductive polymer.

The type of ion to be doped into a hole injection layer is anion and cation to an electron injection layer. Examples of the anion include polystyrene sulfonate ions, alkylbenzene sulfonate ions and camphor sulfonate ions. Examples of the cation include lithium ions, sodium ions, potassium ions and tetrabutylammonium ions. The film thickness of the charge injection layer is, for example, 1 nm to 100 nm and preferably 2 nm to 50 nm.

The material to be used in the charge injection layer may be appropriately selected in consideration of the materials used in the electrode and the layer adjacent thereto. Examples thereof include polyaniline and a derivative thereof, a polyaminophene and a derivative thereof, polypyrrole and a derivative thereof, polyphenylenevinylene and a derivative thereof, polythienylenevinylene and a derivative thereof, polyquinoline and a derivative thereof, polyquinoxaline and a derivative thereof, electroconductive polymers such as a polymer containing an aromatic amine structure in the main chain or a side chain thereof, metallophthalocyanine (e.g. copper phthalocyanine) and carbon.

The insulating layer having a film thickness of 2 nm or less has a function of facilitating charge injection. Examples of the material for the insulating layer include a metal fluoride, metal oxide and organic insulating material. Examples of the polymer LED having an insulating layer having a film thickness of 2 nm or less include a polymer LED, which has an insulating layer having a film thickness of 2 nm or less in adjacent to a cathode, and a polymer LED, which has an insulating layer having a film thickness of 2 nm or less in adjacent to an anode.

Specific examples thereof are polymer LED having the following structures q) to ab).

q) anode/insulating layer of ≦2 nm thickness/luminescent layer/cathode

r) anode/luminescent layer/insulating layer of ≦2 nm thickness/cathode

s) anode/insulating layer of ≦2 nm thickness/luminescent layer/insulating layer of ≦2 nm thickness/cathode

t) anode/insulating layer of ≦2 nm thickness/hole transport layer/luminescent layer/cathode

u) anode/hole transport layer/luminescent layer/insulating layer of ≦2 nm thickness/cathode

v) anode/insulating layer of ≦2 nm thickness/hole transport layer/luminescent layer/insulating layer of ≦2 nm thickness/cathode

w) anode/insulating layer of ≦2 nm thickness/luminescent layer/electron transport layer/cathode

x) anode/luminescent layer/electron transport layer/insulating layer of ≦2 nm thickness/cathode

y) anode/insulating layer of ≦2 nm thickness/luminescent layer/electron transport layer/insulating layer of ≦2 nm thickness/cathode

z) anode/insulating layer of ≦2 nm thickness/hole transport layer/luminescent layer/electron transport layer/cathode

aa) anode/hole transport layer/luminescent layer/electron transport layer/insulating layer of ≦2 nm thickness/cathode

ab) anode/insulating layer of ≦2 nm thickness/hole transport layer/luminescent layer/electron transport layer/insulating layer of ≦2 nm thickness/cathode.

The luminescent layer contains a polymer compound or a polymer composition according to the present invention. However, the luminescent layer may contain a luminescent material other than a polymer compound as mentioned above. Furthermore, in a polymer LED according to the present invention, a luminescent layer containing a luminescent material other than a polymer compound as mentioned above may be laminated with a luminescent layer containing the a polymer compound as mentioned above. As the luminescent material, a known material may be used. For example, use can be made of a low molecular weight compound, such as a naphthalene derivative, anthracene or a derivative thereof, perylene or a derivative thereof, pigment, e.g., polymethine, xanthene, coumarin or cyanine based pigment, a metal complex of 8-hydroxyquinoline or a derivative thereof, aromatic amine, tetraphenylcyclopentadiene or a derivative thereof, or tetraphenyl butadiene or a derivative thereof.

More specifically, known luminescent materials, for example, described in JP-A-57-51781 and JP-A-59-194393, can be used.

Furthermore, as the luminescent material, the following light emitting complexes from the triplet state or derivatives thereof can be used.

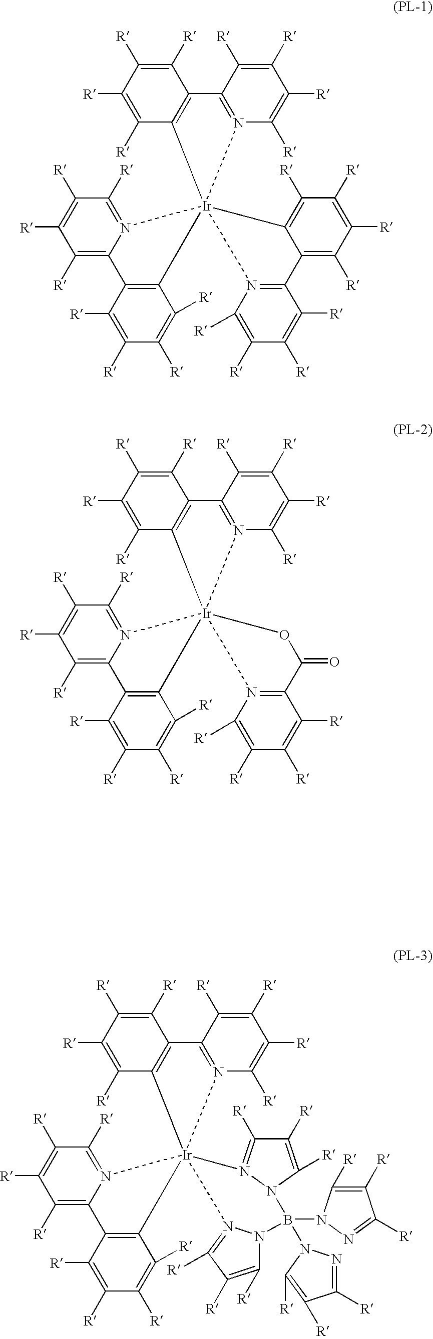

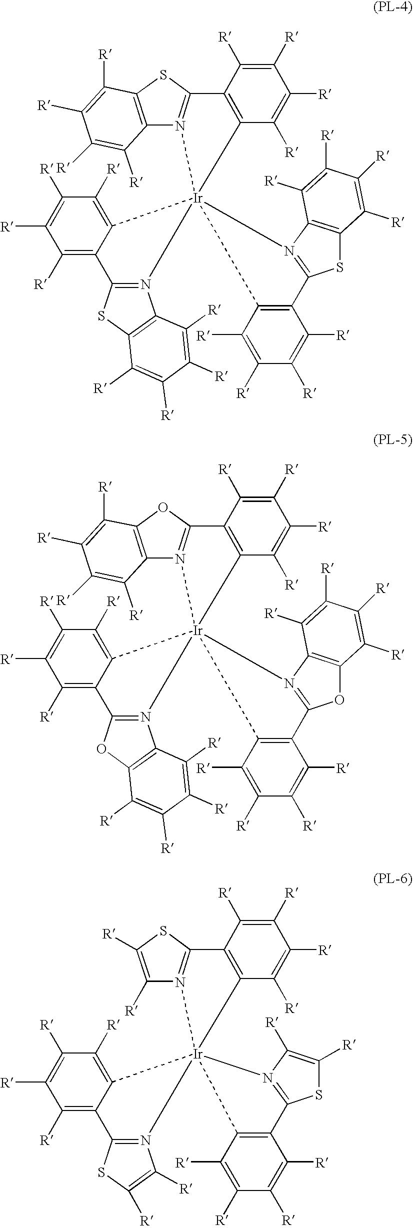

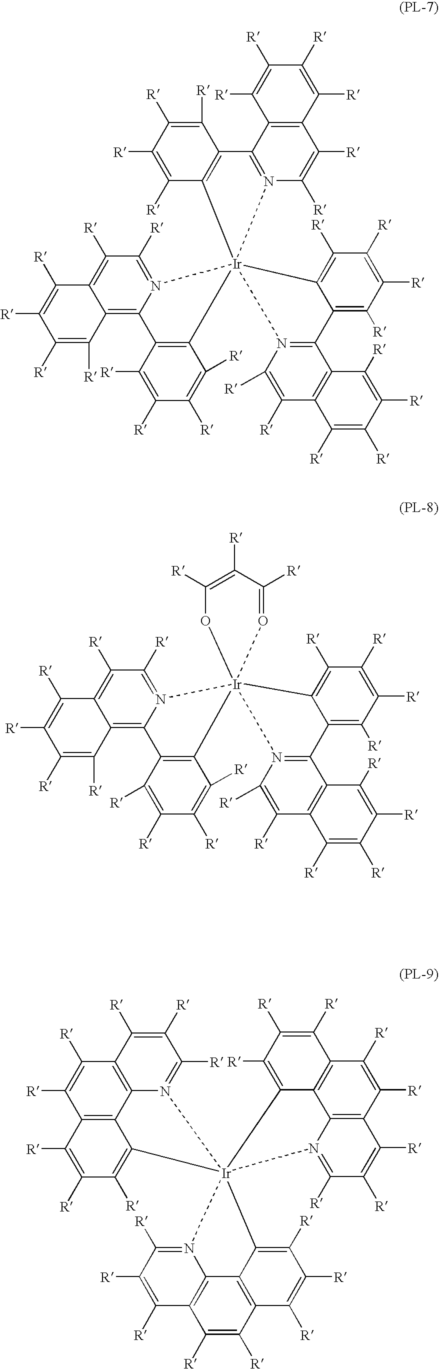

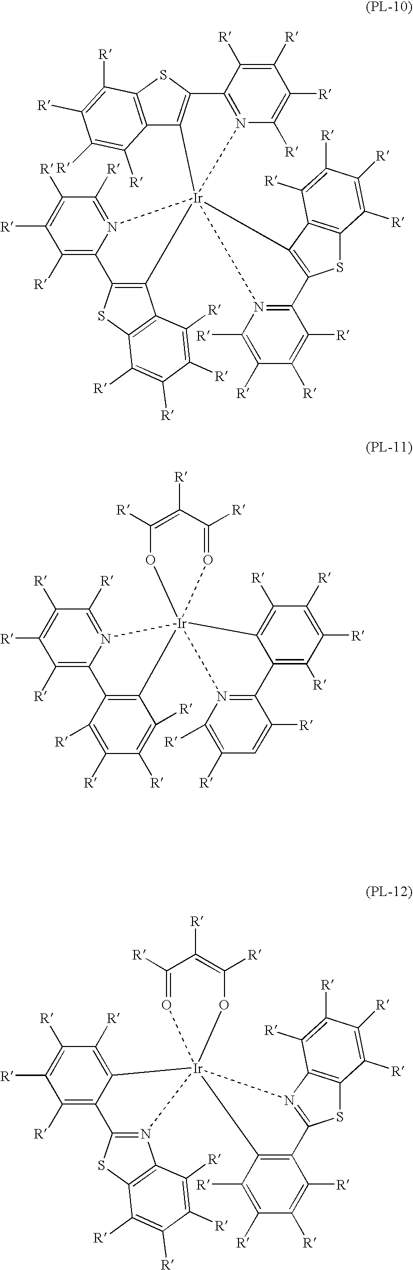

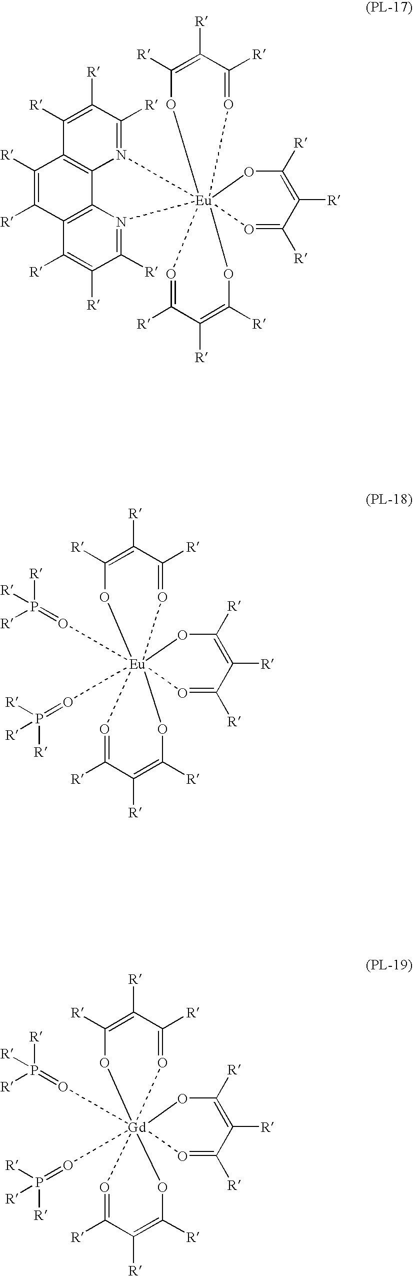

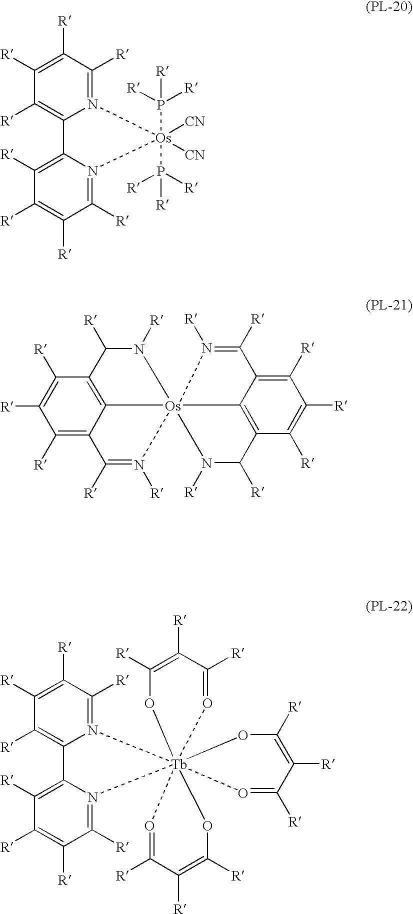

Furthermore, use can be made of polymers containing a light emitting complex from the triplet state as described, for example, in WO03/001616.

The method for forming a film of the luminescent layer is not particularly limited. For example, a method for forming a film from a solution may be mentioned.

Examples of the method for forming a film from a solution include coating methods such as spin coat method, casting method, microgravure coat method, gravure coat method, bar coat method, roll coat method, wire-bar coat method, dip coat method, spray coat method, screen printing, flexographic printing method, offset printing method and inkjet printing method.

Examples of a solvent for forming a film from a solution include toluene, xylene, chloroform and tetrahydrofuran.

As the film thickness of the luminescent layer, the optimum value thereof varies depending upon the material to be used. The film thickness may be selected such that the drive voltage and luminescent efficiency can be obtained at appropriate values. The film thickness is, for example, from 1 nm to 1 μm, preferably 2 nm to 500 nm, and further preferably, 5 nm to 200 nm.

When a polymer LED according to the present invention has a hole transport layer, as an example of the hole transport material to be used, use may be made of polyvinylcarbazole or a derivative thereof, polysilane or a derivative thereof, a polysiloxane derivative having an aromatic amine in a side chain thereof or the main chain, a pyrazoline derivative, an arylamine derivative, a stilbene derivative, a triphenyldiamine derivative, polyaniline or a derivative thereof, polythiophene or a derivative thereof, polypyrrole or a derivative thereof, poly(p-phenylenevinylene) or a derivative thereof, or poly(2,5-thienylenevinylene) or a derivative thereof.

Specific examples of the hole transport material include those described in JP-A-63-70257, 63-175860, 2-135359, 2-135361, 2-209988, 3-37992 and 3-152184.

Of them, as a hole transport material to be used in the hole transport layer, for example, use may be preferably made of polymer hole transport materials such as polyvinylcarbazole or a derivative thereof, polysilane or a derivative thereof, a polysiloxane derivative having an aromatic amine compound group in a side chain or the main chain thereof, polyaniline or a derivative thereof, polythiophene or a derivative thereof, poly(p-phenylenevinylene) or a derivative thereof, or poly(2,5-thienylenevinylene) or a derivative thereof; and more preferably, polyvinylcarbazole or a derivative thereof, or polysilane or a derivative thereof, a polysiloxane derivative having an aromatic amine compound group in a side chain or the main chain thereof. In the case of a low molecular weight hole transport material, it is preferably used by dispersing it in a polymer binder.

The polyvinylcarbazole or a derivative thereof can be obtained from a vinyl monomer by cation polymerization or radical polymerization.

Examples of the polysilane or a derivative thereof include the compounds described in Chem. Rev. Vol. 89, p. 1359 (1989) and the published specification of British Patent GB 2300196. They can be synthesized by the methods described in these documents. In particular, a kipping method is suitably used.

Since a siloxane skeleton structure has virtually no transportability of holes, polysiloxane or a derivative thereof having a structure of the low molecular weight hole transporting material in a side chain or the main chain thereof is suitably used. In particular, mention is made of polysiloxane or a derivative thereof having an aromatic amine in a side chain or the main chain thereof.

A method for forming a film of a hole transport layer is not particularly limited; however, when a low-molecular weight hole transport material is used, a method for forming a film from a solution mixture containing a polymer binder is exemplified. When a high molecular weight hole transport material is used, a method for forming a film from a solution is exemplified.

The solvent to be used in forming a film from a solution is not particularly limited as long as it can dissolve a hole transport material. Examples of the solvent include chlorine based solvents such as chloroform, methylene chloride and dichloroethane; ether based solvents such as tetrahydrofuran; aromatic hydrocarbon based solvents such as toluene and xylene; ketone based solvents such as acetone and methylethyl ketone; and ester based solvents such as ethyl acetate and butyl acetate and ethylcellosolve acetate.

Examples of the method for forming a film from a solution include coating methods such as a spin coat method, casting method, microgravure coat method, gravure coat method, bar coat method, roll coat method, wire-bar coat method, dip coat method, spray coat method, screen printing, flexographic printing method, offset printing method and inkjet printing method.

As the polymer binder to be mixed, one that cannot extremely block charge transport is preferably used and one whose absorption for visible light is low is suitably used. Examples of the polymer binder include polycarbonate, polyacrylate, polymethylacrylate, polymethylmethacrylate, polystyrene, polyvinylchloride and polysiloxane.

The most suitable film thickness of a hole transport layer varies depending upon the material to be used and may be chosen so as to obtain an appropriate drive voltage and luminous efficiency. The hole transport layer must have an appropriate thickness so that formation of a pin hole is at least prevented. When the film is excessively thick, the drive voltage of the device undesirably increases. Accordingly, the film thickness of the hole transport layer is, for example, from 1 nm to 1 μm, preferably 2 nm to 50 nm, and further preferably, 5 nm to 200 nm.

When a polymer LED according to the present invention has an electron transport layer, a known electron transport material may be used. As an example, use may be made of a metal complex of an oxadiazole derivative, anthraquinodimethane or a derivative thereof, benzoquinone or a derivative thereof, naphthoquinone or a derivative thereof, anthraquinone or a derivative thereof, tetracyanoanthraquinodimethane or a derivative thereof, a fluorenone derivative, diphenyldicyanoethylene or a derivative thereof, a diphenoquinone derivative, or 8-hydroxyquinoline or a derivative thereof; polyquinoline or a derivative thereof; polyquinoxaline or a derivative thereof; or polyfluorene or a derivative thereof.

Specific examples of the electron transport material include those described, for example, in JP-A-63-70257, 63-175860, 2-135359, 2-135361, 2-209988, 3-37992 and 3-152184.

Of them, a metal complex of an oxadiazole derivative, benzoquinone or a derivative thereof, anthraquinone or a derivative thereof, or 8-hydroxyquinoline or a derivative thereof; polyquinoline or a derivative thereof; polyquinoxaline or a derivative thereof; polyfluorene or a derivative thereof is preferable; and 2-(4-biphenylyl)-5-(4-t-butylphenyl)-1,3,4-oxadiazole, benzoquinone, anthraquinone, tris(8-quinolinol)aluminum or polyquinoline is further preferable.

A method of forming a film of an electron transport layer is not particularly limited; however, when a low-molecular weight electron transport material is used, a vacuum deposition method for forming a film from powder or a method of forming a film from a solution or a molten state is exemplified. When a high molecular weight electron transport material is used, a method of forming a film from a solution or a molten state is exemplified. When a film formed from a solution or a molten state, a polymer binder may be used in combination.

The solvent to be used in forming a film from a solution is not particularly limited as long as it can dissolve an electron transport material and/or a polymer binder. Examples of the solvent include chlorine based solvents such as chloroform, methylene chloride and dichloroethane; ether based solvents such as tetrahydrofuran; aromatic hydrocarbon based solvents such as toluene and xylene; ketone based solvents such as acetone and methylethyl ketone; and ester based solvents such as ethyl acetate and butyl acetate and ethylcellosolve acetate.

Examples of the method for forming a film from a solution or a molten state include coating methods such as a spin coat method, casting method, microgravure coat method, gravure coat method, bar coat method, roll coat method, wire-bar coat method, dip coat method, spray coat method, screen printing, flexographic printing method, offset printing method and inkjet printing method.

As the polymer binder to be mixed, one that cannot extremely block charge transport is preferable and one whose absorption of light is low is suitably used. As an example of the polymer binder, use may be made of poly(N-vinylcarbazole), polyaniline or a derivative thereof, polythiophene or a derivative thereof, poly(p-phenylenevinylene) or a derivative thereof, poly(2,5-thienylenevinylene) or a derivative thereof, polycarbonate, polyacrylate, polymethylacrylate, polymethylmethacrylate, polystyrene, polyvinylchloride or polysiloxane.

The most suitable film thickness of an electron transport layer varies depending upon the material to be used and may be chosen so as to obtain an appropriate drive voltage and luminous efficiency. The electron transport layer must have an appropriate thickness so that formation of a pin hole is at least prevented. When the film is excessively thick, the drive voltage of the device undesirably increases. Accordingly, the film thickness of the electron transport layer is, for example, from 1 nm to 1 μm, preferably 2 nm to 50 nm, and further preferably, 5 nm to 200 nm.

As a substrate on which a polymer LED according to the present invention is to be formed, any substrate may be used as long as it is not affected when electrodes and an organic compound layer are formed. Examples of the substrate include glass, plastic, polymer film and silicon substrates. When an opaque substrate is used, the electrode placed in opposite thereto is preferably transparent or translucent.

Generally, at least one of the electrodes consisting of an anode and a cathode is transparent or translucent, and more preferably, the anode is transparent or translucent. As the material for the anode, a conductive metal oxide film or a translucent metal thin film is used. Specific examples include indium oxide, zinc oxide, tin oxide and an indium/tin/oxide (ITO), which is a complex of these, and film (NESA) formed of an electroconductive glass of an indium/zinc/oxide and the like, gold, platinum, silver and copper. Of them, ITO, indium/zinc/oxide and tin oxide are preferable. Examples of the film formation method include a vacuum deposition method, sputtering method, ion plating method and plating method. Furthermore, as the anode, use may be made of a transparent electroconductive film made of an organic compound such as polyaniline or a derivative thereof, or a polythiophene or a derivative thereof. The film thickness of the anode can be appropriately selected in consideration of light permeability and electroconductivity. The film thickness is, for example, 10 nm to 10 μm, preferably 20 nm to 1 μm and further preferably, 50 nm to 500 nm. To facilitate charge injection into the anode, a layer formed of a phthalocyanine derivative, electroconductive polymer or carbon, or a layer having an average thickness of 2 nm or less and formed of a metal oxide, metal fluoride or organic insulating material may be provided.

As the material for a cathode to be used in a polymer LED according to the present invention, a material having a small work function is preferable. Examples thereof include metals such as lithium, sodium, potassium, rubidium, cesium, beryllium, magnesium, calcium, strontium, barium, aluminum, scandium, vanadium, zinc, yttrium, indium, cerium, samarium, europium, terbium and ytterbium; alloys formed of two or more types of metals selected from these, alloys formed of at least one type of metals selected from these and at least one type of metal selected from gold, silver, platinum, copper, manganese, titanium, cobalt, nickel, tungsten and tin; or graphite or a graphite interlayer compound. Examples of the alloys include magnesium-silver alloy, magnesium-indium alloy, magnesium-aluminum alloy, indium-silver alloy, lithium-aluminum alloy, lithium-magnesium alloy, lithium-indium alloy and calcium-aluminium alloy. A laminate structure formed of two or more layers may be used as a cathode. The film thickness of the cathode may be appropriately selected in consideration of electroconductivity and durability. The film thickness is, for example, from 10 nm to 10 μm, preferably 20 nm to 1 μm, and further preferably, 50 nm to 500 nm.

As the film formation method for a cathode, use may be made of a vacuum deposition method, sputtering method or laminate method employing thermocompression bonding of metal thin films. Furthermore, a layer formed of an electroconductive polymer or a layer having an average thickness of 2 nm or less and formed of a metal oxide, metal fluoride or organic insulating material may be provided between the cathode and an organic compound layer. Alternatively, after the cathode is formed, a protective layer for protecting the polymer LED may be applied. To use the polymer LED stably for a long time, a protective layer and/or a protection cover may be applied in order to protect the device from the outside world.

As the protective layer, use may be made of a polymer compound, metal oxide, metal fluoride and metal boride. As the protection cover, use may be made of a glass board and a plastic board whose surface is treated so as to reduce water permeability. A method of bonding the cover to a device substrate with a thermosetting resin or a photosetting resin to seal them is suitably used. When a spacer is used to maintain a space, it is easy to protect the device from being damaged. If an inert gas such as nitrogen or argon is injected into the space, oxidation of the cathode can be prevented. Furthermore, if a desiccant such as barium oxide is placed in the space, it is easy to suppress water adsorbed in manufacturing steps from damaging the device. Of these, at least one measure is preferably taken.

A polymer luminescent device according to the present invention can be used as backlight for planar light sources, segment display devices, dot matrice display devices and liquid crystal devices.

To obtain a planer light emission using a polymer LED according to the present invention, a planar anode and a planar cathode may be arranged so as to overlap with each other. Furthermore, to obtain pattern-form light emission, there are a method of providing a mask having a patterned window on the surface of the planar luminescent device, a method of forming an organic compound layer that corresponds to the portion from which no light is emitted, extremely thick to substantially block light emission, and a method of forming either one or both of an anode and a cathode are formed so as to have a pattern. A pattern is formed by any one of these methods and several electrodes are arranged so as to turn on and off independently. In this manner, a segment-type display device can be obtained which can display numeric characters, letters and simple symbols. Furthermore, to obtain a dot matrix device, stripe form anode and cathode are formed and arranged so as to perpendicularly cross to each other. If a method of separately applying a plurality types of polymer fluorescent different in color or a method using a color filter or a light emission conversion filter is employed, partial color display and multicolor display can be attained. The dot matrix device can be passively driven or may be actively driven in combination with TFT and the like. These display devices can be used as display devices of computers, televisions, handheld units, car navigation units and view finders of video cameras.

Furthermore, the planar luminescent device is a thin film luminescent device and can be suitably used as a planar light source for backlight of liquid crystal devices or a planar illumination light source. Moreover, when a flexible substrate is used, a curved-form light sources and curved-form display devices can be obtained.

Furthermore, a polymer compound according to the present invention can be used as a pigment for laser, an organic solar battery material, an organic semiconductor for an organic transistor and a material for a conductive thin film.

### EXAMPLES

The present invention will be further specifically described by way of examples below. However, the present invention is not limited to these.

A polystyrene-reduced number average molecular weight and a polystyrene-reduced weight average molecular weight were obtained by gel permeation chromatography (GPC: LC-10Avp manufactured by Shimadzu Corporation) using tetrahydrofuran as a solvent, as a number average molecular weight and a weight average molecular weight.

### Example 1

### Synthesis of Monomer (1)

### Synthesis Example (1)

A compound (A) (5.0 g) shown below:

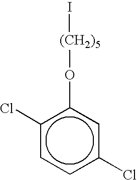

and phenoxazine (2.56 g) were dissolved in o-dichlorobenzene (60 g). To this solution, a 40% aqueous sodium hydroxide solution was added and then benzyltriethylammonium chloride (3.2 g) was added. The reaction was performed at 105° C. for 25 hours. Note that the reaction was performed under a nitrogen gas atmosphere.

After completion of the reaction, the solution was cooled, and allowed to stand still, and then, the upper layer separated was recovered. After the solution was washed with ion exchanged water, the solvent was distilled away under reduced pressure. Then, to the solution, toluene (40 g) was added. After filtration, the solution was passed through a column charged with alumina to purify. The solvent was distilled away from the resultant solution under reduced pressure and dried under reduced pressure to obtain 2.0 g of the monomer (1) shown below:

[H-NMR: solvent CDCl3; 1.5˜1.8 ppm (6H), 3.4˜3.6 ppm (2H), 3.9˜4.1 ppm (2H), 6.4˜7.4 ppm (11H)]

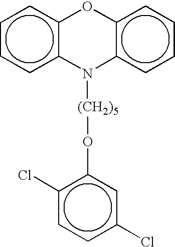

### Synthesis of Polymer Compound 1

After 2,7-dibrome-9,9-dioctylfluorene (1.18 g) and 2,7-dibrome-9,9-diisopentylfluorene (0.26 g), the monomer (1) mentioned above (0.12 g) and 2,2′-bipyridyl (1.4 g) were supplied to a reaction container, the atmosphere of the reaction system was replaced with nitrogen gas. To this, 80 g of tetrahydrofuran (dehydrated solvent), which was degassed by bubbling with argon gas in advance, was added. Subsequently, to the solution mixture, 2.5 g of bis(1,5-cyclooctadiene)nickel(0) was added and the reaction was performed at room temperature for 14 hours. Note that the reaction was performed under a nitrogen gas atmosphere.

After completion of the reaction, a solution mixture of methanol (120 ml)/ion exchanged water (120 ml) was added to the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify.

Next, the toluene solution was washed with about 5% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.48 g). This polymer is referred to as polymer compound 1. The polystyrene-reduced weight average molecular weight of polymer compound 1 thus obtained was 1.0×10⁵ and the polystyrene-reduced number average molecular weight thereof was 4.1×10⁴.

The structures of the repeat units contained in polymer compound 1 and estimated from the supplied materials are as follows. The molar ratio of repeat unit A:repeat unit B:repeat unit C estimated from the supplied materials is 72/18/10.

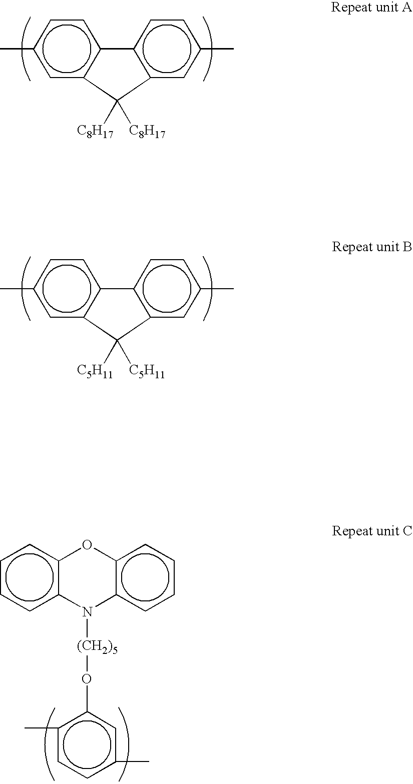

### Example 2

### Synthesis of Polymer Compound 2

A monomer (2)(0.61 g) represented by the following formula:

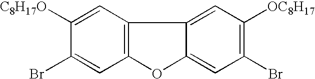

the monomer (1) (0.19 g) and 2,2′-bipyridyl (0.7 g) were supplied to a reaction container and the atmosphere of the reaction system was replaced with nitrogen gas. To this, 50 g of tetrahydrofuran (dehydrated solvent), which was degassed by bubbling with argon gas in advance, was added. Subsequently, 1.24 g of bis(1,5-cyclooctadiene)nickel(0) was added to the solution mixture, and the reaction was performed at room temperature for 32 hours. Note that the reaction was performed under a nitrogen gas atmosphere.

After completion of the reaction, a methanol (40 ml)/ion exchanged water (40 ml) solution mixture was added to the solution, and the mixture was stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, after the toluene solution was washed with about 5% ammonia water, allowed to stand still and separated, the toluene solution was recovered. Subsequently, the toluene solution was washed with ion exchanged water, allowed to stand still and separated, and then, the toluene solution was recovered. The toluene solution was then poured in methanol to generate a reprecipitate.

The precipitate generated was collected and dried under reduced pressure to obtain a polymer (0.11 g). This polymer is referred to as polymer compound 2. The polystyrene-reduced weight average molecular weight of polymer compound 2 thus obtained was 7.5×10⁴ and the polystyrene-reduced number average molecular weight thereof was 1.4×10⁴.

The structures of the repeat units contained in polymer compound 2 and estimated from the supplied materials are as follows. The molar ratio of repeat unit D:repeat unit E and estimated from the supplied materials is 70/30.

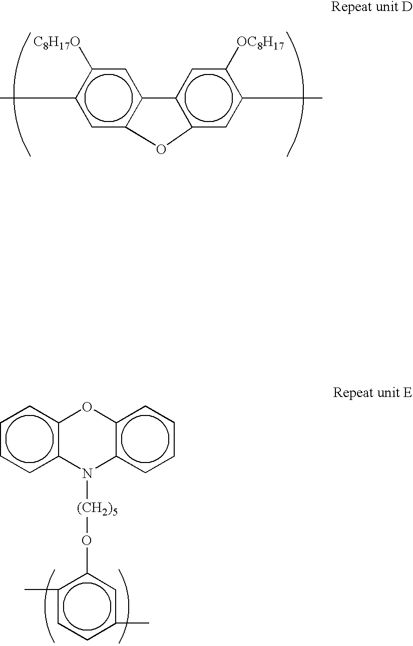

### Comparative Example 1

### Synthesis of Polymer Compound 3

2,7-dibrome-9,9-dioctylfluorene (0.59 g), 2,7-dibrome-9,9-diisopentylfluorene (0.13 g), a monomer (3) (0.071 g) represented by the following formula:

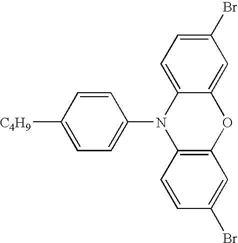

and 2,2′-bipyridyl (0.56 g) were supplied to a reaction vessel and then the atmosphere of the reaction system was replaced with nitrogen gas. To this, 60 g of tetrahydrofuran (dehydrated solvent), which was degassed by bubbling with argon gas in advance, was added. Subsequently, to the solution mixture, 1.0 g of bis(1,5-cyclooctadiene)nickel(0) was added and the reaction was performed at 60° C. for 4 hours. Note that the reaction was performed under a nitrogen gas atmosphere.

After completion of the reaction, the solution was cooled and a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, after the toluene solution was washed with about a 1N aqueous hydrochloric acid solution, allowed to stand still and separated, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated, and then, the toluene solution was recovered. The toluene solution was then poured in methanol to generate a reprecipitate.

The precipitate generated was collected and dried under reduced pressure to obtain a polymer (0.29 g). This polymer is referred to as polymer compound 3. The polystyrene-reduced weight average molecular weight of polymer compound 3 thus obtained was 4.2×10⁵ and the polystyrene-reduced number average molecular weight thereof was 8.9×10⁴.

The structures of the repeat units contained in polymer compound 3 and estimated from the supplied materials are as follows. The molar ratio of repeat unit F:repeat unit G:repeat unit H estimated from the supplied materials is 72/18/10.

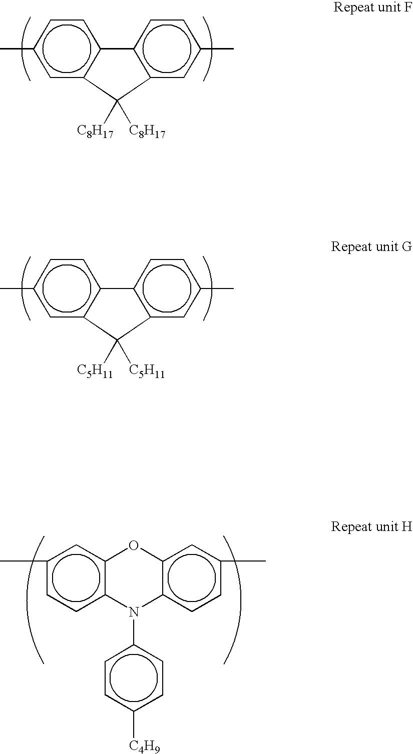

### Comparative Example 2

### Synthesis of Polymer Compound 4

The monomer (2) (0.61 g), the monomer (3) (0.21 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, to the solution mixture, 1.0 g of bis(1,5-cyclooctadiene)nickel(0) was added and the reaction was performed at room temperature for 40 hours. Note that the reaction was performed under a nitrogen gas atmosphere.

After completion of the reaction, a solution mixture of methanol (40 ml)/ion exchanged water (40 ml) was poured in the solution and stirred for about 1 hour. The precipitate generated was then collected by filtration. Subsequently, the precipitate was dried under reduced pressure and dissolved in toluene. After the toluene solution was filtrated to remove insoluble matter, the toluene solution was passed through a column charged with alumina to purify. Next, after the toluene solution was washed with about a 1N aqueous hydrochloric acid solution, allowed to stand still and separated, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.35 g). This polymer is referred to as polymer compound 4. The polystyrene-reduced weight average molecular weight of polymer compound 4 thus obtained was 7.2×10⁴ and the polystyrene-reduced number average molecular weight thereof was 2.0×10⁴.

The structures of the repeat units contained in polymer compound 4 and estimated from the supplied materials are as follows. The molar ratio of repeat unit M:repeat unit N estimated from the supplied materials is 70/30.

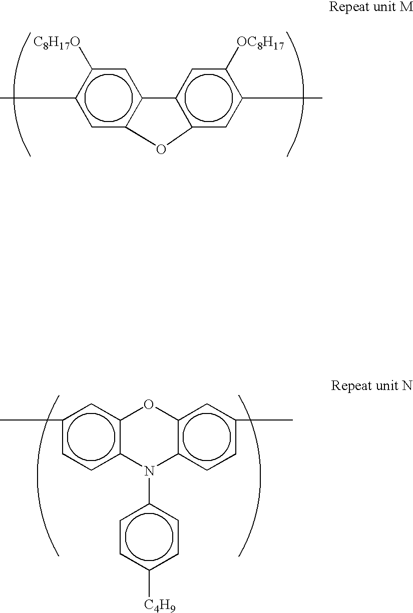

### Example 3

### Synthesis of Monomer (4)

### Synthesis Example (2)

The following compound (C) (7.4 g):

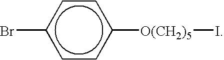

and phenoxazine (2.7 g) were dissolved in o-dichlorobenzene (60 g). To this solution, a 40% aqueous sodium hydroxide solution was added and then benzyltriethylammonium chloride (3.2 g) was added. The reaction was performed at 105° C. for 25 hours. Note that the reaction was performed in a nitrogen gas atmosphere.

After completion of the reaction, the solution was cooled, allowed to stand still and separated, and then, the upper layer was recovered. Subsequently, the solution was washed with ion exchanged water and the solvent was distilled away under reduced pressure. Then, to the solution, toluene (40 g) was added. After filtration, the solution was passed through a column charged with alumina to purify. The solvent was then distilled away under reduced pressure. The precipitate obtained was washed with methanol and dried under reduced pressure to obtain 2.7 g of the monomer (4) shown below:

[H-NMR: solvent CDCl₃; 1.5˜1.9 ppm (6H), 3.4˜3.6 ppm (2H), 3.8˜4.0 ppm (2H), 6.4˜7.4 ppm (12H)]

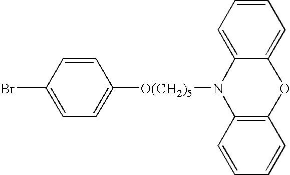

### Synthesis of Polymer Compound 5

The monomer (2) (0.79 g), the monomer (4) (0.064 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, to the solution mixture, 1.0 g of bis(1,5-cyclooctadiene)nickel(0) was added and the reaction was performed at 60° C. for 4 hours. Note that the reaction was performed under a nitrogen gas atmosphere.

After completion of the reaction, the solution was cooled. A solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, the toluene solution was washed with about a 1N aqueous hydrochloric acid solution, allowed to stand still and separated. Thereafter, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.14 g). This polymer is referred to as polymer compound 5. The polystyrene-reduced weight average molecular weight of polymer compound 5 thus obtained was 2.5×10⁴ and the polystyrene-reduced number average molecular weight thereof was 1.8×10⁴.

The structures of the repeat unit and the terminal group contained in polymer compound 5 and estimated from the supplied materials are as follows. The molar ratio of repeat unit A′:terminal group B′ estimated from the supplied materials is 90/10.

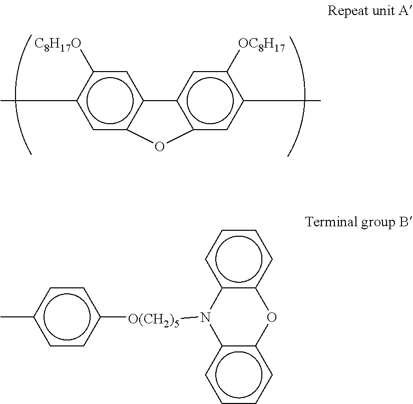

### Example 4

### Synthesis of Monomer (5)

### Synthesis Example (3)

The following compound (D) (3.15 g)

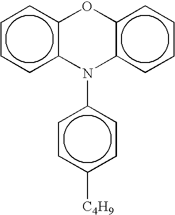

was dissolved in N,N-dimethylformamide (100 g). The solution was cooled on ice and then a solution of N-bromosuccinimide (1.62 g) dissolved in N,N-dimethylformamide (50 g) previously prepared was added dropwise for about 80 minutes.

Subsequently after dropwise addition, the reaction was performed at 0 to 5° C. for 4 hours. Then, the temperature of the reaction solution was raised to room temperature and the reaction was continuously performed at room temperature overnight. Note that the reaction was performed under a nitrogen gas atmosphere.

After completion of the reaction, ion exchanged water was added to the reaction solution and washed. The solvent was distilled away from the solution under reduced pressure. After toluene was added to the precipitate generated and dissolved it, the toluene solution was filtrated to remove insoluble matter. The toluene solution was passed through a column charged with alumina to purify. After the solvent was evaporated under reduced pressure, then the residue was dried under reduced pressure to obtain the following monomer (5) (2.0 g).

[H-NMR: solvent CDCl₃; 0.9˜1.0 ppm (3H), 1.3˜1.7 ppm (4H), 2.6˜2.7 ppm (2H), 5.7˜6.0 ppm (2H), 6.5˜6.8 (5H, 7.1˜7.4 (4H))

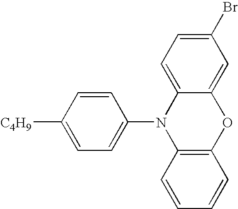

### Synthesis of Polymer Compound 6

The monomer (2) (0.79 g), the monomer (5) (0.059 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at 60° C. for 4 hours. Note that the reaction was performed under a nitrogen gas atmosphere.

After completion of the reaction, the solution was cooled. A solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, the toluene solution was washed with about a 1N aqueous hydrochloric acid solution, allowed to stand still and separated. Thereafter, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.20 g). This polymer is referred to as polymer compound 6. The polystyrene-reduced weight average molecular weight of polymer compound 6 thus obtained was 2.5×10⁴ and the polystyrene-reduced number average molecular weight thereof was 1.6×10⁴.

The structures of the repeat unit and the terminal group contained in polymer compound 6 and estimated from the supplied materials are as follows. The molar ratio of repeat unit C′:terminal group D′ estimated from the supplied materials is 90/10.

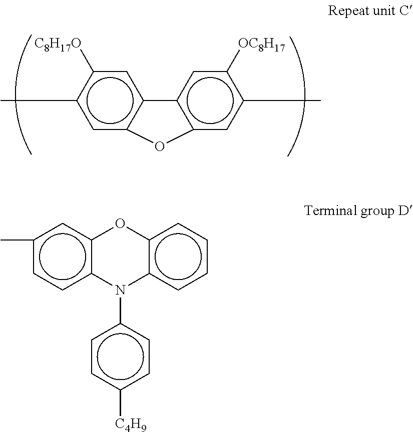

### Comparative Example 3

### Synthesis of Polymer Compound 7

The monomer (2) (0.79 g), the monomer (3) (0.071 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at 60° C. for 4 hours. Note that the reaction was performed under a nitrogen gas atmosphere.

After completion of the reaction, the solution was cooled. Then a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, the toluene solution was washed with about a 1N aqueous hydrochloric acid solution, allowed to stand still and separated. Thereafter, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated, and then, the toluene solution was recovered. The toluene solution was then poured in methanol to generate a reprecipitate.

The precipitate generated was collected and dried under reduced pressure to obtain a polymer (0.29 g). This polymer is referred to as polymer compound 7. The polystyrene-reduced weight average molecular weight of polymer compound 7 thus obtained was 1.0×10⁵ and the polystyrene-reduced number average molecular weight thereof was 4.4×10⁴.

The structures of the repeat units contained in polymer compound 7 and estimated from the supplied materials are as follows. The molar ratio of repeat unit E′:repeat unit F′ estimated from the supplied materials is 90/10.

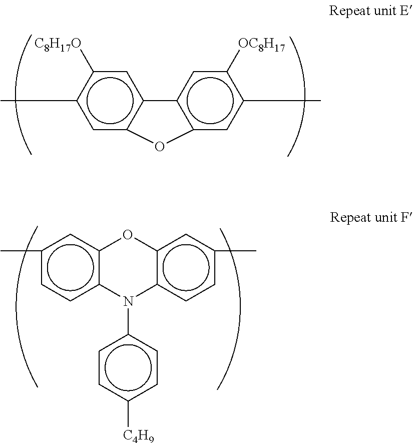

### Example 5

### Synthesis of Polymer Compound 8

The monomer (5) (0.059 g), 2,7-dibrome-9,9-dioctylfluorene (0.59 g), 2,7-dibrome-9,9-diisopentylfluorene (0.13 g), and 2,2′-bipyridyl (0.56 g) were supplied to a reaction vessel and then the atmosphere of the reaction system was replaced with nitrogen gas. To this, 60 g of tetrahydrofuran (dehydrated solvent), which was degassed by bubbling with argon gas in advance, was added. Subsequently, to the solution mixture, 1.0 g of bis(1,5-cyclooctadiene)nickel(0) was added and the reaction was performed at 60° C. for 4 hours. Note that the reaction was performed under a nitrogen gas atmosphere.

After completion of the reaction, the solution was cooled and a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. After the toluene solution was filtrated to remove insoluble matter, the toluene solution was passed through a column charged with alumina to purify. Next, after the toluene solution was washed with about a 1N aqueous hydrochloric acid solution, allowed to stand still and separated, the toluene solution was recovered. Then, the toluene solution was washed with about 5% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.20 g). This polymer is referred to as polymer compound 8. The polystyrene-reduced weight average molecular weight of polymer compound 8 thus obtained was 3.2×10⁴ and the polystyrene-reduced number average molecular weight thereof was 1.6×10⁴.

The structures of the repeat units and the terminal group contained in polymer compound 8 and estimated from the supplied materials are as follows. The molar ratio of repeat unit A″:repeat unit B″:terminal group C″ estimated from the supplied materials is 72/18/10.

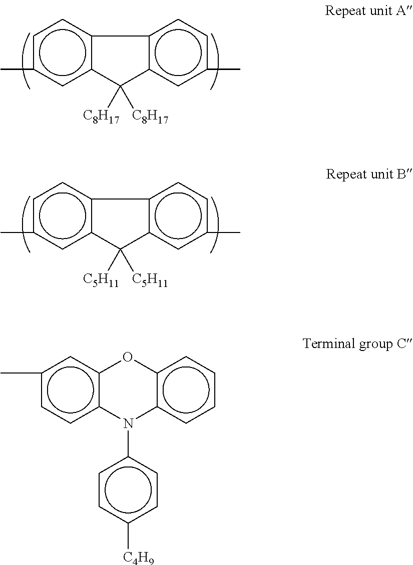

### Example 6

### Synthesis of Polymer Compound 9

The monomer (6) (0.81 g) represented by the following formula:

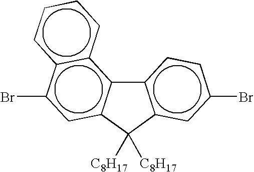

the monomer (5) (0.059 g) and 2,2′-bipyridyl (0.58 g) were supplied to a reaction vessel and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at room temperature for 23 hours. Note that the reaction was performed under a nitrogen gas atmosphere.

After completion of the reaction, a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. The toluene solution was filtrated to remove insoluble matter. Thereafter, the toluene solution was washed with an about 5% aqueous acetic acid solution, allowed to stand still and separated. Thereafter, the toluene solution was recovered. Then, the toluene solution was washed with 4% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.31 g). This polymer is referred to as polymer compound 9. The polystyrene-reduced weight average molecular weight of polymer compound 9 thus obtained was 2.9×10⁴ and the polystyrene-reduced number average molecular weight thereof was 1.5×10⁴.

The structures of the repeat unit and the terminal group contained in polymer compound 9 and estimated from the supplied materials are as follows. The molar ratio of repeat unit D″:terminal group E″ estimated from the supplied materials is 90/10.

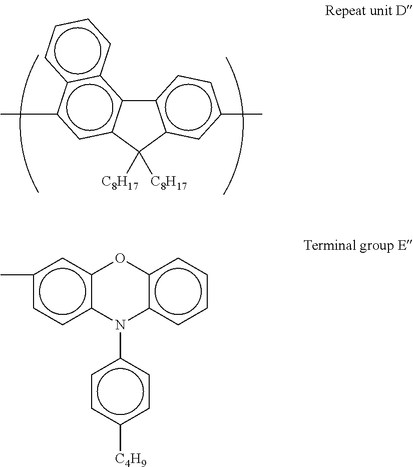

### Example 7

### Synthesis of Polymer Compound 10

The monomer (6) (0.81 g), the monomer (1) (0.063 g) and 2,2′-bipyridyl (0.58 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at room temperature for 23 hours. Note that the reaction was performed under a nitrogen gas atmosphere.

After completion of the reaction, a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. The toluene solution was filtrated to remove insoluble matter. Thereafter, the toluene solution was washed with an about 5% aqueous acetic acid solution, allowed to stand still and separated. Thereafter, the toluene solution was recovered. Then, the toluene solution was washed with 4% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.40 g). This polymer is referred to as polymer compound 10. The polystyrene-reduced weight average molecular weight of polymer compound 10 thus obtained was 1.4×10⁵ and the polystyrene-reduced number average molecular weight thereof was 4.7×10⁴.

The structures of the repeat units contained in polymer compound 10 and estimated from the supplied materials are as follows. The molar ratio of repeat unit F″:repeat unit G″ estimated from the supplied materials is 90/10.

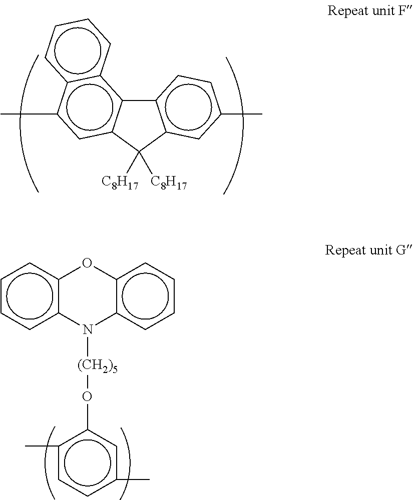

### Example 8

### Synthesis of Monomer (7)

### Synthesis Example 4

The compound (A) (5.0 g) and phenothiazine (2.8 g) were dissolved in o-dichlorobenzene (60 g). To this solution, a 40% aqueous sodium hydroxide solution was added and then benzyltriethylammonium chloride (3.2 g) was added. The reaction was performed at 105° C. for 25 hours. Note that the reaction was performed under a nitrogen gas atmosphere.

After completion of the reaction, the solution was cooled, allowed to stand still. Then, the upper layer separated was recovered. Subsequently, the solution was washed with ion exchanged water and the solvent was distilled away under reduced pressure. Then, to the solution, toluene (40 g) was added. After filtration, the solution was passed through a column charged with alumina to purify. The solvent was distilled away from the resultant solution under reduced pressure to obtain a precipitate (2.0 g). Subsequently, the precipitate (1.5 g) was purified by silica gel column chromatography (solvent mixture of toluene/hexane=2/8). The solvent was distilled away from an aliquoted solution under reduced pressure and dried under reduced pressure to obtain the following monomer (7) (0.9 g).

[H-NMR: solvent CDCl₃; 1.5˜2.0 ppm (6H), 3.8˜4.0 ppm (4H), 6.7˜7.3 ppm (11H)]

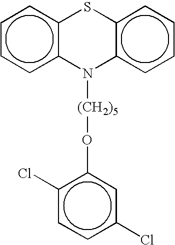

### Synthesis of Polymer Compound 11

The monomer (6) (0.72 g), the monomer (7) (0.13 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at room temperature for 23 hours. Note that the reaction was performed under a nitrogen gas atmosphere.

After completion of the reaction, a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. The toluene solution was filtrated to remove insoluble matter. Thereafter, the toluene solution was washed with an about 5% aqueous acetic acid solution, allowed to stand still and separated. Then, the toluene solution was recovered. Thereafter, the toluene solution was washed with 4% ammonia water, allowed to stand still and separated. Then, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.34 g). This polymer is referred to as polymer compound 11. The polystyrene-reduced weight average molecular weight of polymer compound 11 thus obtained was 4.9×10⁴ and the polystyrene-reduced number average molecular weight thereof was 2.5×10⁴.

The structures of the repeat units contained in polymer compound 11 and estimated from the supplied materials are as follows. The molar ratio of repeat unit H′″:repeat unit I′″ estimated from the supplied materials is 80/20.

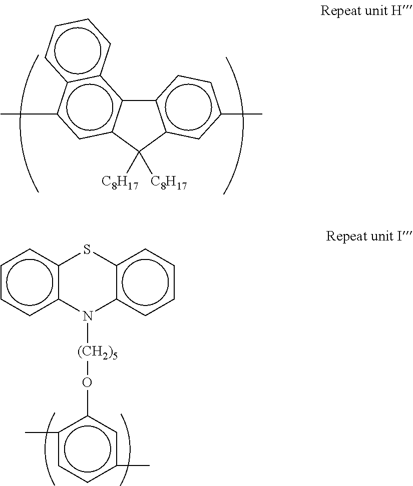

### Example 9

### Synthesis of Polymer Compound 12

The monomer (2) (0.70 g), the monomer (7) (0.13 g) and 2,2′-bipyridyl (0.56 g) were supplied to a reaction container and then the atmosphere of the reaction system was replaced with nitrogen gas. To this, 60 g of tetrahydrofuran (dehydrated solvent), which was degassed by bubbling with argon gas in advance, was added. Subsequently, 1.0 g of bis(1,5-cyclooctadiene)nickel(0) was added to the solution mixture, and the reaction was performed at room temperature for 23 hours. Note that the reaction was performed under a nitrogen gas atmosphere.

After completion of the reaction, a solution mixture of methanol (40 ml)/ion exchanged water (40 ml) was poured in the solution and stirred for about 1 hour. The precipitate generated was collected by filtration. Subsequently, the precipitate was dried under reduced pressure and dissolved in toluene. The toluene solution was filtrated to remove insoluble matter. Thereafter, the toluene solution was washed with an about 5% aqueous acetic acid solution, allowed to stand still and separated. Thereafter, the toluene solution was recovered. Then, the toluene solution was washed with 4% ammonia water, allowed to stand still and separated. Thereafter, the toluene solution was recovered. Subsequently, the toluene solution was washed with ion exchanged water, allowed to stand still and separated and then the toluene solution was recovered. The toluene solution was then poured in methanol to generate a reprecipitate.

The precipitate generated was collected and dried under reduced pressure to obtain a polymer (0.21 g). This polymer is referred to as polymer compound 12. The polystyrene-reduced weight average molecular weight of polymer compound 12 thus obtained was 3.0×10⁴ and the polystyrene-reduced number average molecular weight thereof was 6.3×10³.

The structures of the repeat units contained in polymer compound 12 and estimated from the supplied materials are as follows. The molar ratio of repeat unit J′″:repeat unit K′″ estimated from the supplied materials is 80/20.

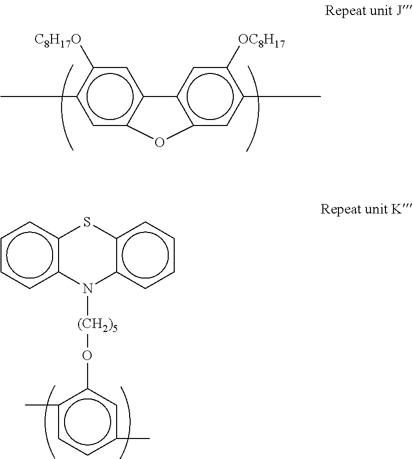

### Example 10

### Evaluation of Fluorescent Property of Polymer Compound

A 0.8 wt % toluene solution of a polymer compound was applied onto a quartz plate by spin coating to prepare a thin film of the polymer compound. The fluorescent spectrum of the thin film was obtained by a fluorospectrophotometer (Fluorolog manufactured by Jobinyvon-Spex) at an excitation wavelength of 350 nm. A relative fluorescent intensity of the thin film was obtained by dividing the integration value (which is obtained by integrating the fluorescent spectrum plotted against wavelength by the spectrum measurement range based on the Raman-line intensity of water as a reference) by the absorbency measured by a spectrophotometer (Cary 5E manufactured by Varian) at the excitation wavelength.

The measurement results of fluorescent peak wavelength and fluorescent intensity are shown in Table 1. The fluorescent intensity of polymer compound 1 containing a side chain group, according to the present invention was stronger than that of a polymer compound 3 having a phenoxazine ring in the polymer chain. The fluorescent intensity of polymer compound 2 containing a side chain group, according to the present invention was stronger than that of a polymer compound 4 having a phenoxazine ring in the polymer chain.

The fluorescent intensity values of polymer compounds 5 and 6 containing a terminal group, according to the present invention were stronger than that of polymer compound 7 having a phenoxazine ring in the polymer chain.

The fluorescent intensity of polymer compound 8 containing a terminal group, according to the present invention was stronger than that of polymer compound 3 having a phenoxazine ring in the polymer chain.

TABLE 1
Peak wavelength and fluorescent intensity
(relative value) of polymer compound

| Polymer | Fluorescent | Fluorescent intensity |
|---|---|---|
| compound | peak wavelength (nm) | (relative value) |
| 1 | 423 | 8.3 |
| 2 | 433 | 5.1 |
| 3 | 458 | 4.2 |
| 4 | 474 | 3.0 |
| 5 | 414 | 6.4 |
| 6 | 456 | 6.4 |
| 7 | 468 | 3.9 |
| 8 | 454 | 8.5 |
| 9 | 465 | 12.4 |
| 10 | 450 | 12.8 |
| 11 | 449 | 12.9 |
| 12 | 415 | 3.3 |

### Example 11

### Evaluation of Device Characteristics

On a glass substrate having an ITO film of about 150 nm in thickness formed by sputtering, a solution of poly(ethylenedioxythiophene)/polystyrene sulfonate (BaytronP manufactured by Bayer) is applied in accordance with spin coating to form a film of about 50 nm in thickness. The film is dried on a hot plate at about 200° C. for 10 minutes. Subsequently, a toluene solution, which is prepared so as to contain a mixture of polymer compound 1 and polymer compound 2 (3:7 by weight) in a concentration of about 1.5%, is applied by spin coating at a rate of 1500 rpm to form a film. The resultant film is dried at reduced pressure at 80° C. for one hour. Thereafter, lithium fluoride is deposited to a thickness of about 4 nm. About calcium is deposited to about 20 nm thickness and then, aluminum is deposited to about 50 nm thickness as a cathode. In this manner, an EL device is prepared. Note that, after degree of vacuum reached to 1×10⁻⁴ Pa or less, deposition of a metal is initiated. When voltage is applied to the device obtained, blue EL is emitted.

### INDUSTRIAL APPLICABILITY

When a polymer compound according to the present invention is used as a luminescent material for a luminescent layer of a polymer LED, the polymer LED shows excellent properties. Accordingly, the polymer LED can be preferably used in curved and planar light sources serving as backlight or illumination for a liquid crystal display and used in devices such as a segment-type display device and a dot matrix flat panel display device. In addition, a polymer compound according to the present invention can be used as a dye for laser, a material for organic solar battery, an organic semiconductor for an organic transistor and a material for a conductive thin film.

1. A polymer compound having at least one type of repeat unit selected from the group consisting of the repeat units represented by the following formula (1), characterized by having a substituent selected from the group consisting of the monovalent groups represented by the following formula (2) or (3),
—Ar₁—(Z′)p— (1)
where Ar₁ represents an arylene group, a divalent heterocyclic group or a divalent aromatic amine group; Z′ represents —CR₄═CR₅— or —C≡C—; R₄ and R₅ each independently represent a hydrogen atom, an alkyl group, an aryl group, a monovalent heterocyclic group or a cyano group; and p represents 0 or 1, 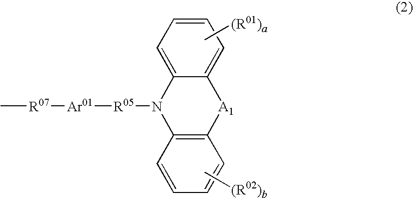
where A₁ represents —O—, —S— or —C(O)—; Ar⁰¹ represents a direct bond, an arylene group, a divalent heterocyclic group or a divalent aromatic amine group; R⁰⁵ and R⁰⁷ each independently represent a direct bond, —R₁—, —O—R₁—, —R₁—O—, —R₁—C(O)O—, —R₁—OC(O)—, —R₁—N(R₂₀)—, —O—, —S—, —C(O)O— or —C(O)—; R₁ represents an alkylene group or an alkenylene group, with the proviso that when Ar⁰¹ is a direct bond, R⁰⁷ is also a direct bond; R₂₀ represents a hydrogen atom, an alkyl group, an aryl group, a monovalent heterocyclic group or a cyano group; R⁰¹ and R⁰² each independently represent a substituent; a and b are each independently an integer from 0 to 4; and a plurality of substituents represented by R⁰¹ and R⁰² may be the same or different, 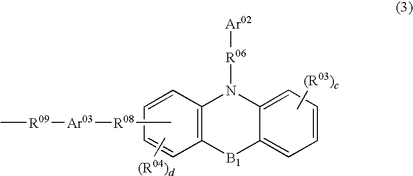
where B₁ represents —O—, —S— or —C(O)—; Ar⁰² represents a hydrogen atom, an aryl group, a monovalent heterocyclic group or a monovalent aromatic amine group; Ar⁰³ represents a direct bond, an arylene group, a divalent heterocyclic group or a divalent aromatic amine group; R⁰⁶, R⁰⁸ and R⁰⁹ each independently represent a direct bond, —R₁—, —O—R₁—, —R₁—O—, —R₁—C(O)O—, —R₁—OC(O)—, —R₁—N(R₂₀)—, —O—, —S—, —C(O)O— or —C(O)—; R₁ represents an alkylene group or an alkenylene group, R₂₀ represents a hydrogen atom, an alkyl group, an aryl group, a monovalent heterocyclic group or a cyano group, with the proviso that when Ar⁰³ is a direct bond, R⁰⁹ is also a direct bond; R⁰³ and R⁰⁴ each independently represent a substituent; c is an integer from 0 to 4; d is an integer from 0 to 3; and a plurality of substituents represented by R⁰³ and R⁰⁴ may be the same or different.

2. The polymer compound according to claim 1, wherein Ar₁ of the aforementioned formula (1) has at least one of the groups represented by the aforementioned formula (2).

3. The polymer compound according to claim 1, wherein Ar₁ of the aforementioned formula (1) has at least one of the groups represented by the aforementioned formula (3).

4. The polymer compound according to claim 1, wherein at least one of the molecular chain ends of the polymer compound has a group represented by the aforementioned formula (2).

5. The polymer compound according to claim 1, wherein at least one of the molecular chain ends of the polymer compound has a group represented by the aforementioned formula (3).

6. The polymer compound according to claim 1, further comprising a repeat unit represented by the following formula (30),
—Ar₄—(Z)ₜ— (30)
where Ar₄ represents an arylene group that may have a substituent, a divalent heterocyclic group that may have a substituent, or a divalent aromatic amine group that may have a substituent, with the proviso that none of those represented by the aforementioned formulas (2) and (3) are included in the substituents; Z represents —CR₇═CR₈— or —C≡C—; R₇ and R₈ each independently represent a hydrogen atom, an alkyl group, an aryl group, a monovalent heterocyclic group or a cyano group; and t represents 0 or 1.

7. The polymer compound according to claim 1, having a polystyrene-reduced number average molecular weight of 10³ to 10⁸.

8. The polymer compound according to claim 1, being fluorescent in a solid state.

9. The polymer compound according to claim 1, being fluorescent in a solid state and having a polystyrene-reduced number average molecular weight of 10³ to 10⁸.

10. The polymer compound according to claim 1, being phosphorescent in a solid state.

11. A polymer composition characterized by comprising the polymer compound having a polystyrene-reduced number average molecular weight of 10³ to 10⁸, being fluorescent in a solid state, having none of the groups represented by the aforementioned formulas (2) and (3) as a substituent, and the compound according to claim 1.

12. A polymer luminescent device having a luminescent layer between electrodes composed of an anode and a cathode, characterized in that the luminescent layer contains a polymer compound according to claim 1.

13. A polymer luminescent device having a luminescent layer between electrodes composed of an anode and a cathode, characterized in that the luminescent layer contains a polymer compound according to claim 11.

14. The polymer luminescent device according to claim 12, providing a layer containing a conductive polymer between at least one of the electrodes and the luminescent layer and in adjacent to the electrode.

15. The polymer luminescent device according to claim 12, providing an insulating layer having an average film thickness of 2 nm or less between at least one of the electrodes and the luminescent layer and in adjacent to the electrode.

16. The polymer luminescent device according to claim 12, providing an electron transport layer between the cathode and a luminescent layer and in adjacent to the luminescent layer.

17. The polymer luminescent device according to claim 12, providing a hole transport layer between the anode and the luminescent layer and in adjacent to the luminescent layer.

18. The polymer luminescent device according to claim 12, providing an electron transport layer between the cathode and the luminescent layer and in adjacent to the luminescent layer and providing a hole transport layer between the anode and the luminescent layer and in adjacent to the luminescent layer.

19. A planar light source characterized by comprising a polymer luminescent device according to claim 12.

20. A segment display device characterized by comprising a polymer luminescent device according to claim 12.

21. A dot matrix display device characterized by comprising a polymer luminescent device according to claim 12.

22. A liquid crystal display device characterized by using a polymer luminescent device according to claim 12 as backlight.

23. A solution composition characterized by comprising the polymer compound according to claim 1.

24. A thin film characterized by comprising the polymer compound according to claim 1.

25. A transistor characterized by comprising the polymer compound according to claim 1.

26. A solar battery characterized by comprising the polymer compound according to claim 1.
